(19) United States
(12) Patent Application Publication
(10) Pub. No.: US 2018/0277518 A1
(43) Pub. Date: Sep. 27, 2018

(54) SEMICONDUCTOR DEVICE AND MANUFACTURING METHOD THEREOF

(71) Applicant: RENESAS ELECTRONICS CORPORATION, Tokyo (JP)

(72) Inventors: Tetsuya IIDA, Ibaraki (JP); Yasutaka NAKASHIBA, Ibaraki (JP); Nobuya KOIKE, Tokyo (JP)

(21) Appl. No.: 15/861,231

(22) Filed: Jan. 3, 2018

(30) Foreign Application Priority Data
Mar. 24, 2017 (JP) 2017-059866

(51) Int. Cl. H01L 25/065; H01L 23/528; H01L 23/00; H01L 23/522; H01L 23/532; H01L 23/31; H01L 23/544; H01L 25/00; H01L 21/78; H01L 21/56; H01L 21/02; H01L 23/495

(52) U.S. Cl. CPC H01L 25/0657; H01L 2224/83139; H01L 24/32; H01L 23/5227; H01L 23/5329; H01L 24/05; H01L 23/3107; H01L 23/544; H01L 25/50; H01L 21/78; H01L 24/83; H01L 24/48; H01L 24/85; H01L 21/56; H01L 21/0217; H01L 21/0214; H01L 24/73; H01L 24/92; H01L 23/49541; H01L 23/49575; H01L 2225/06593; H01L 2223/54426; H01L 2224/32145; H01L 2224/48091; H01L 2224/48247; H01L 2224/73265; H01L 2224/73215; H01L 2224/92147; H01L 2224/92247; H01L 2225/06562; H01L 2225/0651; H01L 2225/06531; H01L 2224/8385; H01L 23/528

(57) ABSTRACT

An improvement is achieved in the reliability of a semiconductor device. A first semiconductor chip includes a semiconductor substrate, a wiring structure formed over the semiconductor substrate, an insulating film formed over the wiring structure, and a first insulating film formed over the insulating film. A second semiconductor chip includes a semiconductor substrate, a wiring structure formed over the semiconductor substrate, an insulating film formed over the wiring structure, and a second insulating film formed over the insulating film. The first insulating film forms an uppermost layer of the first semiconductor chip. The second insulating film forms an uppermost layer of the second semiconductor chip. Each of the first and second insulating films is made of a photosensitive resin film having an adhesive property. The first and second semiconductor chips are stacked such that the first insulating film of the first semiconductor chip and the second insulating film of the second semiconductor chip are in contact with each other.

### CROSS-REFERENCE TO RELATED APPLICATIONS

The disclosure of Japanese Patent Application No. 2017-059866 filed on Mar. 24, 2017 including the specification, drawings and abstract is incorporated herein by reference in its entirety.

### BACKGROUND

The present invention relates to a semiconductor device and a manufacturing method thereof, which can be used appropriately as a semiconductor device in which, e.g., two semiconductor chips having respective inductors formed therein are disposed to face each other and a manufacturing method thereof.

As a technique which transmits an electric signal between two circuits to which electric signals having different potentials are input, there is a technique using a photocoupler. The photocoupler has a light emitting element such as a light emitting diode and a light receiving element such as a phototransistor. The photocoupler converts the electric signal input thereto to light using the light emitting element and restores the light to the electric signal using the light receiving element to transmit the electric signal.

On the other hand, a technique which magnetically couples (inductively couples) two inductors to transmit an electric signal has been developed.

Japanese Unexamined Patent Application Publication No. 2011-54800 (Patent Document 1) discloses a technique related to a semiconductor chip in which, in a first semiconductor chip and a second semiconductor chip, respective inductors are formed and signal transmission between the individual chips is performed using the inductive coupling of the inductors.

Each of Japanese Unexamined Patent Application Publications Nos. 2011-248188 (Patent Document 2) and 2002-162738 (Patent Document 3) discloses a technique related to a permanent resist.

### RELATED ART DOCUMENTS

### Patent Documents

[Patent Document 1] Japanese Unexamined Patent Application Publication No. 2011-54800

[Patent Document 2] Japanese Unexamined Patent Application Publication No. 2011-248188

[Patent Document 3] Japanese Unexamined Patent Application Publication No. 2002-162738

### SUMMARY

It is desired to improve the reliability of a semiconductor device in which two semiconductor chips are disposed to face each other.

Other problems and novel features of the present invention will become apparent from a statement in the present specification and the accompanying drawings.

According to an embodiment, a semiconductor device includes a first semiconductor chip having a first photosensitive resin film having an adhesive property in an uppermost layer thereof and a second semiconductor chip having a second photosensitive resin film having an adhesive property in an uppermost layer thereof. The first semiconductor chip and the second semiconductor chip are stacked such that the first photosensitive resin film of the first semiconductor chip and the second photosensitive resin film of the second semiconductor chip are in contact with each other.

According to the embodiment, a method of manufacturing a semiconductor device includes the steps of providing a first semiconductor chip including a first photosensitive resin film having an adhesive property in an uppermost layer thereof and providing a second semiconductor chip including a second photosensitive resin film having an adhesive property in an uppermost layer thereof. The method of manufacturing the semiconductor device further includes the step of stacking the first semiconductor chip and the second semiconductor chip such that the first photosensitive resin film of the first semiconductor chip having the adhesive property and the second photosensitive resin film of the second semiconductor chip having the adhesive property come in contact with each other.

According to the embodiment, the reliability of the semiconductor device can be improved.

### BRIEF DESCRIPTION OF THE DRAWINGS

FIG. 1 is a circuit diagram showing an example of an electronic device using a semiconductor device in an embodiment;

FIG. 2 is an illustrative view showing an example of signal transmission;

FIG. 3 is a top view of a semiconductor package in the embodiment;

FIG. 4 is a perspective plan view of the semiconductor package in FIG. 3;

FIG. 5 is a perspective plan view of the semiconductor package in FIG. 3;

FIG. 6 is a perspective plan view of the semiconductor package in FIG. 3;

FIG. 7 is a perspective plan view of the semiconductor package in FIG. 3;

FIG. 8 is a cross-sectional view of the semiconductor package in FIG. 3;

FIG. 9 is a cross-sectional view of the semiconductor package in FIG. 3;

FIG. 10 is a partially enlarged cross-sectional view showing a portion of the semiconductor package in FIG. 8 in enlarged relation;

FIG. 11 is a cross-sectional view of the semiconductor package in FIGS. 3 to 10 during the manufacturing process thereof;

FIG. 12 is a cross-sectional view of the semiconductor package during the manufacturing process thereof, which is subsequent to FIG. 11;

FIG. 13 is a cross-sectional view of the semiconductor package during the manufacturing process thereof, which is subsequent to FIG. 12;

FIG. 14 is a cross-sectional view illustrating a process step in FIG. 13;

FIG. 15 is a cross-sectional view illustrating the process step in FIG. 13;

FIG. 16 is a cross-sectional view of the semiconductor package during the manufacturing process thereof, which is subsequent to FIG. 13;

FIG. 17 is a cross-sectional view of the semiconductor package during the manufacturing process thereof, which is subsequent to FIG. 16;

FIG. 18 is a cross-sectional view of the semiconductor package during the manufacturing process thereof, which is subsequent to FIG. 17;

FIG. 19 is an illustrative view showing an example of an electronic system using the semiconductor device in the embodiment;

FIG. 20 is a cross-sectional view of a semiconductor chip in the embodiment;

FIG. 21 is a plan view showing a coil wire;

FIG. 22 is a cross-sectional view of the semiconductor chip in the embodiment during the manufacturing process thereof;

FIG. 23 is a cross-sectional view of the semiconductor chip during the manufacturing process thereof, which is subsequent to FIG. 22;

FIG. 24 is a cross-sectional view of the semiconductor chip during the manufacturing process thereof, which is subsequent to FIG. 23;

FIG. 25 is a cross-sectional view of the semiconductor chip during the manufacturing process thereof, which is subsequent to FIG. 24;

FIG. 26 is a cross-sectional view of the semiconductor chip during the manufacturing process thereof, which is subsequent to FIG. 25;

FIG. 27 is a cross-sectional view of the semiconductor chip during the manufacturing process thereof, which is subsequent to FIG. 26;

FIG. 28 is a cross-sectional view of the semiconductor chip during the manufacturing process thereof, which is subsequent to FIG. 27;

FIG. 29 is a cross-sectional view of the semiconductor chip during the manufacturing process thereof, which is subsequent to FIG. 28;

FIG. 30 is a cross-sectional view of the semiconductor chip during the manufacturing process thereof, which is subsequent to FIG. 29;

FIG. 31 is a cross-sectional view of the semiconductor chip during the manufacturing process thereof, which is subsequent to FIG. 30;

FIG. 32 is a cross-sectional view of the semiconductor chip during the manufacturing process thereof, which is subsequent to FIG. 31;

FIG. 33 is a cross-sectional view of the semiconductor chip during the manufacturing process thereof, which is subsequent to FIG. 31;

FIG. 34 is a cross-sectional view of the semiconductor chip during the manufacturing process thereof, which is subsequent to FIG. 33;

FIG. 35 is a cross-sectional view of the semiconductor chip during the manufacturing process thereof, which is subsequent to FIG. 32 or 34;

FIG. 36 is a cross-sectional view of the semiconductor chip during the manufacturing process thereof, which is subsequent to FIG. 35;

FIG. 37 is a cross-sectional view of the semiconductor chip during the manufacturing process thereof, which is subsequent to FIG. 36;

FIG. 38 is a cross-sectional view of the semiconductor chip during the manufacturing process thereof, which is subsequent to FIG. 37;

FIG. 39 is a cross-sectional view of a semiconductor package in a studied example;

FIG. 40 is a partially enlarged cross-sectional view showing a portion of the semiconductor package in the studied example in FIG. 39 in enlarged relation;

FIG. 41 is a partially enlarged cross-sectional view showing a portion of a semiconductor package in another embodiment;

FIG. 42 is a cross-sectional view illustrating the manufacturing process of the semiconductor package in FIG. 41;

FIG. 43 is a cross-sectional view illustrating the manufacturing process of the semiconductor package in FIG. 41;

FIG. 44 is a plan view showing a semiconductor chip used in the semiconductor package in FIG. 41;

FIG. 45 is a cross-sectional view of the semiconductor chip used in the semiconductor package in FIG. 41 during the manufacturing process thereof;

FIG. 46 is a cross-sectional view of the semiconductor chip during the manufacturing process thereof, which is subsequent to FIG. 45;

FIG. 47 is a cross-sectional view of the semiconductor chip during the manufacturing process thereof, which is subsequent to FIG. 46;

FIG. 48 is a cross-sectional view of the semiconductor chip during the manufacturing process thereof, which is subsequent to FIG. 47;

FIG. 49 is a cross-sectional view of the semiconductor chip during the manufacturing process thereof, which is subsequent to FIG. 48;

FIG. 50 is a cross-sectional view of a semiconductor chip in still another embodiment during the manufacturing process thereof;

FIG. 51 is a cross-sectional view of the semiconductor chip during the manufacturing process thereof, which is subsequent to FIG. 50;

FIG. 52 is a cross-sectional view of the semiconductor chip during the manufacturing process thereof, which is subsequent to FIG. 51;

FIG. 53 is a cross-sectional view of the semiconductor chip during the manufacturing process thereof, which is subsequent to FIG. 52;

FIG. 54 is a cross-sectional view of a semiconductor chip in yet another embodiment during the manufacturing process thereof;

FIG. 55 is a cross-sectional view of the semiconductor chip during the manufacturing process thereof, which is subsequent to FIG. 54;

FIG. 56 is a cross-sectional view of the semiconductor chip during the manufacturing process thereof, which is subsequent to FIG. 55;

FIG. 57 is a cross-sectional view of a semiconductor chip in still another embodiment during the manufacturing process thereof;

FIG. 58 is a cross-sectional view of the semiconductor chip during the manufacturing process thereof, which is subsequent to FIG. 57;

FIG. 59 is a cross-sectional view of the semiconductor chip during the manufacturing process thereof, which is subsequent to FIG. 58;

FIG. 60 is a cross-sectional view of the semiconductor chip during the manufacturing process thereof, which is subsequent to FIG. 59; and

FIG. 61 is a cross-sectional view of the semiconductor chip during the manufacturing process thereof, which is subsequent to FIG. 60.

### DETAILED DESCRIPTION

In each of the following embodiments, if necessary for the sake of convenience, the embodiment will be described by being divided into a plurality of sections or embodiments. However, they are by no means irrelevant to each other unless particularly explicitly described otherwise, but are in relations such that one of the sections or embodiments is a modification, details, supplementary explanation, and so forth of part or the whole of the others. Also, in each of the following embodiments, when the number and the like (including the number, numerical value, amount, range, and the like) of elements are referred to, they are not limited to specific numbers unless particularly explicitly described otherwise or unless they are obviously limited to specific numbers in principle. The number and the like of the elements may be not less than or not more than specific numbers. Also, in each of the following embodiments, it goes without saying that the components thereof (including also elements, steps, and the like) are not necessarily indispensable unless particularly explicitly described otherwise or unless the components are considered to be obviously indispensable in principle. Likewise, in each of the following embodiments, if the shapes, positional relationships, and the like of the components and the like are referred to, the shapes and the like are assumed to include those substantially proximate or similar thereto and the like unless particularly explicitly described otherwise or unless it can be considered that they obviously do not in principle. The same shall apply in regard to the foregoing numerical value and range.

The following will describe the embodiments of the present invention in detail on the basis of the drawings. Note that, throughout all the drawings for illustrating the embodiments, members having the same functions are designated by the same reference numerals, and a repeated description thereof is omitted.

Also, in the drawings used in the following embodiments, hatching may be omitted even in a cross-sectional view for improved clarity of illustration, while even a plan view may be hatched for improved clarity of illustration.

### Embodiment 1

<About Circuit Configuration>

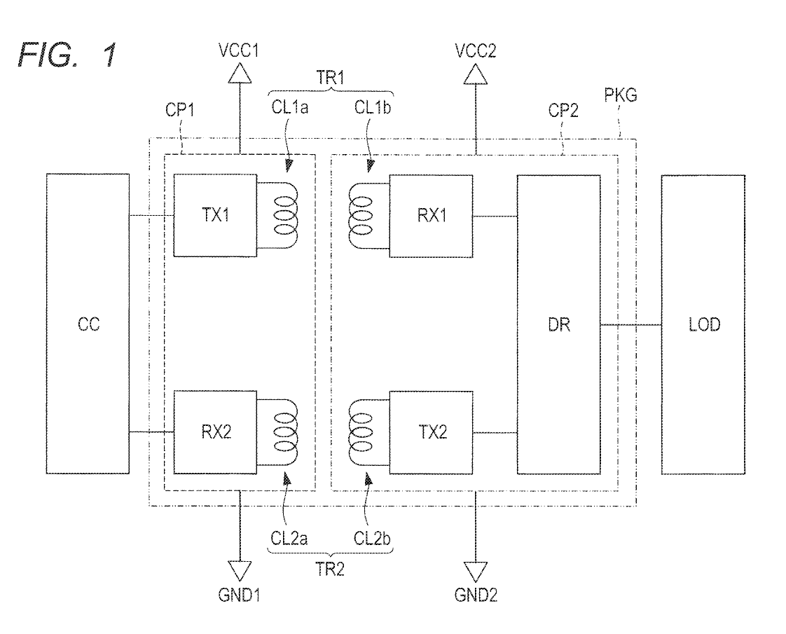

FIG. 1 is a circuit diagram showing an example of an electronic device (semiconductor device) using a semiconductor device in an embodiment. Note that, in FIG. 1, the portion enclosed by the dotted line is formed in a semiconductor chip CP1, the portion enclosed by the dot-dash line is formed in a semiconductor chip CP2, and the portion enclosed by the two-dot-dash line is formed in a semiconductor package PKG.

The electronic device shown in FIG. 1 includes the semiconductor package (semiconductor device) PKG in which the semiconductor chips (semiconductor devices) CP1 and CP2 are embedded. In the semiconductor chip CP1, a transmission circuit TX1 and a reception circuit RX2 are formed. In the semiconductor chip CP2, a reception circuit RX1, a transmission circuit TX2, and a drive circuit DR are formed. The electronic device shown in FIG. 1 also has a control circuit CC. The control circuit CC is formed in another semiconductor chip provided outside the semiconductor package PKG.

The transmission circuit TX1 and the reception circuit RX1 are circuits for transmitting a control signal from the control circuit CC to the drive circuit DR. The transmission circuit TX2 and the reception circuit RX2 are circuits for transmitting a signal from the drive circuit DR to the control circuit CC. The control circuit CC controls the drive circuit DR, while the drive circuit DR drives a load LOD. The load LOD is provided outside the semiconductor package PKG.

The circuits in the semiconductor chip CP1 including the transmission circuit TX1 and the reception circuit RX2 are supplied with a power supply voltage VCC1 and grounded with a ground voltage GND1. The circuits in the semiconductor chip CP2 including the transmission circuit TX2 and the reception circuit RX1 are supplied with a power supply voltage VCC2 and grounded with a ground voltage GND2. The power supply voltages VCC1 and VCC2 may be the same as or different from each other. Likewise, the ground voltages GND1 and GND2 may also be the same as or different from each other.

Between the transmission circuit TX1 and the reception circuit RX1, a transducer (converter) TR1 including magnetically coupled (inductively coupled) coils (inductors) CL1a and CL1b is interposed. A signal can be transmitted from the transmission circuit TX1 to the reception circuit RX1 via the transducer TR1. This allows the control circuit CC to transmit a signal to the drive circuit DR via the transmission circuit TX1, the transducer TR1, and the reception circuit RX1.

Between the transmission circuit TX2 and the reception circuit RX2, a transducer TR2 including magnetically coupled (inductively coupled) coils (inductors) CL2b and CL2a is interposed. A signal can be transmitted from the transmission circuit TX2 to the reception circuit RX2 via the transducer TR2. This allows the drive circuit DR to transmit a signal to the control circuit CC via the transmission circuit TX2, the transducer TR2, and the reception circuit RX2. Each of the coils CL1a, CL1b, CL2b, and CL2a can also be regarded as an inductor. Each of the transducers TR1 and TR2 can also be regarded as a magnetically coupled element.

The transducer TR1 is formed of the coil CL1a formed in the semiconductor chip CP1 and the coil CL1b formed in the semiconductor chip CP2. The coils CL1a and CL1b are not connected via a conductor, but are magnetically coupled to each other. Accordingly, when a current flows in the coil CL1a in the semiconductor chip CP1, an induced electromotive force is generated in the coil CL1b in the semiconductor chip CP2 in response to the current change so that an induced current flows therein. The coil CL1a is a primary coil, while the coil CL1b is a secondary coil. Using the coils CL1a and CL1b, a signal is transmitted from the transmission circuit TX1 to the coil CL1a (primary coil) of the transducer TR1 to allow a current to flow, and the induced current (or induced electromotive force) generated in the coil CL1b (secondary coil) of the transducer TR1 in accordance with the current is sensed (received) by the reception circuit RX1. Thus, the signal corresponding to the signal transmitted by the transmission circuit TX1 can be received by the reception circuit RX1.

The transducer TR2 is formed of the coil CL2b formed in the semiconductor chip CP2 and the coil CL2a formed in the semiconductor chip CP1. The coils CL2b and CL2a are not connected via a conductor, but are magnetically coupled to each other. Accordingly, when a current flows in the coil CL2b in the semiconductor chip CP2, an induced electromotive force is generated in the coil CL2a in the semiconductor chip CP1 in response to the current change so that an induced current flows therein. The coil CL2b is a primary coil, while the coil CL2a is a secondary coil. Using the coils CL2b and CL2a, a signal is transmitted from the transmission circuit TX2 to the coil CL2b (primary coil) of the transducer TR2 to allow a current to flow, and the induced current (or induced electromotive force) generated in the coil CL2a (secondary coil) of the transducer TR2 in accordance with the current is sensed (received) by the reception circuit RX2. Thus, the signal corresponding to the signal transmitted by the transmission circuit TX2 can be received by the reception circuit RX2.

Using a path extending from the transmission circuit TX1 to the reception circuit RX1 via the transducer TR1 and a path extending from the transmission circuit TX2 to the reception circuit RX2 via the transducer TR2, signal transmission/reception is performed between the semiconductor chips CP1 and CP2. The drive circuit DR can drive the load LOD in accordance with the signal transmitted from the transmission circuit TX1 of the semiconductor chip CP1 to the reception circuit RX1 of the semiconductor chip CP2 via the transducer TR1. As the load LOD, various loads can be used depending on an intended purpose. For example, a motor, an inverter for driving a motor, or the like can be used.

The semiconductor chips CP1 and CP2 have different voltage levels (reference potentials). For example, the semiconductor chip CP1 is coupled to a lower voltage region having a circuit (e.g., the control circuit CC) which is operated or driven with a lower voltage (e.g., several to several tens of volts) via wires BW and leads LD each described later or the like. On the other hand, the semiconductor chip CP2 is coupled to a higher voltage region having a circuit (e.g., the load LOD) which is operated or driven with a voltage (e.g., not less than 100 V) higher than the lower voltage via the wires BW and the leads LD each described later or the like. However, since signal transmission between the semiconductor chips CP1 and CP2 is performed via the transducers TR1 and TR2, signal transmission between different-voltage circuits is possible.

In the case shown in FIG. 1, the control circuit CC is embedded in the semiconductor chip other than the semiconductor chips CP1 and CP2. However, in another embodiment, it is also possible to embed the control circuit CC in the semiconductor chip CP1. Also, in the case shown in FIG. 1, the drive circuit DR is embedded in the semiconductor chip CP2. However, in another embodiment, it is also possible to embed the drive circuit DR in a semiconductor chip other than the semiconductor chips CP1 and CP2.

<About Example of Signal Transmission>

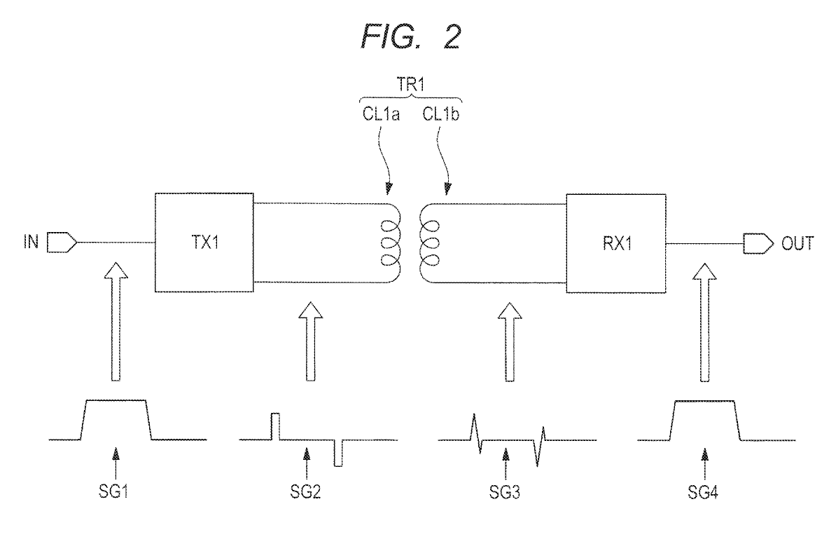

FIG. 2 is an illustrative view showing an example of signal transmission.

The transmission circuit TX extracts an edge portion from a square-wave signal SG1 input to the transmission circuit TX1 to generate a signal SG2 having a given pulse width and transmits the signal SG2 to the coil CL1a (primary coil) of the transducer TR1. When a current resulting from the signal SG2 flows in the coil CL1a (primary coil) of the transducer TR1, a signal SG3 corresponding thereto flows in the coil CL1b (secondary coil) of the transducer TR1 due to an induced electromotive force. The signal SG3 is amplified in the reception circuit RX1 and further modulated into a square wave so that a square-wave signal SG4 is output from the reception circuit RX1. Thus, the signal SG4 corresponding to the signal SG1 input to the transmission circuit TX1 can be output from the reception circuit RX1. In this manner, the signal is transmitted from the transmission circuit TX1 to the reception circuit RX1. Signal transmission from the transmission circuit TX2 to the reception circuit RX2 can also be similarly performed.

In FIG. 2, an example of signal transmission from a transmission circuit to a reception circuit is shown. However, the signal transmission is not limited thereto, but can variously be modified. It is sufficient for the signal transmission to be performed by a method which transmits a signal via magnetically coupled coils (primary and secondary coils).

<About Example of Configuration of Semiconductor Package>

Next, a description will be given of an example of a configuration of the semiconductor package in the present embodiment. Note that the semiconductor package can also be regarded as a semiconductor device.

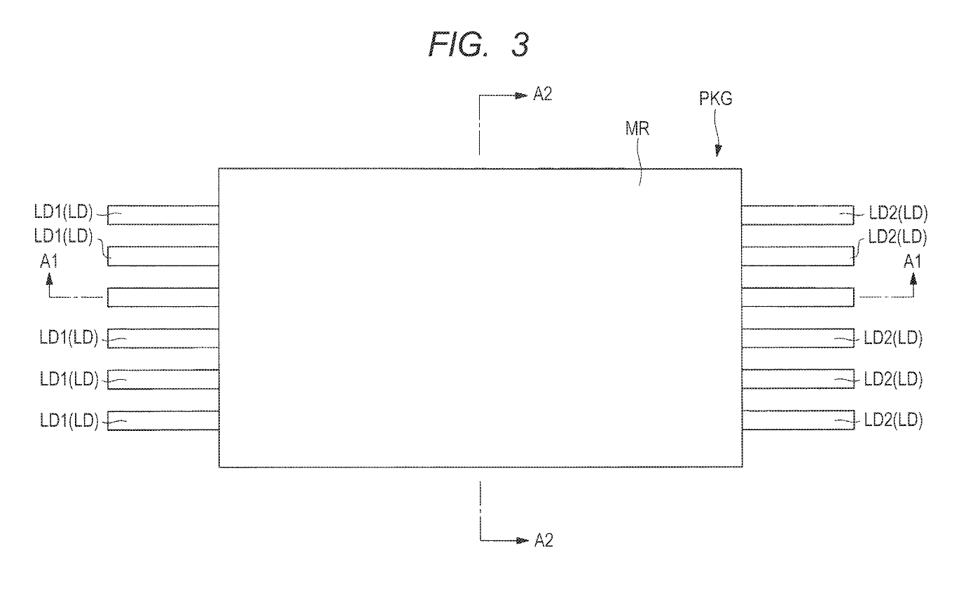

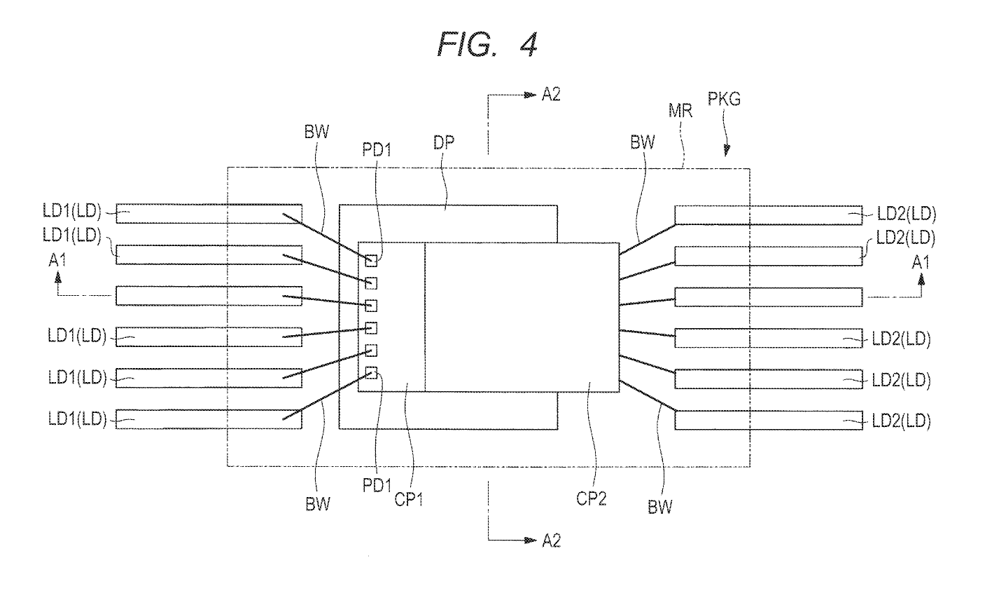

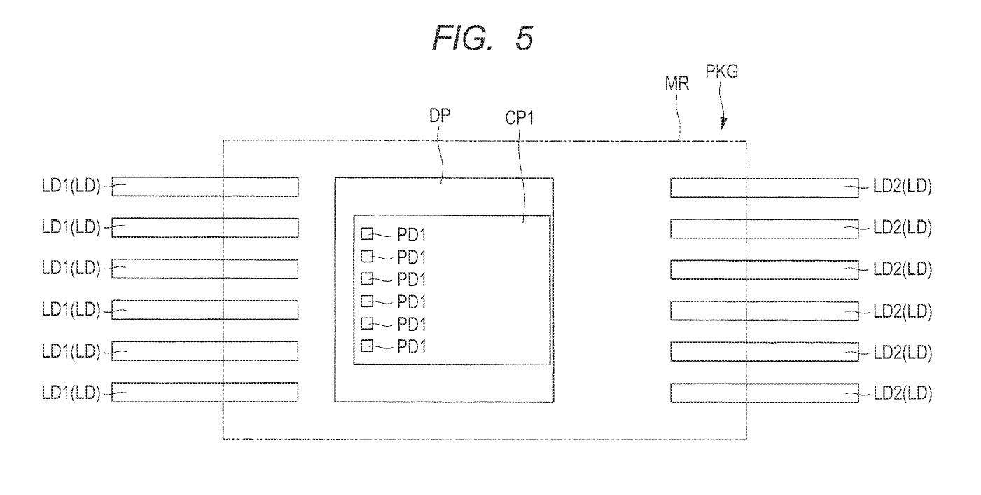

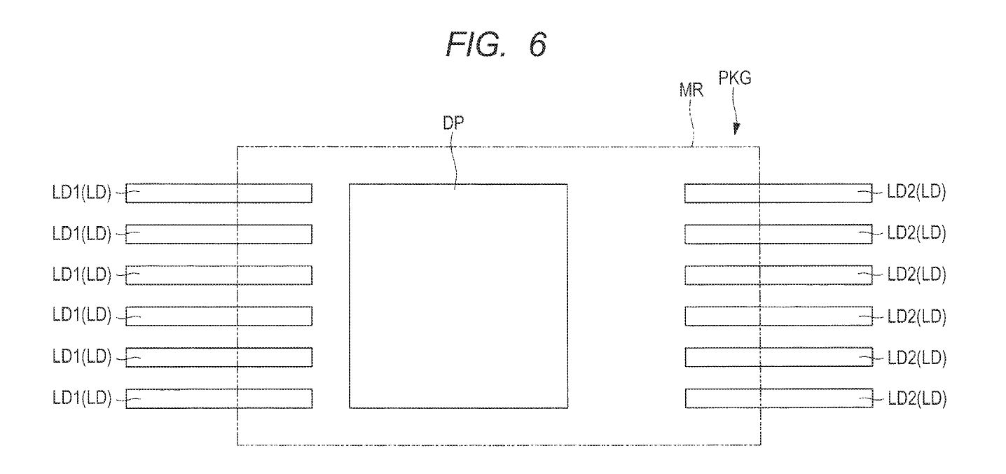

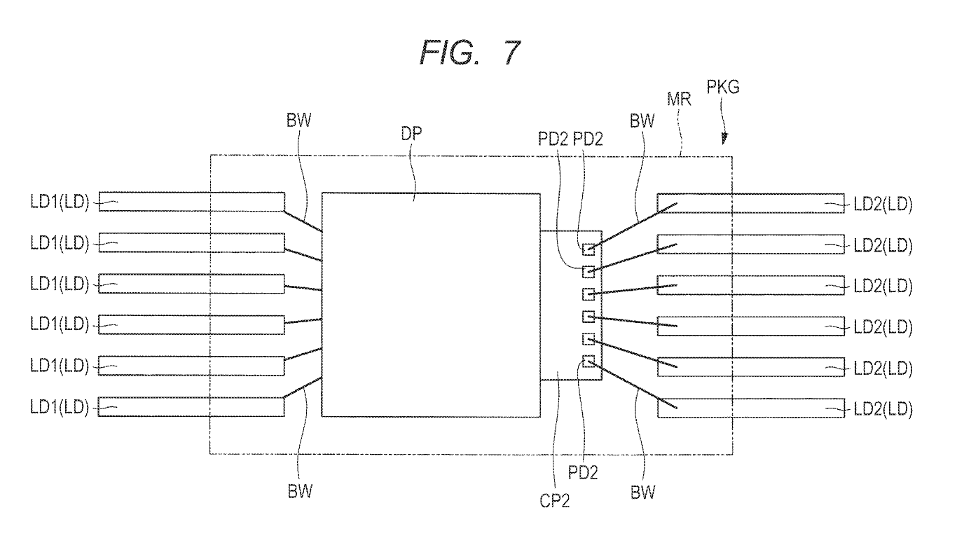

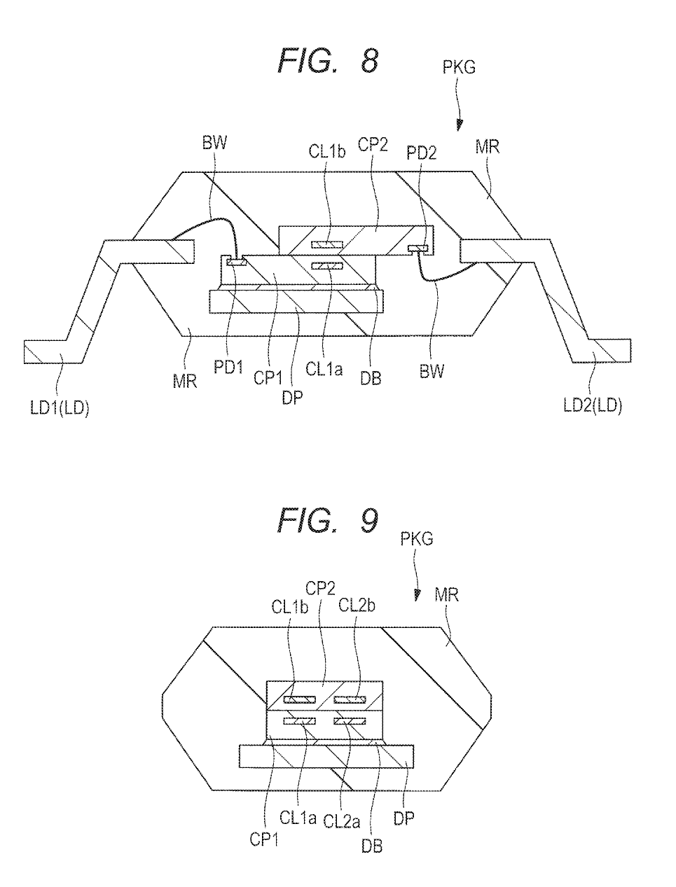

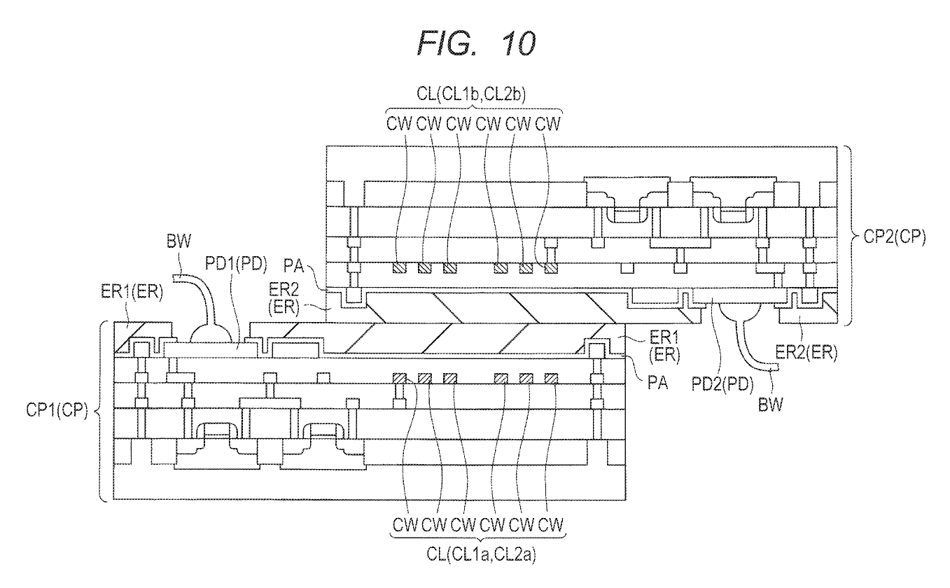

FIGS. 3 to 7 are plan views each showing the semiconductor package (semiconductor device) PKG in the present embodiment. FIGS. 8 and 9 are cross-sectional views each showing the semiconductor package PKG in the present embodiment. Among FIGS. 3 to 7, FIG. 3 is a top view (upper-surface-side plan view) of the semiconductor package PKG. FIGS. 4 to 6 are perspective plan views when the semiconductor package PKG is transparently viewed from over the upper surface thereof. FIG. 7 is a perspective plan view when the semiconductor package PKG is transparently viewed from under the lower surface thereof. In FIG. 4, the semiconductor package PKG is viewed through a sealing resin portion MR, and the outer shape (outer periphery) of the sealing resin portion MR is shown by the two-dot-dash line. FIG. 5 corresponds to a perspective plan view obtained by removing the semiconductor chip CP2 and the wires BW from FIG. 4. FIG. 6 corresponds to a perspective plan view obtained by further removing the semiconductor chip CP1 from FIG. 5. In FIG. 7, in the same manner as in FIG. 4, the semiconductor package PKG is viewed through the sealing resin portion MR, and the outer shape (outer periphery) of the sealing resin portion MR is shown by the two-dot-dash line. However, in FIGS. 7 and 4, the semiconductor package PKG is viewed in opposite directions. A cross-sectional view along the line A1-A1 in FIGS. 3 and 4 substantially corresponds to FIG. 8. A cross-sectional view along the line A2-A2 in FIGS. 3 and 4 substantially corresponds to FIG. 9. FIG. 10 is a partially enlarged cross-sectional view showing a portion of the semiconductor package PKG in FIG. 9 in enlarged relation. Note that, in FIG. 10, for improved clarity of illustration, the illustration of the sealing resin portion MR, a die pad DP, and the leads LD is omitted. FIG. 10 is a cross-sectional view but, for improved clarity of illustration, an insulating film ER (ER1 or ER2) in the semiconductor chip CP1 or CP2 and coil wires CW are hatched, while the hatching of the other portion is omitted.

The semiconductor package PKG shown in FIGS. 3 to 10 includes the semiconductor chips CP1 and CP2. The following will specifically describe a configuration of the semiconductor package PKG.

The semiconductor package PKG shown in FIGS. 3 to 10 includes the semiconductor chips CP1 and CP2, the die pad DP over which the semiconductor chip CP1 is mounted, the plurality of leads LD, the plurality of wires BW coupling the semiconductor chip CP1 to the leads LD and coupling the semiconductor chip CP2 to the leads LD, and the sealing resin portion MR sealing therein the semiconductor chips CP1 and CP2, the die pad DP, the leads LD, and the wires BW.

The sealing resin portion (sealing portion, sealing resin, or sealing body) MR as a sealing portion is made of a resin material such as, e.g., a thermosetting resin material or the like and can also include a filler or the like. By the sealing resin portion MR, the semiconductor chips CP1 and CP2, the die pad DP, the plurality of leads LD, and the plurality of wires BW are sealed and electrically and mechanically protected. The two-dimensional shape (outer shape) of the sealing resin portion MR crossing the thickness thereof can be, e.g., a rectangular shape.

Over a top surface of the semiconductor chip CP1 serving as the main surface of the semiconductor chip CP1 where elements are formed, a plurality of pads (pad electrodes or bonding pads) PD1 are formed. The plurality of pads PD1 are the external coupling terminals of the semiconductor chip CP1. Each of the pads PD1 of the semiconductor chip CP1 is electrically coupled to a semiconductor integrated circuit (such as, e.g., the foregoing transmission circuit TX1 or the foregoing reception circuit RX2) formed in the semiconductor chip CP1.

Over a top surface of the semiconductor chip CP2 serving as the main surface of the semiconductor chip CP2 where elements are formed, a plurality of pads PD2 are formed. The plurality of pads PD2 are the external coupling terminals of the semiconductor chip CP2. Each of the pads PD2 of the semiconductor chip CP2 is electrically coupled to a semiconductor integrated circuit (such as, e.g., the foregoing transmission circuit TX2, the foregoing reception circuit RX1, or the foregoing drive circuit DR) formed in the semiconductor chip CP2.

Note that, of the semiconductor chip CP1, the main surface where the pads PD1 are formed is referred to as the top surface of the semiconductor chip CP1 and the main surface opposite thereto is referred to as a back surface of the semiconductor chip CP1. Also, of the semiconductor chip CP2, the main surface where the pads PD2 are formed is referred to as the top surface of the semiconductor chip CP2 and the main surface opposite thereto is referred to as a back surface of the semiconductor chip CP2. Each of the top surfaces of the semiconductor chips CP1 and CP2 is formed mainly of the upper surface of insulating film ER.

The insulating film ER of the semiconductor chip CP1 which forms the top surface of the semiconductor chip CP1 is designated by the reference numeral ER1 and referred to as the insulating film ER1, while the insulating film ER of the semiconductor chip CP2 which forms the top surface of the semiconductor chip CP2 is designated by the reference numeral ER2 and referred to as the insulating film ER2.

The semiconductor chip CP1 is mounted (placed) over the upper surface of the die pad DP as a chip mounting portion such that the top surface of the semiconductor chip CP1 faces upward and the back surface of the semiconductor chip CP1 faces the upper surface of the die pad DP. The back surface of the semiconductor chip CP1 is bonded and fixed to the upper surface of the die pad DP via a die bonding material (adhesive material) DB.

The semiconductor chip CP2 is mounted (placed) over and fixed to the top surface of the semiconductor chip CP1 such that the top surface of the semiconductor chip CP2 faces the top surface of the semiconductor chip CP1. That is, the semiconductor chip CP2 is mounted (placed) over the top surface of the semiconductor chip CP1 such that the top surface of the semiconductor chip CP2 faces the top surface of the semiconductor chip CP1 and the back surface of the semiconductor chip CP2 faces upward. Since the top surface of the semiconductor chip CP1 and the top surface of the semiconductor chip CP2 face each other, the upper surface of the insulating film ER1 of the semiconductor chip CP1 and the upper surface of the insulating film ER2 of the semiconductor chip CP2 face each other and are in contact with each other.

The insulating film ER1 of the semiconductor chip CP1 and the insulating film ER2 of the semiconductor chip CP2 are each made of a resin film (photosensitive resin film) having an adhesive property, though the details thereof will be described later. Since the semiconductor chip CP2 is thus placed over the semiconductor chip CP1 such that the insulating film ER1 of the semiconductor chip CP1 and the insulating film ER2 of the semiconductor chip CP2 face each other and are in contact with each other, the insulating film ER2 of the semiconductor chip CP2 is bonded and fixed to the insulating film ER1 of the semiconductor chip CP1. As a result, the semiconductor chip CP2 is bonded and fixed to the semiconductor chip CP1. Accordingly, each of the insulating film ER1 of the semiconductor chip CP1 and the insulating film ER2 of the semiconductor chip CP2 also has the function of bonding or fixing the semiconductor chips CP1 and CP2 to each other.

In plan view, the semiconductor chips CP1 and CP2 partially overlap each other. That is, in plan view, the entire top surface of the semiconductor chip CP1 does not overlap the semiconductor chip CP2, and the entire top surface of the semiconductor chip CP2 does not overlap the semiconductor chip CP1. The semiconductor chip CP1 has a region overlapping the semiconductor chip CP2 and a region not overlapping the semiconductor chip CP2 in plan view.

Also, the semiconductor chip CP2 has a region overlapping the semiconductor chip CP1 and a region not overlapping the semiconductor chip CP1 in plan view. Note that the wording “in plan view” corresponds to the case where an object is viewed in a plane generally parallel with the main surface of the semiconductor chip, the main surface of the semiconductor chip CP2, or both of the respective main surfaces of the semiconductor chips CP1 and CP2.

Note that the region of the semiconductor chip CP1 overlapping the semiconductor chip CP2 in plan view can also be regarded as the region thereof facing the semiconductor chip CP2. The region of the semiconductor chip CP1 not overlapping the semiconductor chip CP2 in plan view can also be regarded as the region thereof not facing the semiconductor chip CP2. The region of the semiconductor chip CP2 overlapping the semiconductor chip CP1 in plan view can also be regarded as the region thereof facing the semiconductor chip CP1. The region of the semiconductor chip CP2 not overlapping the semiconductor chip CP1 in plan view can also be regarded as the region thereof not facing the semiconductor chip CP1.

The semiconductor chip CP1 has the plurality of pads PD1 which are disposed over the region of the top surface of the semiconductor chip CP1 not overlapping the semiconductor chip CP2 in plan view. Consequently, the plurality of pads PD1 provided over the semiconductor chip CP1 are not covered with the semiconductor chip CP2. On the other hand, the semiconductor chip CP2 has the plurality of pads PD2 which are disposed over the region of the top surface of the semiconductor chip CP2 not overlapping the semiconductor chip CP1 in plan view. Consequently, the plurality of pads PD2 provided over the semiconductor chip CP2 are not covered with the semiconductor chip CP1.

Since the plurality of pads PD1 of the semiconductor chip CP1 do not overlap the semiconductor chip CP2, the wires BW can be coupled to the pads PD1. Also, since the plurality of pads PD2 of the semiconductor chip CP2 do not overlap the semiconductor chip CP1, the wires BW can be coupled to the pads PD2.

The leads LD are each formed of a conductor. Preferably, the leads LD are made of a metal material such as copper (Cu) or a copper alloy. Each of the leads LD includes an inner lead portion as the portion of the lead LD which is located in the sealing resin portion MR and an outer lead portion as the portion of the lead LD which is located outside the sealing resin portion MR. The outer lead portion of the lead LD protrudes from the side surface of the sealing resin portion MR to the outside of the sealing resin portion MR. The spaces between the inner lead portions of the adjacent leads LD are filled with the material forming the sealing resin portion MR. The outer lead portion of each of the leads LD can function as the external coupling terminal portion (external terminal) of the semiconductor package PKG. The outer lead portion of each of the leads LD has been bent such that the lower surface of the outer lead portion in the vicinity of the end portion thereof is located slightly below the lower surface of the sealing resin portion MR.

In another form, it is also possible not to bend the outer lead portion of each of the leads LD. In that case, the outer lead portion of each of the leads LD is allowed to protrude from the side surface of the sealing resin portion MR and extend in a direction parallel with the lower or upper surface of the sealing resin portion MR.

The pads PD1 over the top surface of the semiconductor chip CP1 and the pads PD2 over the top surface of the semiconductor chip CP2 are electrically coupled to the respective inner lead portions of the leads LD via the wires BW each as a conductive coupling member.

It is assumed herein that, of the plurality of leads LD of the semiconductor package PKG, the leads LD electrically coupled to the pads PD1 of the semiconductor chip CP1 via the wires BW are each designated by a reference numeral LD1 and referred to as the leads LD1. It is also assumed that, of the plurality of leads LD of the semiconductor package PKG, the leads LD electrically coupled to the pads PD2 of the semiconductor chip CP2 via the wires BW are each designated by a reference numeral LD2 and referred to as the leads LD2.

That is, the pads PD1 over the top surface of the semiconductor chip CP1 are electrically coupled to the respective inner lead portions of the leads LD1 via the wires BW, while the pads PD2 over the top surface of the semiconductor chip CP2 are electrically coupled to the respective inner lead portions of the leads LD2 via the wires BW. In short, the wires BW having one ends coupled to the individual pads PD1 over the top surface of the semiconductor chip CP1 have the other ends coupled to the respective upper surfaces of the inner lead portions of the leads LD1. Also, the wires BW having one ends coupled to the individual pads PD2 over the top surface of the semiconductor chip CP2 have the other ends coupled to the respective lower surfaces of the inner lead portions of the leads LD2.

Note that the leads LD1 coupled to the pads PD1 of the semiconductor chip CP1 via the wires BW are different from the leads LD2 coupled to the pads PD2 of the semiconductor chip CP2 via the wires BW. The pads PD1 of the semiconductor chip CP1 are not coupled to the pads PD2 of the semiconductor chip CP2 via the wires BW. Thus, the pads PD1 of the semiconductor chip CP1 are not coupled to the pads PD2 of the semiconductor chip CP2 via conductors.

In the rectangle (quadrilateral) forming the two-dimensional shape of the sealing resin portion MR, the plurality of leads LD1 and the plurality of leads LD2 are arranged along the sides (side surfaces) opposite to each other.

The wires (bonding wires) BW are the conductive coupling members (members for coupling). More specifically, the wires BW are conductive wires and made of metal wires (metal thin wires) such as, e.g., gold (Au) wires or copper (Cu) wires. The wires BW are sealed in the sealing resin portion MR and are not exposed from the sealing resin portion MR.

As described above, the semiconductor chip CP1 and the semiconductor chip CP2 are stacked such that the insulating film ER1 of the semiconductor chip CP1 and the insulating film ER2 of the semiconductor chip CP2 face each other and are in contact with each other. In the semiconductor chip CP1, the coils CL1a and CL2a described above are formed while, in the semiconductor chip CP2, the coils CL1b and CL2b described above are formed. The coil CL1a formed in the semiconductor chip CP1 and the coil CL1b formed in the semiconductor chip CP2 overlap each other in plan view. The coil CL2a formed in the semiconductor chip CP1 and the coil CL2b formed in the semiconductor chip CP2 overlap each other in plan view. That is, the semiconductor chip CP1 and the semiconductor chip CP2 are stacked such that the coil CL1a formed in the semiconductor chip CP1 and the coil CL1b formed in the semiconductor chip CP2 face each other and the coil CL2a formed in the semiconductor chip CP1 and the coil CL2b formed in the semiconductor chip CP2 face each other.

The coil CL1a formed in the semiconductor chip CP1 and the coil CL1b formed in the semiconductor chip CP2 are magnetically coupled (inductively coupled) to each other to form the foregoing transducer TR1. The coil CL2a formed in the semiconductor chip CP1 and the coil CL2b formed in the semiconductor chip CP2 are magnetically coupled (inductively coupled) to each other to form the foregoing transducer TR2. Between the coil CL1a in the semiconductor chip CP1 and the coil CL1b in the semiconductor chip CP2, the plurality of insulating films (including the insulating film ER1) of the semiconductor chip CP1 and the plurality of insulating films (including the insulating film ER2) of the semiconductor chip CP2 are interposed. Likewise, between the coil CL2a in the semiconductor chip CP1 and the coil CL2b in the semiconductor chip CP2, the plurality of insulating films (including the insulating films ER1 and PA) of the semiconductor chip CP1 and the plurality of insulating films (including the insulating films ER2 and PA) of the semiconductor chip CP2 are interposed. Consequently, the coil CL1a in the semiconductor chip CP1 and the coil CL1b in the semiconductor chip CP2 are not connected via a conductor. Also, the coil CL2a in the semiconductor chip CP1 and the coil CL2b in the semiconductor chip CP2 are not connected via a conductor.

The transmission of an electric signal between the semiconductor chips CP1 and CP2 is performed only via the transducers TR1 and TR2. That is, only the signal transmitted from the circuit formed in the semiconductor chip CP1 by electromagnetic induction via the coil CL1a in the semiconductor chip CP1 and the coil CL1b in the semiconductor chip CP2 is transmitted to the semiconductor chip CP2. Also, only the signal transmitted from the circuit formed in the semiconductor chip CP2 by electromagnetic induction via the coil CL2b in the semiconductor chip CP2 and the coil CL2a in the semiconductor chip CP1 is transmitted to the semiconductor chip CP1.

<About Manufacturing Process of Semiconductor Package>

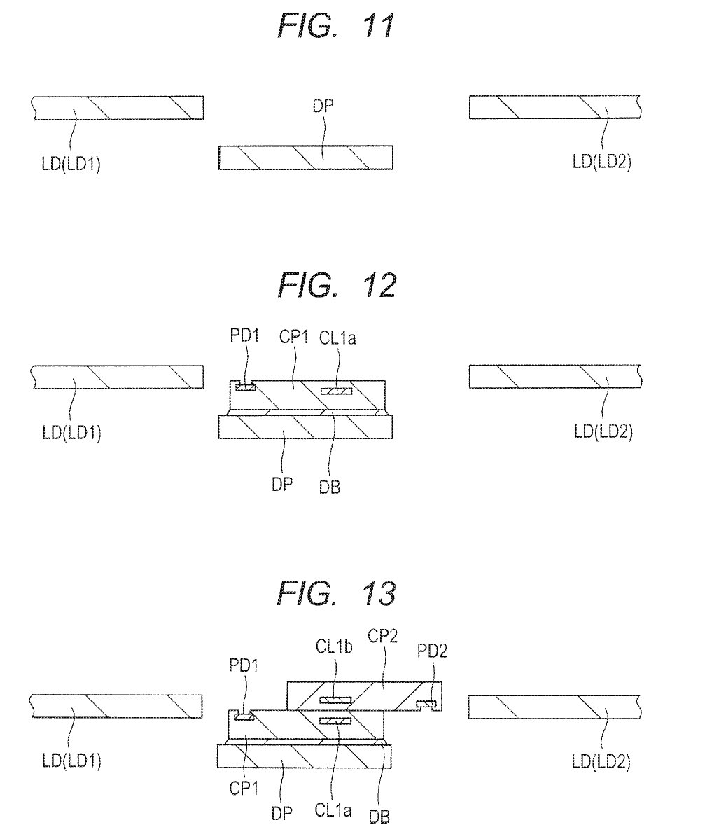

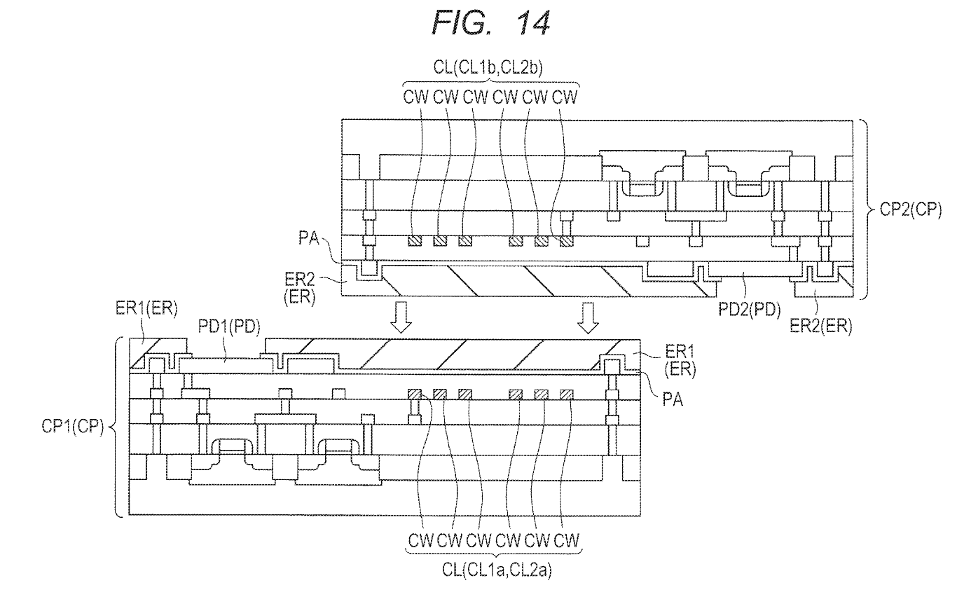

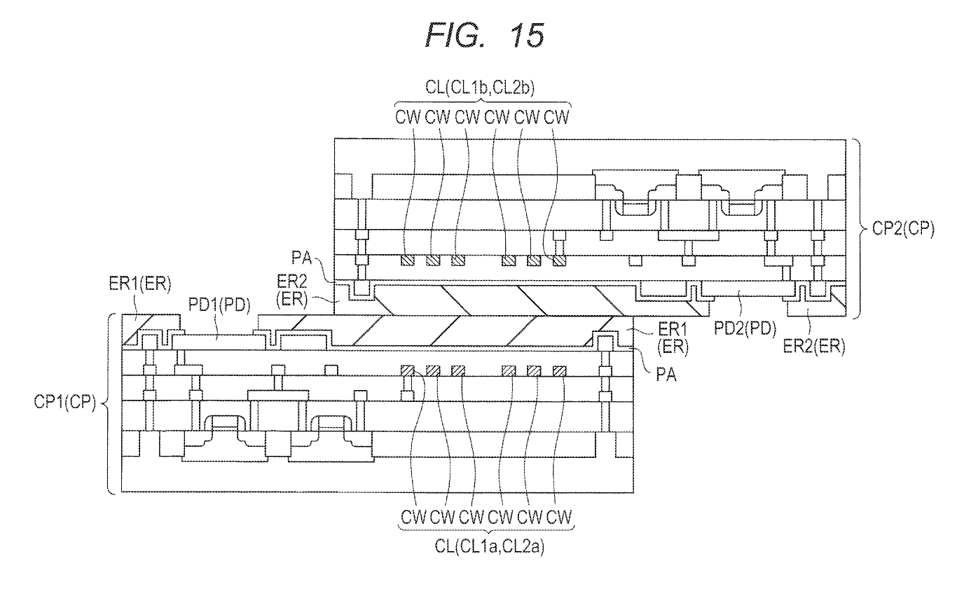

Next, referring to FIGS. 11 to 18, a description will be given of an example of the manufacturing process of the semiconductor package PKG. FIGS. 11 to 13 and 16 to 18 are cross-sectional views of the semiconductor package PKG during the manufacturing process thereof and shows cross sections corresponding to FIG. 8 described above. FIGS. 14 and 15 are cross-sectional views illustrating the step (step of stacking the semiconductor chips CP1 and CP2) in FIG. 13 and shows a cross section corresponding to FIG. 10 described above.

For example, the semiconductor package PKG can be manufactured as follows.

That is, first, as shown in FIG. 11, a lead frame in which the die pad DP and the plurality of leads LD are connected to a framework is provided (prepared). Also, the semiconductor chip CP1 and the semiconductor chip CP2 are provided (prepared). The manufacturing process (provision process) of the semiconductor chips CP1 and CP2 will be described later in greater detail.

Next, as shown in FIG. 12, a die bonding step is performed to mount the semiconductor chip CP1 over the die pad DP of the lead frame via the die bonding material (adhesive material) DB and bond the semiconductor chip CP1 thereto. At this time, the back surface of the semiconductor chip CP1 is bonded to the upper surface of the die pad DP using the die bonding material DB such that the back surface of the semiconductor chip CP1 faces the upper surface of the die pad DP. This achieves a state in which the semiconductor chip CP1 is mounted over and fixed to the die pad DP as the chip mounting portion.

Next, as shown in FIG. 13, the semiconductor chip CP2 is mounted over and fixed to the top surface of the semiconductor chip CP1 such that the top surface of the semiconductor chip CP2 faces the top surface of the semiconductor chip CP1, i.e., the insulating film ER2 of the semiconductor chip CP2 faces the insulating film ER1 of the semiconductor chip CP1. This achieves a state in which the semiconductor chip CP1 and the semiconductor chip CP2 are stacked, and the coils (CL1a and CL2a) in the semiconductor chip CP1 and the coils (CL1b and CL2b) in the semiconductor chip CP2 are magnetically coupled to each other.

Each of the insulating film ER1 of the semiconductor chip CP1 and the insulating film ER2 of the semiconductor chip CP2 has an adhesive property. Accordingly, in the step in FIG. 13, as shown in FIGS. 14 and 15, the semiconductor chip CP2 is placed (mounted) over the semiconductor chip CP1 such that the insulating film ER2 (the upper surface thereof) of the semiconductor chip CP2 and the insulating film ER1 (the upper surface thereof) of the semiconductor chip CP1 face each other and are in contact with each other. Consequently, the insulating film ER2 of the semiconductor chip CP2 is bonded and fixed to the insulating film ER1 of the semiconductor chip CP1. This allows the semiconductor chip CP2 to be bonded and fixed to the semiconductor chip CP1. Accordingly, each of the insulating film ER1 of the semiconductor chip CP1 and the insulating film ER2 of the semiconductor chip CP2 also has the function of bonding or fixing the semiconductor chips CP1 and CP2 to each other. That is, since each of the insulating film ER1 of the semiconductor chip CP1 and the insulating film ER2 of the semiconductor chip CP2 has an adhesive property, the semiconductor chip CP1 and the semiconductor chip CP2 can be bonded together such that the insulating film ER1 of the semiconductor chip CP1 and the insulating film ER2 of the semiconductor chip CP2 face each other.

The description has been given heretofore of the case where the semiconductor chip CP1 is mounted over the die pad DP of the lead frame via the die bonding material DB and then the semiconductor chip CP2 is mounted over the semiconductor chip CP1 mounted over the die pad DP. In other words, the description has been given of the case where, prior to the step of stacking the semiconductor chips CP1 and CP2, the semiconductor chip CP1 is mounted over the die pad DP. In another embodiment, there may also be a case in which, after the step of stacking the semiconductor chips CP1 and CP2, the semiconductor chip CP1 is mounted over the die pad DP. In this case, after the semiconductor chip CP1 and the semiconductor chip CP2 are bonded together such that the insulating film ER1 of the semiconductor chip CP1 and the insulating film ER2 of the semiconductor chip CP2 face each other, the semiconductor chip CP1 bonded to the semiconductor chip CP2 is mounted over the die pad DP of the lead frame via the die bonding material DB. It is possible to bond the back surface of the semiconductor chip CP1 bonded to the semiconductor chip CP2 to the die pad DP of the lead frame via the die bonding material DB.

The step in FIG. 13 can be regarded as the step of stacking the semiconductor chips CP1 and CP2. In the step in FIG. 13, the semiconductor chips CP1 and CP2 are stacked such that the insulating film ER1 of the semiconductor chip CP1 and the insulating film ER2 of the semiconductor chip CP2 come in contact with each other. At this time, the semiconductor chips CP1 and CP2 are stacked such that the coils (CL1a and CL2a) in the semiconductor chip CP1 and the coils (CL1b and CL2b) in the semiconductor chip CP2 are magnetically coupled to each other. Since the adhesive property of each of the insulating films ER1 and ER2 of the semiconductor chips CP1 and CP2 is necessary when the step in FIG. 13 is performed, each of the insulating films ER1 and ER2 of the semiconductor chips CP1 and CP2 holds the adhesive property until the step in FIG. 13 is performed.

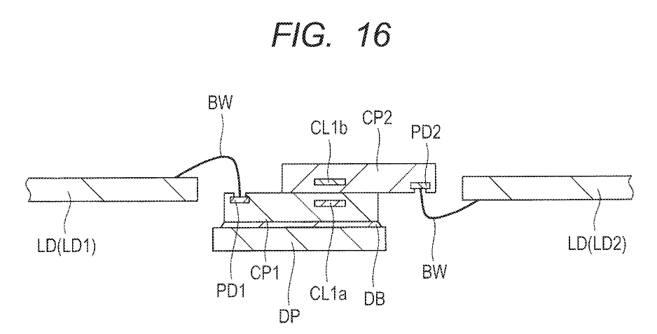

Next, as shown in FIG. 16, a wire bonding step is performed to couple the plurality of pads PD1 and PD2 of the semiconductor chips CP1 and CP2 to the plurality of leads LD with the plurality of wires (conductive coupling members) BW. At this time, it is appropriate to, e.g., couple the plurality of pads PD1 over the top surface of the semiconductor chip CP1 to the plurality of leads LD1 via the plurality of wires BW, then invert the lead frame, and couple the plurality of pads PD2 over the top surface of the semiconductor chip CP2 to the plurality of leads LD2 via the plurality of wires BW. Alternatively, it is also possible to reverse the order in which wire bonding is performed on the semiconductor chips CP1 and CP2 by first coupling the plurality of pads PD2 over the top surface of the semiconductor chip CP2 to the plurality of leads LD2 via the plurality of wires BW and then coupling the plurality of pads PD1 over the top surface of the semiconductor chip CP1 to the plurality of leads LD1 via the plurality of wires BW. By performing the wire bonding step, the plurality of pads PD1 of the semiconductor chip CP1 are electrically coupled to the plurality of leads LD1 via the plurality of wires BW, and the plurality of pads PD2 of the semiconductor chip CP2 are electrically coupled to the plurality of leads LD2 via the plurality of other wires BW. In the wire bonding step also, a state in which the insulating film ER2 of the semiconductor chip CP2 is bonded and fixed to the insulating film ER1 of the semiconductor chip CP1 is maintained.

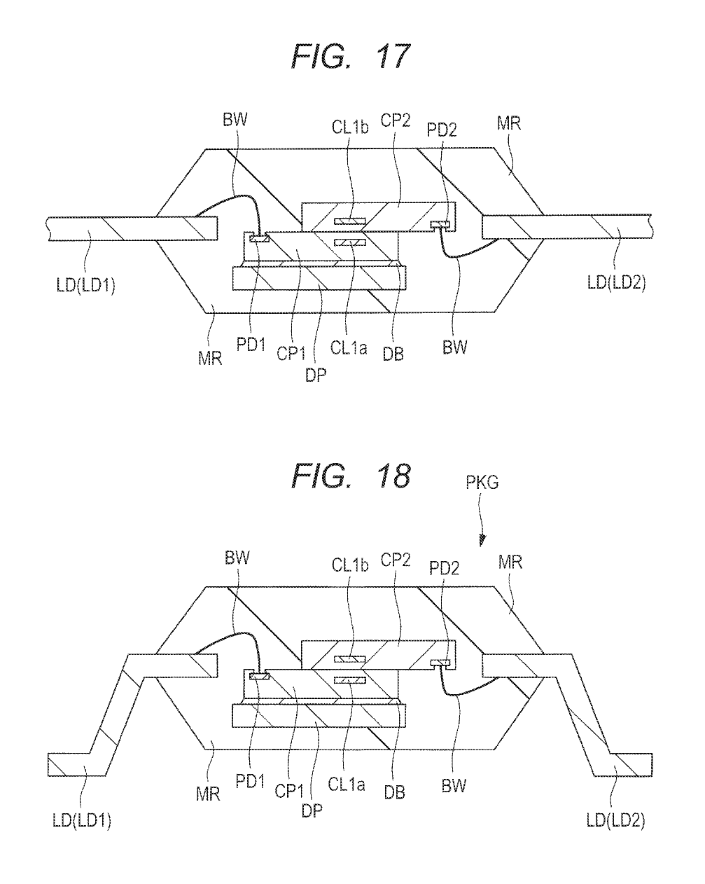

Next, as shown in FIG. 17, a resin sealing step is performed to form the sealing resin portion MR sealing therein the semiconductor chips CP1 and CP2, the die pad DP, the plurality of leads LD, and the plurality of wires BW.

Until the sealing resin portion MR is formed, the semiconductor chip CP2 has been fixed to the semiconductor chip CP1 owing to the adhesive property of each of the insulating films ER1 and ER2 of the semiconductor chips CP1 and CP2. However, when the sealing resin portion MR is formed, the sealing resin portion MR allows the semiconductor chips CP1 and CP2 to be fixed to each other.

Next, the plurality of leads LD having the respective inner lead portions sealed in the sealing resin portion MR are cut from the framework of the lead frame. Then, as shown in FIG. 18, the outer lead portions of the plurality of leads LD are subjected to bending. In this manner, the semiconductor package PKG can be manufactured. There may also be a case in which the bending of the leads LD is not performed. Each of the leads LD has at least one portion exposed from the sealing resin portion MR to function as the external terminal of the semiconductor package PKG.

Note that the description has been given heretofore of the case where the semiconductor chip CP1 is mounted over the die pad DP in the semiconductor package PKG. However, in another form, it is also possible to switch the semiconductor chips CP1 and CP2 to each other in the semiconductor package PKG. In that case, over the die pad DP, the semiconductor chip CP2 is mounted.

Also, the description has been given heretofore of the case where, by way of example, the package form of the semiconductor package PKG is a SOP (Small Outline Package). However, the semiconductor package PKG is also applicable to a package form other than the SOP.

In either case, the manufacturing process of the semiconductor package includes the step of providing the semiconductor chip CP1, the step of providing the semiconductor chip CP2, and stacking the semiconductor chips CP1 and CP2.

<About Electronic System Using Semiconductor Device>

Examples of the applications of a product in which the semiconductor package PKG is mounted include the motor control unit of an automobile or a household electrical appliance such as a washer, a switching power supply, an illumination controller, a solar power generation controller, a mobile phone, and a mobile communication device.

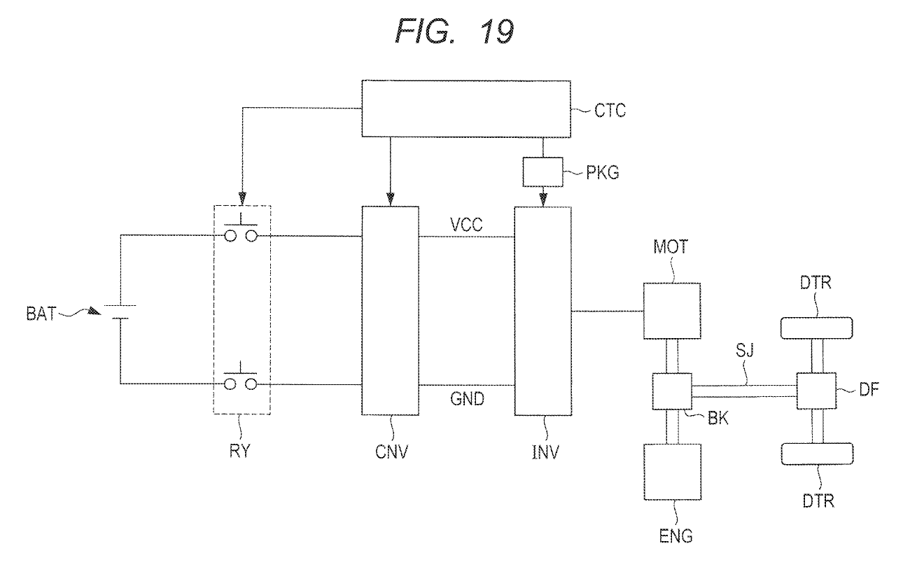

A description will be given herein of an electric automobile system as an example of an electronic system (electronic device) using the semiconductor package PKG in the present embodiment. FIG. 19 is an illustrative view (circuit block diagram) showing an example of the electronic system (electronic device) using the semiconductor package PKG in the present embodiment, which is the electric automobile system herein.

The electronic system (which is the electric automobile system herein) shown in FIG. 19 has a load such as a motor MOT, an inverter (inverter circuit) INV, a power supply BAT, and a control unit (control circuit or controller) CTC. As the motor MOT, e.g., a 3-phase motor or the like can be used. The foregoing semiconductor package PKG is coupled between the control unit CTC and the inverter INV.

In the electronic system in FIG. 19, the power supply BAT is coupled to the inverter INV via a relay RY and a converter CNV such that the voltage (power) of the power supply BAT is supplied to the inverter INV. Since the converter CNV is interposed between the power supply BAT and the inverter INV, the voltage (dc voltage) of the power supply BAT is converted (boosted) to a voltage appropriate for driving the motor in the converter CNV and then supplied to the inverter INV. The relay RY is interposed between the power supply BAT and the converter CNV to be able to switch the state between the power supply BAT and the converter CNV between a coupled state and a non-coupled state.

To the inverter INV, the control unit CTC is coupled via the semiconductor package PKG to be able to control the inverter INV. To the inverter INV, the motor MOT is also coupled. The dc voltage (dc power) supplied from the power supply BAT to the inverter INV via the converter CNV is converted to an ac voltage (ac power) by the inverter INV controlled by the control unit CTC and supplied to the motor MOT to be able to drive the motor MOT. The motor MOT can rotate the tires of an automobile or the like.

For example, in the case of a hybrid automobile, the output shaft of the motor MOT and the output shaft of the engine ENG are combined with each other in a power distribution mechanism BK and the torque thereof is transmitted to an axle SJ. The axle SJ operates in association with a drive wheel DTR via differentials DF. In such a case as where a large drive force is required, the motor MOT is driven in conjunction with the engine ENG. The output torques thereof are combined in the power distribution mechanism BK and transmitted to the drive wheel DTR via the axle SJ to drive the drive wheel DTR. In such a case as where the required drive force is not so large (such as, e.g., when the automobile runs at a given speed), it is possible to stop the engine ENG and drive the drive wheel DTR only with the motor MOT. In the case of a hybrid automobile, the engine ENG is also needed in addition to the motor MOT. However, in the case of an electric automobile having no engine, the engine ENG can be omitted.

The control unit CTC is formed of, e.g., an ECU (Electronic Control Unit) and has an embedded control semiconductor chip such as an MCU (Micro Controller Unit). The relay RY and the converter CNV can also be controlled by the control unit CTC.

However, the control unit CTC and the inverter INV do not directly perform signal transmission therebetween. Between the control unit CTC and the inverter INV, the foregoing semiconductor package PKG is interposed. That is, the signal transmission between the control unit CTC and the inverter INV is performed via the semiconductor package PKG. In the electronic system in FIG. 19, the foregoing control circuit CC in FIG. 1 described above corresponds to the control unit CTC in FIG. 19, and the foregoing load LOD in FIG. 1 described above corresponds to the inverter INV in FIG. 19. The foregoing leads LD1 of the semiconductor package PKG are coupled to the control unit CTC, and the foregoing leads LD2 of the semiconductor package PKG are coupled to the inverter INV. When the foregoing drive circuit DR in FIG. 1 described above is embedded in the semiconductor chip outside the semiconductor package PKG, it follows that the semiconductor chip (semiconductor chip having the embedded drive circuit DR) is interposed between the semiconductor package PKG and the inverter INV in FIG. 19. In response to the signal (control signal) transmitted from the control unit CTC to the drive circuit DR via the foregoing transmission circuit TX1, the foregoing transducer TR1, and the foregoing reception circuit RX1, the drive circuit DR outputs a signal for controlling or driving the inverter INV and the signal is input to the inverter INV. The control unit CTC can control the inverter INV via the semiconductor package PKG.

The inverter INV has power semiconductor elements (power transistors). Examples of the power semiconductor elements include IGBTs (Insulated Gate Bipolar Transistors) and the like. For example, in the case where the motor MOT is a 3-phase motor, the inverter INV has six IGBTs corresponding to the three phases. To each of the power semiconductor elements of the inverter INV, a signal is input from the drive circuit DR. In the case where the power semiconductor elements are IGBTs, the signal from the drive circuit DR is input to the gate electrode of each of the IGBTs. The control unit CTC controls the turning ON/OFF of the power semiconductor elements of the inverter INV via the semiconductor package PKG and can thus control the inerter INV and drive the motor MOT.

As described above, the semiconductor package PKG has the foregoing semiconductor chips CP1 and CP2 embedded therein, but the semiconductor chips CP1 and CP2 have different voltage levels (reference potentials). For example, to drive or control the inverter INV, the drive circuit DR is coupled to the inverter INV, and the reference potential (voltage level) of the semiconductor chip CP2 may rise to a voltage substantially equal to the power supply voltage VCC of the inverter INV to be driven. The power supply voltage VCC is considerably high (e.g., about several hundreds of volts to several thousands of volts). The same applies also to the case where the drive circuit DR is embedded in a semiconductor chip other than the semiconductor chip CP2. This produces a large voltage level (reference potential) difference between the semiconductor chips CP1 and CP2. That is, to the semiconductor chip CP2, a voltage (e.g., about several hundreds of volts to several thousands of volts) higher than the power supply voltage (e.g., about several volts to several tens of volts) supplied to the semiconductor chip CP1 may be supplied from the inverter INV.

However, as described above, what is electrically transmitted between the semiconductor chips CP1 and CP2 is the signal transmitted from the primary coil (CL1a) in the semiconductor chip CP1 to the secondary coil (CL1b) in the semiconductor chip CP2 by electromagnetic induction or the signal transmitted from the primary coil (CL2b) in the semiconductor chip CP2 to the secondary coil (CL2a) in the semiconductor chip CP1 by electromagnetic induction. Accordingly, even when the respective voltage levels (reference potentials) of the semiconductor chips CP1 and CP2 are different, it is possible to reliably prevent the voltage level (reference potential) of the semiconductor chip CP2 from being input to the semiconductor chip CP1 or prevent the voltage level (reference potential) of the semiconductor chip CP1 from being input to the semiconductor chip CP2. That is, even when the reference potential (voltage level) of the semiconductor chip CP2 has risen to a voltage substantially equal to the power supply voltage VCC (e.g., several hundreds of volts to several thousands of volts) of the inverter INV to be driven, it is possible to reliably prevent the reference potential of the semiconductor chip CP2 from being input to the semiconductor chip CP1. Therefore, it is possible to reliably transmit an electric signal between the semiconductor chips CP1 and CP2 having the different voltage levels (reference potentials).

<About Structure of Semiconductor Chip>

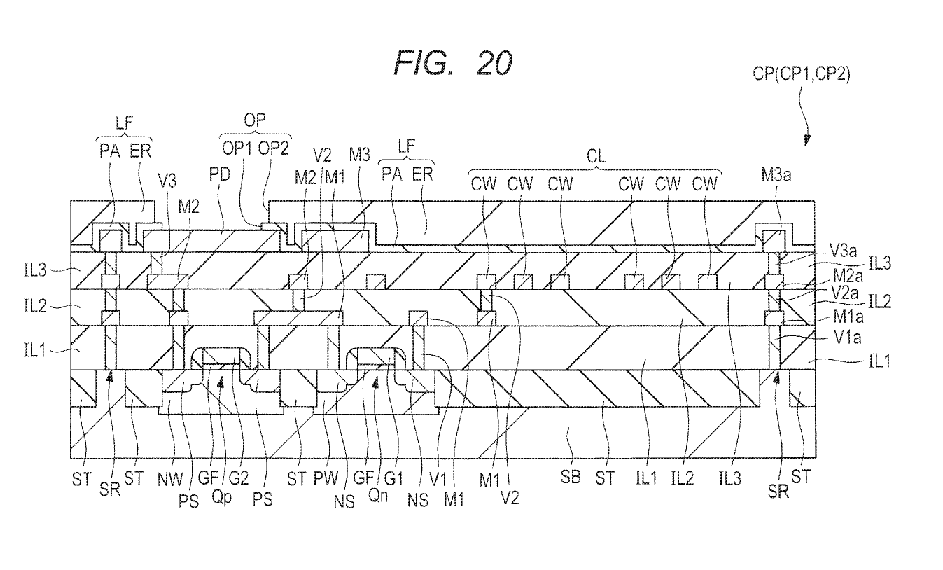

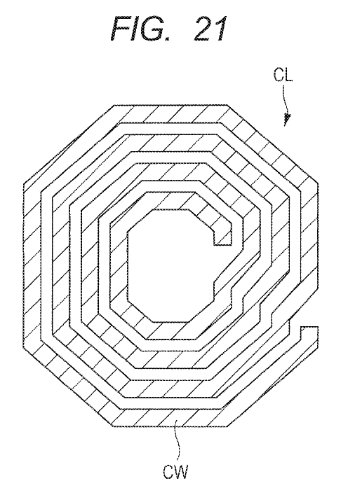

FIG. 20 is a cross-sectional view schematically showing a cross-sectional structure of the semiconductor chip (semiconductor device) CP in the present embodiment. FIG. 21 is a plan view showing a coil wire CW forming each of the coils CL formed in the semiconductor chip CP.

The semiconductor chip CP shown in FIG. 20 corresponds to the foregoing semiconductor chip CP1 or the foregoing semiconductor chip CP2. That is, to either of the foregoing semiconductor chips CP1 and CP2, the configuration of the semiconductor chip CP shown in FIG. 20 is applicable.

The semiconductor chip CP in the present embodiment is formed by using a semiconductor substrate SB made of monocrystalline silicon or the like.

As shown in FIG. 20, in the semiconductor substrate SB made of monocrystalline silicon or the like and included in the semiconductor chip (semiconductor device) CP in the present embodiment, a semiconductor element such as a MISFET (Metal Insulator Semiconductor Field Effect Transistor) is formed.

For example, in a semiconductor substrate SB, a p-type well PW and an n-type well NW are formed. Over the p-type well PW, a gate electrode G1 for an n-channel MISFET is formed via a gate insulating film GF while, over the n-type well NW, a gate electrode G2 for a p-channel MISFET is formed via the gate insulating film GF.

In the p-type well PW of the semiconductor substrate SB, source/drain n-type semiconductor regions NS of the n-channel MISFET are formed while, in the n-type well NW of the semiconductor substrate SB, source/drain p-type semiconductor regions PS of the p-channel MISFET are formed. The gate electrode G1, the gate insulating film GF under the gate electrode G1, and the n-type semiconductor regions NS (source/drain regions) on both sides of the gate electrode G1 form an n-channel MISFET Qn. On the other hand, the gate electrode G2, the gate insulating film GF under the gate electrode G2, and the p-type semiconductor regions PS (source/drain regions) on both sides of the gate electrode G2 form a p-channel MISFET Qp.

Note that, as examples of the semiconductor elements formed in the semiconductor substrate SB, the MISFETs have been described heretofore. However, it may also be possible to additionally form a capacitor element, a resistor element, a memory element, a transistor having another configuration, and the like. When the semiconductor chip CP is the foregoing semiconductor chip CP1, the semiconductor elements formed in the semiconductor substrate SB form the transmission circuit TX1 and the reception circuit RX2 each described above. When the semiconductor chip CP is the foregoing semiconductor chip CP2, the semiconductor elements formed in the semiconductor substrate SB form the transmission circuit TX2, the reception circuit RX1, and the drive circuit DR each described above. As an example of the semiconductor substrate SB, a monocrystalline silicon substrate has been described heretofore. In another form, a SOI (Silicon On Insulator) substrate or the like can also be used as the semiconductor substrate SB.

Over the semiconductor substrate SB, a wiring structure including one or more wiring layers is formed. Preferably, a multi-layer wiring structure is formed of a plurality of interlayer insulating films and a plurality of wiring layers.

That is, over the semiconductor substrate SB, a plurality of interlayer insulating films IL1, IL2, and IL3 are formed and, in the plurality of interlayer insulating films IL1, IL2, and IL3, plugs V1, via portions V2 and V3, and wires M1, M2, and M3 are formed.

Specifically, over the semiconductor substrate SB, the interlayer insulating film IL1 is formed as an insulating film so as to cover the foregoing MISFETs. Over the interlayer insulating film IL1, the wires M1 are formed. The wires M1 are in the first wiring layer (lowermost wiring layer). Over the interlayer insulating film IL1, the interlayer insulating film IL2 is formed as the insulating film so as to cover the wires M1. Over the interlayer insulating film IL2, the wires M2 are formed. The wires M2 are in the second wiring layer as the wiring layer immediately above the first wiring layer. Over the interlayer insulating film IL2, the interlayer insulating film IL3 is formed as the insulating film so as to cover the wires M2. Over the interlayer insulating film IL3, the wires M3 are formed. The wires M3 are in the third wiring layer as the wiring layer immediately above the second wiring layer. The third wiring layer is the uppermost wiring layer.

The plugs V1 are each made of a conductor and formed in the layer located under the wires M1. That is, the plugs V1 are formed in the interlayer insulating film IL1 so as to extend through the interlayer insulating film IL1. The plugs V1 have upper surfaces in contact with the lower surfaces of the wires M1 to thus be electrically coupled to the wires M1. The plugs V1 have bottom portions coupled to various semiconductor regions (such as, e.g., the n-type semiconductor regions NS and the p-type semiconductor regions PS) formed in the semiconductor substrate SB, the gate electrodes G1 and G2, and the like. As a result, the wires M1 are electrically coupled to the various semiconductor regions formed in the semiconductor substrate SB, the gate electrodes G1 and G2, and the like via the plugs V1.

The via portions V2 are each made of a conductor and formed between the wires M2 and the wires M1, i.e., formed in the interlayer insulating film IL2 to couple the wires M2 to the wires Ml. The via portions V2 can also be formed integrally with the wires M2. The via portions V3 are each made of a conductor and formed between the wires M3 and the wires M2, i.e., formed in the interlayer insulating film IL3 to couple the wires M3 to the wires M2. The via portions V3 can also be formed integrally with the wires M3.

In the semiconductor chip CP shown in FIG. 20, the third wiring layer is the uppermost wiring layer and the wires M3 are the uppermost-layer wires. The semiconductor elements (e.g., the foregoing MISFETs) formed in the semiconductor substrate SB are wired as intended by the first wiring layer (wires M1), the second wiring layer (wires M2), and the third wiring layer (wires M3) to be able to perform an intended operation.

A pad (pad electrode or bonding pad) PD is formed of the third wiring layer as the uppermost wiring layer. In short, the pad PD is formed in the same layer as that of the wires M3. That is, the wires M3 and the pad PD are formed of the same conductive layer in the same step. Accordingly, similarly to the wires M3, the pad PD is also formed over the interlayer insulating film IL3.

The pad PD is electrically coupled to the internal wiring of the semiconductor chip CP. For example, by providing the wire M3 integrally formed with the pad PD and allowing the wire ME3 integrally formed with the pad PD to be coupled to the wire M2 via the via portion V3 provided immediately under the wire M3, the pad PD can electrically be coupled to the wire M2. It is also possible to provide the via portion V3 immediately under the pad PD and electrically couple the pad PD to the wire M2 via the via portion V3. Note that the internal wiring of the semiconductor chip CP is formed in the multi-layer wiring structure over the semiconductor substrate SB and includes the wires M1, M2, and M3 herein.

Also, the coils CL are formed of the wiring layer (which is the second wiring layer herein) immediately under the uppermost wiring layer (which is the third wiring layer herein). In short, the coils CL (the coil wires CW) are formed in the same layer as that of the wires M2. That is, the wires M2 and the coils CL (coil wires CW) are formed of the same conductive layer in the same step. Accordingly, similarly to the wires M2, the coils CL (coil wires CW) are also formed over the interlayer insulating film IL2.

In another form, the wiring layer in which the coils CL are formed can also be changed. For example, the coils CL can also be formed in the uppermost wiring layer (which is the third wiring layer herein). Alternatively, the coils CL can also be formed in the wiring layer (which is the first wiring layer herein) two layers below the uppermost wiring layer (which is the third wiring layer herein).

Thus, in the semiconductor chip CP in the present embodiment, the wiring structure including one or more wiring layers (preferably, a plurality of wiring layers) is formed over the semiconductor substrate SB. In the uppermost wiring layer (which is the third wiring layer herein) among the wiring layers included in the wiring structure, the pad PD is formed. In any (which is the second wiring layer herein) of the wiring layers of the wiring structure, the coils CL (col wires CW) are formed.

When the semiconductor chip CP is the foregoing semiconductor chip CP1, each of the coils CL corresponds to the foregoing coil CL1a or the foregoing coil CL2a, and the pad PD corresponds to the foregoing pad PD1. Accordingly, when the semiconductor chip CP is the foregoing semiconductor chip CP1, the coil CL serving as the foregoing coil CL1a and the coil CL serving as the foregoing coil CL2a are formed over the interlayer insulating film IL2. When the semiconductor chip CP is the foregoing semiconductor chip CP2, each of the coils CL corresponds to the foregoing coil CL1b or the foregoing coil CL2b, and the pad PD corresponds to the foregoing pad PD2. Accordingly, when the semiconductor chip CP is the foregoing semiconductor chip CP2, the coil CL serving as the foregoing coil CL1b and the coil CL serving as the foregoing coil CL2b are formed over the interlayer insulating film IL2.

Each of the coils CL is formed of the coil wire (coil-shaped wire) CW wound into a helical shape (coil shape or loop shape) in plan view over the interlayer insulating film IL2 (see FIG. 21). The coil wire CW can be regarded as a wire for a coil. Accordingly, when the semiconductor chip CP is the foregoing semiconductor chip CP1, the foregoing coil CL1a is formed of the coil wire CW for the coil CL1a, while the foregoing coil CL2a is formed of the coil wire CW for the coil CL2a. The coil wire CW for the coil CL1a and the coil wire CW for the coil CL2a are not connected, but are spaced apart from each other. On the other hand, when the semiconductor chip CP is the foregoing semiconductor chip CP2, the foregoing coil CL1b is formed of the coil wire CW for the coil CL1b, while the foregoing coil CL2b is formed of the coil wire CW for the coil CL2b. The coil wire CW for the coil CL1b and the coil wire CW for the coil CL2b are not connected, but are spaced apart from each other.

Each of the coils CL is electrically coupled to the internal wiring of the semiconductor chip CP and coupled to the circuit (transmission circuit or reception circuit) formed in the semiconductor chip CP via the internal wiring of the semiconductor chip CP. For example, it is possible to provide the via portion V2 immediately under one end portion of the coil CL and electrically couple the one end portion of the coil CL1 to the wire M1 via the via portion V2 and also provide another via portion V2 immediately under the other end portion of the coil CL and electrically couple the other end portion of the coil CL to another wire M1 via the via portion V2.

FIG. 20 shows the case where the number of the wiring layers formed over the semiconductor substrate SB is 3 (where the total of three layers including the wires M1, M2, and M3 are formed). However, the number of the wiring layers is not limited to 3 and can variously be changed, but is preferably not less than 2.

In the semiconductor chip CP in the present embodiment, a wiring structure including one or more layers (preferably, a plurality of wiring layers) is formed over the semiconductor substrate SB. Over the wiring structure, the insulating film PA is formed. Over the insulating film PA, the insulating film ER (photosensitive resin film) is formed.

That is, over the interlayer insulating film IL3, the insulating film PA is formed so as to cover the wires M3 and, over the insulating film PA, the insulating film ER is formed. That is, over the interlayer insulating film IL3, a multi-layer film LF including the insulating film PA and the insulating film ER over the insulating film PA is formed so as to cover the wires M3. The multi-layer film including the insulating film PA and the insulating film ER over the insulating film PA is designated herein by the reference numeral LF and referred to as the multi-layer film LF.

The insulating film PA functions as a passivation film, which is preferably an inorganic insulating film. As the insulating film PA, a silicon nitride film or a silicon oxynitride film can appropriately be used, and the silicon nitride film is particularly preferred. Since the silicon nitride film is an insulating film having low moisture absorbency, by using a silicon nitride film as the insulating film PA covering the wires M3 and the pad PD, it is possible to improve the moisture resistance of the semiconductor chip CP.

The insulating film ER is the uppermost-layer film (insulating film) of the semiconductor chip CP. That is, the insulating film ER forms the uppermost layer of the semiconductor chip CP, and the film located closest to the top surface of the semiconductor chip CP is the insulating film ER. The upper surface of the insulating film ER mainly forms the upper surface (top surface) of the semiconductor chip CP. When the semiconductor chip CP is the foregoing semiconductor chip CP1, the insulating film ER corresponds to the foregoing insulating film ER1. When the semiconductor chip CP is the foregoing semiconductor chip CP2, the insulating film ER corresponds to the foregoing insulating film ER2.

The insulating film ER is made of a photosensitive resin film and has an adhesive property. Since the insulating film ER has the adhesive property, when the foregoing semiconductor package PKG is manufactured, the semiconductor chips CP1 and CP1 can be stacked and fixed such that the insulating film ER2 (ER) of the semiconductor chip CP2 and the insulating film ER1 (ER) of the semiconductor chip CP1 come in contact with each other.

The multi-layer film LF has an opening OP exposing at least a portion of the pad PD. However, since the multi-layer film LF includes the insulating film PA and the insulating film ER, the opening OP of the multi-layer film LF is formed of an opening OP1 of the insulating film PA and an opening OP2 of the insulating film ER.

The pad PD is exposed from the opening OP of the multi-layer film LF. That is, by providing the opening OP over the pad PD, the pad PD is exposed from the opening OP of the multi-layer film LF. This allows a conductive coupling member such as the foregoing wire BW to be coupled to the pad PD exposed from the opening OP of the multi-layer film LF.

As shown in FIG. 20, in the outer peripheral portion of the semiconductor chip CP, a seal ring (guard ring) SR is formed. In plan view, the seal ring SR is formed in the outer peripheral portion of the semiconductor chip CP so as to circle along the outer periphery of the semiconductor chip CP. In plan view, in the semiconductor chip CP, various circuits and semiconductor elements are formed in the region enclosed in the seal ring SR. Accordingly, in plan view, the n-channel MISFET Qn, the p-channel MISFET Qp, the wires M1, M2, and M3, the pad PD, and the coils CL (coil wires CW) are formed (disposed) in the region enclosed in the seal ring SR in the semiconductor chip CP.

The seal ring SR is formed of seal ring wires (metal pattern) M1a, M2a, and M3a and seal ring via portions (metal pattern) V1a, V2a, and V3a. The seal ring SR is formed of these seal ring wires M1a, M2a, and M3a and the sealing ring via portions V1a, V2a, and V3a which are vertically aligned to have a metal wall shape. The seal ring wires M1a, M2a, and M3a and the seal ring via portions V1a, V2a, and V3a are formed not to wire elements or circuits, but to form the seal ring SR.

<About Manufacturing Process of Semiconductor Chip>

Next, a description will be given of the manufacturing process of the semiconductor chip (semiconductor device) CP in the present embodiment. By the following manufacturing process, the semiconductor chip CP in FIG. 20 described above can be manufactured.

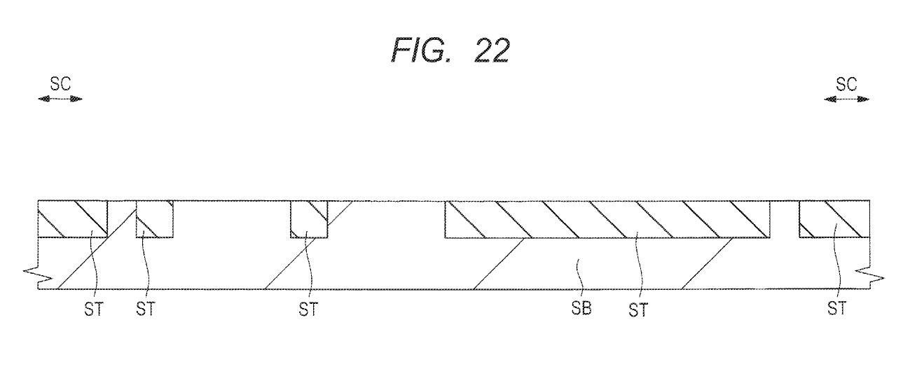

FIGS. 22 to 38 are main-portion cross-sectional views of the semiconductor chip (semiconductor device) CP in the present embodiment during the manufacturing process thereof. FIGS. 22 to 38 show cross-sectional views corresponding to FIG. 20 described above. FIGS. 22 to 37 also show a scribe region (dicing region or cutting region) SC as a region to be cut in the dicing step.

First, as shown in FIG. 22, the semiconductor substrate (semiconductor wafer) SB made of p-type monocrystalline silicon having a specific resistance of, e.g., about 1 to 10 Ωcm or the like is provided (prepared). At this stage, the semiconductor substrate SB is in the form of a semiconductor wafer.

Next, in the main surface of the semiconductor substrate SB, isolation regions ST are formed by, e.g., a STI (Shallow Trench Isolation) method or the like.

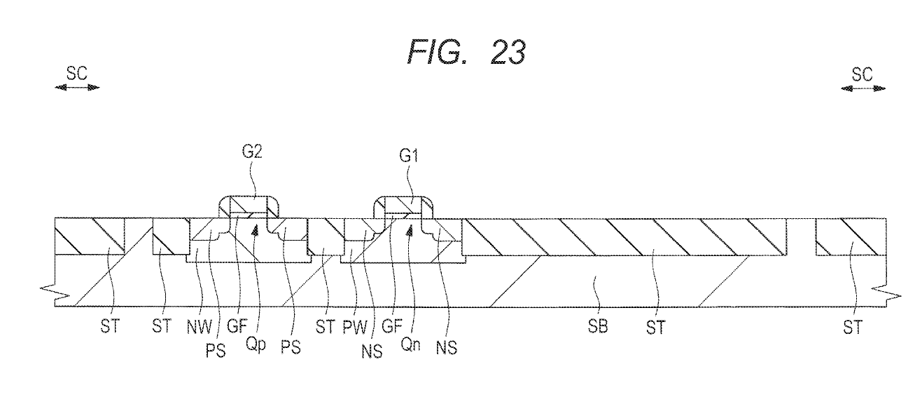

Next, as shown in FIG. 23, semiconductor elements such as MISFETs are formed in the semiconductor substrate SB (the active region thereof).

That is, using an ion implantation method, the p-type well PW and the n-type well NW are formed. Over the p-type well PW and the n-type well NW, the gate electrodes G1 and G2 are formed via the gate insulating films GF and, using an ion implantation method, the n-type semiconductor regions NS and the p-type semiconductor regions PS are formed. Thus, in the semiconductor substrate SB, the n-channel MISFET Qn and the p-channel MISFET Qp are formed.

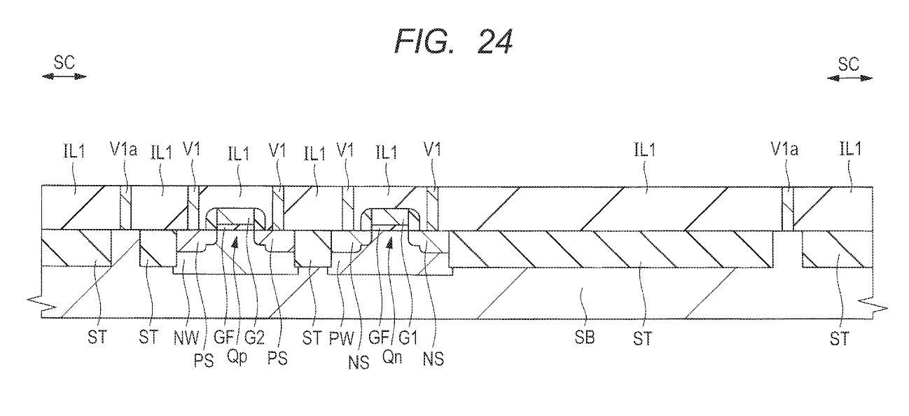

Next, as shown in FIG. 24, over the main surface (entire main surface) of the semiconductor substrate SB, the interlayer insulating film IL1 is formed so as to cover the MISFETs Qn and Qp. The interlayer insulating film IL1 is made of a single-layer film, e.g., a silicon dioxide film, a multi-layer film including a silicon nitride film and a silicon dioxide film thicker than the silicon nitride film, or the like. After the deposition of the interlayer insulating film IL1, the upper surface of the interlayer insulating film IL1 can also be planarized by performing polishing or the like on the upper surface of the interlayer insulating film IL1 as necessary in accordance with a CMP (Chemical Mechanical Polishing) method.

Next, using the photoresist layer (not shown) formed over the interlayer insulating IL1 using a photolithographic technique as an etching mask, dry etching is performed on the interlayer insulating film IL1 to form contact holes (through holes) in the interlayer insulating film IL1. Then, by embedding a conductive film in the contact holes, the conductive plugs (coupling conductor portions) V1 are formed. At this time, the seal ring via portion Via is also formed.

To form the plugs V1, e.g., over the interlayer insulating film IL1 including the bottom portions and the side walls of the contact holes, a barrier conductor film (e.g., a titanium film, a titanium nitride film, or a multi-layer film thereof) is formed. Then, a main conductor film made of a tungsten film or the like is formed over the barrier conductor film so as to be embedded in the contact holes. Subsequently, the respective unneeded portions of the main conductor film and the barrier conductor film which are located outside the contact holes are removed by a CMP method, an etch-back method, or the like. As a result, the upper surface of the interlayer insulating film IL1 is exposed, and the plugs V1 are formed of the remaining barrier conductor film and the remaining main conductor film each embedded in the contact holes of the interlayer insulating film IL1.

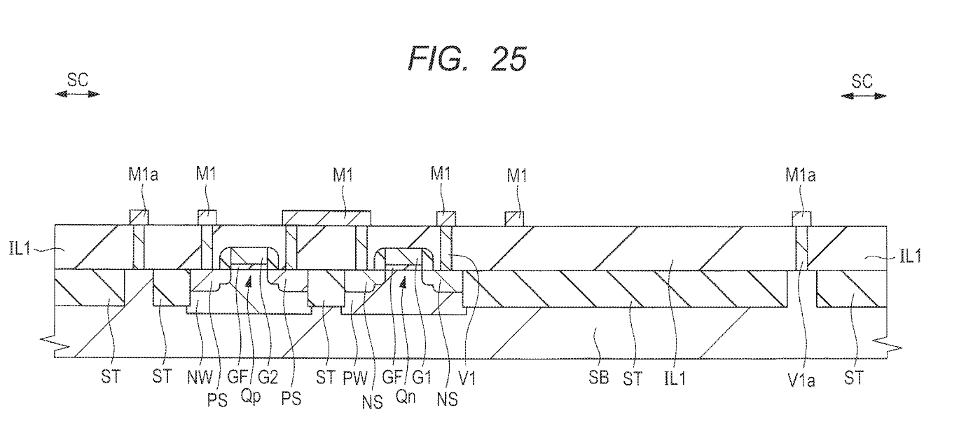

Next, as shown in FIG. 25, over the interlayer insulating film IL1 in which the plugs V1 are embedded, the wires M1 in the first wiring layer as the lowermost wiring layer are formed. To form the wires M1, first, over the interlayer insulating film IL1 in which the plugs V1 are embedded, a conductive film for the first wiring layer is formed. The conductive film for the first wiring layer is made of a multi-layer film including, e.g., a barrier conductor film (e.g., a titanium film, a titanium nitride film, or a multi-layer film thereof), an aluminum film, and a barrier conductor film (e.g., a titanium film, a titanium nitride film, or a multi-layer film thereof) which are stacked upwardly in this order. The conductive film for the first wiring layer can be formed using, e.g., a sputtering method or the like. Then, by patterning the conductive film for the first wiring layer using a photolithographic technique and an etching technique, the wires M1 and the seal ring wire M1a can be formed. The plugs V1 have upper surfaces in contact with the wires M1 to thus be electrically coupled to the wires M1.

The description has been given heretofore of the case where the wires M1 are formed by a method which patterns the conductive film. In another form, the wires M1 can also be formed by a damascene method. In this case, after an insulating film is formed over the interlayer insulating film IL1 in which the plugs V1 are embedded, wire trenches are formed in the insulating film and a conductive film is embedded in the wire trenches to be able to form the wires M1 as embedded wires (e.g., embedded copper wires). The same applies also to the wires M2 formed later.

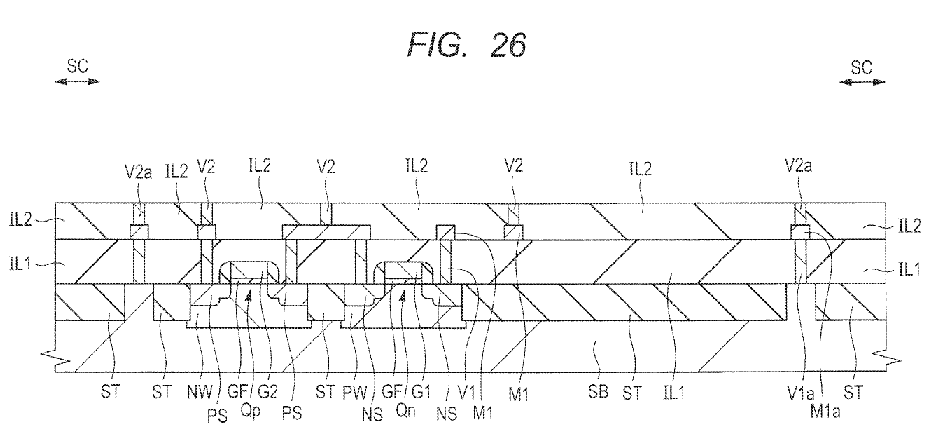

Next, as shown in FIG. 26, over the main surface (entire main surface) of the semiconductor substrate SB, i.e., over the interlayer insulating film IL1, the interlayer insulating film IL2 is formed so as to cover the wires M1 and the seal ring wire M1a. The interlayer insulating film IL2 is made of a silicon dioxide film or the like and can be formed using a CVD method or the like. After the deposition of the interlayer insulating film IL2, it is also possible to perform polishing or the like on the upper surface of the interlayer insulating film IL2 by a CMP method and thus enhance the planarity of the upper surface of the interlayer insulating film IL2.

Next, using the photoresist layer (not shown) formed over the interlayer insulating film IL2 using a photolithographic technique as an etching mask, dry etching is performed on the interlayer insulating film IL2 to form through holes (through openings) in the interlayer insulating film IL2. Then, by embedding the conductive film in the through holes, the conductive via portions (coupling conductor portions) V2 are formed. At this time, the seal ring via portion V2a is also formed. The via portions V2 can be regarded also as conductive plugs. The via portions V2 can be formed using the same method as used to form the plugs V1, but the material of the conductive film of the via portions V2 can also be different from that of the plugs V1. For example, the plugs V1 can be made mainly of a tungsten film, while the via portions V2 can be made mainly of an aluminum film.

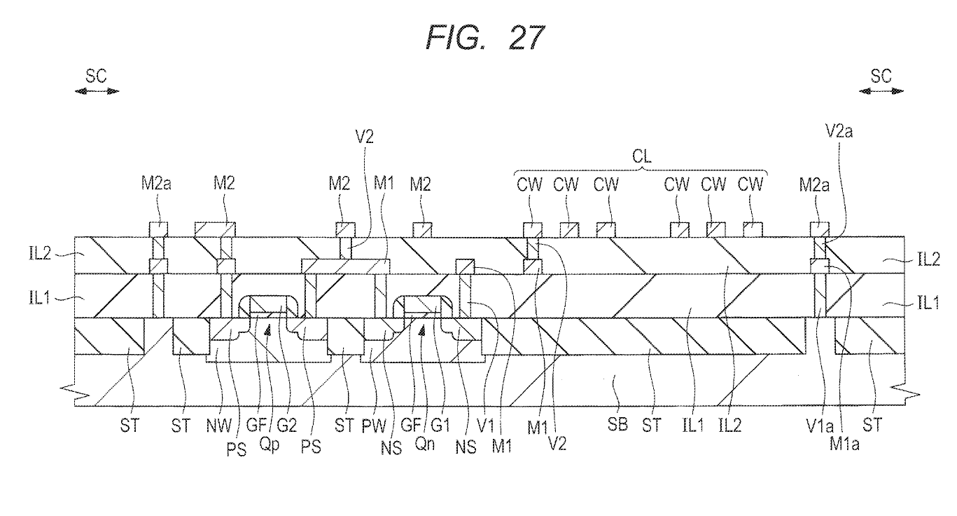

Next, as shown in FIG. 27, over the interlayer insulating film IL2 in which the via portions V2 are embedded, the wires M2 in the second wiring layer and the coil wires CW are formed. To form the wires M2 and the coil wires CW, first, over the interlayer insulating film IL2 in which the via portions V2 are embedded, a conductive film for the second wiring layer is formed. For the conductive film for the second wiring layer, the same material as that of the conductive film for the foregoing first wiring layer can be used. The conductive film for the second wiring layer serves as each of a conductive film for forming the wires M2, a conductive film for forming the coil wires CW, and a conductive film for forming the seal ring wire M2a. Then, the conductive film for the second wiring layer is patterned using a photolithographic technique and an etching technique to be able to form the wires M2, the coil wires CW, and the seal ring wire M2a. The via portions V2 have lower surfaces in contact with the wires M1 to thus be electrically coupled to the wires M1 and have upper surfaces in contact with the wires M2 or the coil wires CW to thus be electrically coupled to the wires M2 or the coil wires CW. That is, the via portions V2 electrically couple the wires M1 to the wires M2 or electrically couple the wires M1 to the coil wires CW.

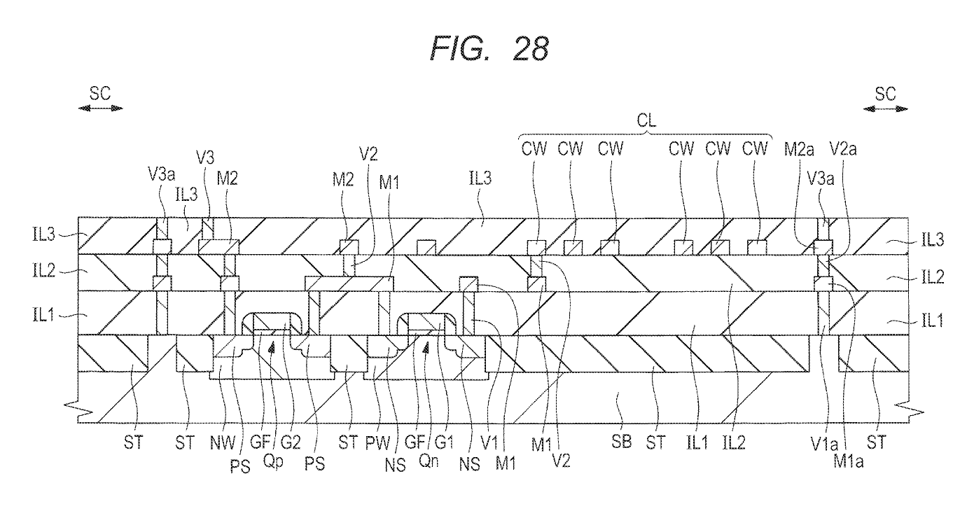

Next, as shown in FIG. 28, over the main surface (entire main surface) of the semiconductor substrate SB, i.e., over the interlayer insulating film IL2, the interlayer insulating film IL3 is formed so as to cover the wires M2, the coil wires CW, and the seal ring wire M2a. The interlayer insulating film IL3 is made of a silicon dioxide film or the like and can be formed using a CVD method or the like. After the deposition of the interlayer insulating film IL3, it is also possible to perform polishing or the like on the upper surface of the interlayer insulating film IL3 by a CMP method and thus enhance the planarity of the upper surface of the interlayer insulating film IL3.

Next, using the photoresist layer (not shown) formed over the interlayer insulating film IL3 using a photolithographic technique as an etching mask, dry etching is performed on the interlayer insulating film IL3 to form through holes in the interlayer insulating film IL3. Then, by embedding the conductive film in the through holes, the conductive via portions (coupling conductor portions) V3 are formed. At this time, the seal ring via portion Via is also formed. The via portions V3 can be regarded also as conductive plugs. The via portions V3 can be formed of the same conductive material as that of the via portions V2 using the same method as used to form the via portions V2.

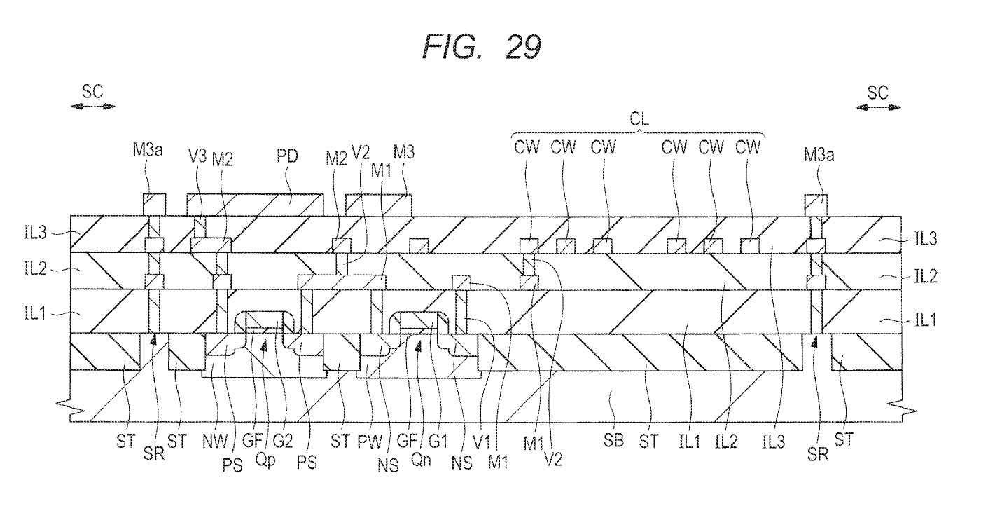

Next, as shown in FIG. 29, over the interlayer insulating film IL3 in which the via portions V3 are embedded, the wires M3 in the third wiring layer and the pad PD are formed. To form the wires M3 and the pad PD, first, over the interlayer insulating film IL3 in which the via portions V3 are embedded, a conductive film for the third wiring layer is formed. The conductive film for the third wiring layer is made of a multi-layer film including a barrier conductor film (e.g., a titanium film, a titanium nitride film, or a multi-layer film thereof), an aluminum film, and a barrier conductor film (e.g., a titanium film, a titanium nitride film, or a multi-layer film thereof) which are stacked upwardly in this order. The conductive film for the third wiring layer can be formed using a sputtering method or the like. The conductive film for the third wiring layer serves as each of a conductive film for forming the wires M3, a conductive film for forming the pad PD, and a conductive film for forming the seal ring wire M3a. Then, the conductive film for the third wiring layer is patterned using a photolithographic technique and an etching technique to be able to form the wires M3, the pad PD, and the seal ring wire M3a.

The via portions V3 have lower surfaces in contact with the wires M2 to thus be electrically coupled to the wires M2 and have upper surfaces in contact with the wires M3 or the pad PD to thus be electrically coupled to the wires M3 or the pad PD. That is, the via portions V3 electrically couple the wires M2 to the wires M3 or electrically couple the wire M2 to the pad PD.

The description has been given heretofore of the case where the via portions V3 and the wires M3 are formed in different steps. In another form, the via portions V3 can also be formed in the same step of forming the wires M3 and the pad PD. In this case, each of the via portions V3 is formed integrally with the wire M3 or the pad PD. In this case, after the through holes for the via portions V3 are formed in the interlayer insulating film IL3, a conductive film for the third wiring layer may be formed appropriately over the interlayer insulating film IL3 so as to be embedded in the through holes and then patterned using a photolithographic technique and an etching technique to form the wires M3, the pad PD, and the seal ring wire M3a. The foregoing via portions V2 and the foregoing wires M2 can also be formed in the same step. In that case, the foregoing via portions V2 are formed integrally with the foregoing wires M2.

The pad PD can have a generally rectangular two-dimensional shape having sides each larger than, e.g., the wire width of each of the wires M3. The pad PD is preferably an aluminum pad containing aluminum as a main component. The wires M3 are preferably aluminum wires containing aluminum as a main component.

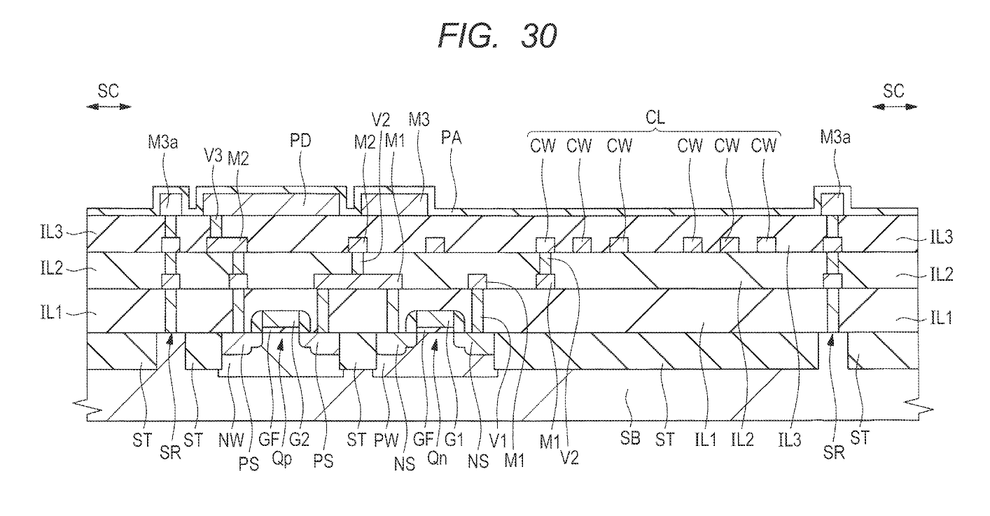

Next, as shown in FIG. 30, over the main surface (entire main surface) of the semiconductor substrate SB, i.e. over the interlayer insulating film IL3, the insulating film PA is formed so as to cover the wires M3, the pad PD, and the seal ring wire M3a. The insulating film PA is an inorganic insulating film made of an inorganic insulating material, which is preferably made of silicon nitride or silicon oxynitride, and is more preferably made of silicon nitride. The insulating film PA can be formed using a CVD method or the like. As a method for depositing a silicon nitride film forming the insulating film PA, a HDP (High Density Plasma)-CVD method is particularly appropriate. The thickness (formed film thickness) of the insulating film PA can be set to, e.g., about 0.1 to 0.5 μm.

At the stage prior to the deposition of the insulating film PA, the wires M3, the pad PD, and the seal ring wire M3a are exposed. However, when the insulating film PA is deposited, the wires M3, the pad PD, and the seal ring wire M3a are covered with the insulating film PA to be in an unexposed state.

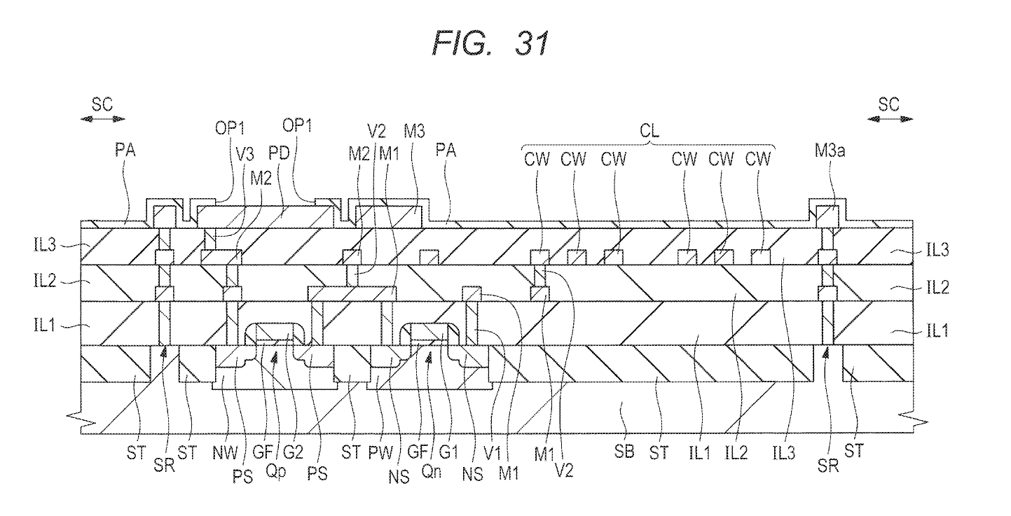

Next, over the insulating film PA, a photoresist pattern (not shown) is formed using a photolithographic technique. Then, using the photoresist pattern as an etching mask, the insulating film PA is etched (by dry etching) to be formed with the opening OP1, as shown in FIG. 31. In plan view, the opening OP1 is included in the pad PD. Accordingly, when the opening OP1 is formed in the insulating film PA, a portion of the pad PD is exposed from the opening OP1 of the insulating film PA. That is, the pad PD has an outer peripheral portion covered with the insulating film PA, while having a center portion exposed from the opening OP1 of the insulating film PA. Even when the opening OP1 is formed in the insulating film PA, a state in which the wires M3 and the seal ring wire M3a are covered with the insulating film PA is maintained. Subsequently, the photoresist pattern is removed. FIG. 31 shows this stage.

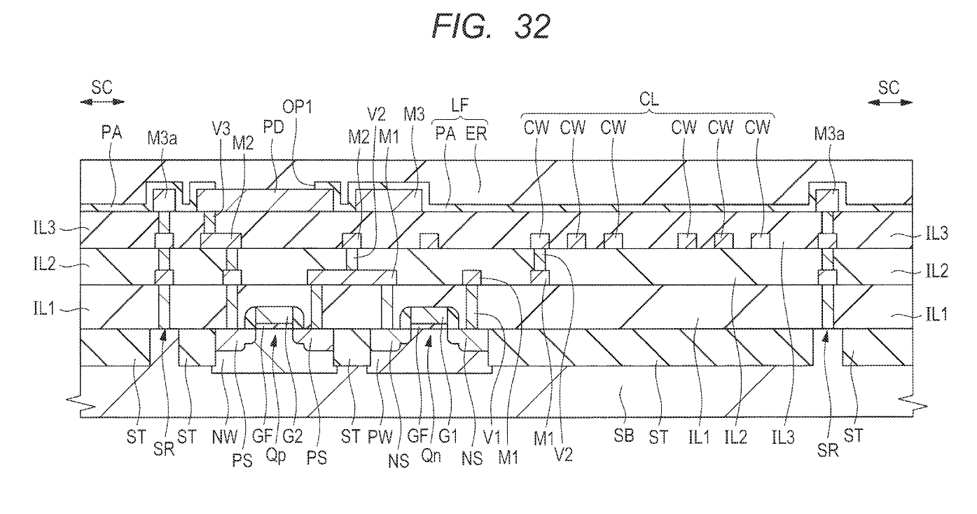

Next, as shown in FIG. 32, over the main surface (entire main surface) of the semiconductor substrate SB, i.e., over the insulating film PA, the insulating film ER is formed. The insulating film ER is made of a photosensitive resin film and is preferably made of a permanent resist (permanent resist layer).

The insulating film ER can also be formed by sticking a photosensitive resin sheet (permanent resist sheet) onto the main surface (entire main surface) of the semiconductor substrate SB, but the insulating film ER is more preferably formed by a coating method (spin coating method). By forming the insulating film ER by the coating method (spin coating method), it is possible to enhance the adhesion between the insulating film ER and an underlying film (which is the insulating film PA herein) and also enhance the planarity of the upper surface of the insulating film ER. The thickness (formed film thickness) of the insulating film ER is preferably larger than the thickness (formed film thickness) of the insulating film PA and can be set to, e.g., about 1 to 5 μm.

The spin coating method is a method which dropwise applies a chemical solution as a material for forming a thin film (which is a material for forming the insulating film ER herein) onto a rotating semiconductor wafer (which is the semiconductor substrate SB herein). After the chemical solution is applied onto the semiconductor wafer by the spin coating method, baking treatment (heat treatment) is preferably performed.

As a result of forming the insulating film PA and the insulating film ER, a state is achieved in which, over the interlayer insulating film IL3, the multi-layer film LF including the insulating film PA and the insulating film ER over the insulating film PA is formed so as to cover the wires M3, the pad PD, and the seal ring wire M3a. In the manufactured semiconductor chip CP, the insulating film ER is the uppermost-layer film. Over the portion of the pad PD which is exposed from the opening OP1 of the insulating film PA also, the insulating film ER is formed. Accordingly, when the insulating film ER is formed, a state is achieved in which the portion of the pad PD which is exposed from the opening OP1 of the insulating film PA is covered with the insulating film ER. As a result, when the insulating film ER is formed, not only the wires M3 and the sea ring wire M3a, but also the pad PD is no longer exposed.

In the case of forming the insulating film ER by the coating method (spin coating method), the insulating film ER can be formed by performing, only once, each of film formation using the coating method (spin coating method) and the baking treatment (heating treatment) of the formed film. However, the insulating film ER can also be formed by performing the film formation using the coating method (spin coating method) and the baking treatment (heat treatment) of the formed film in a plurality of cycles. In that case, since the material of the films formed in the plurality of cycles is the same, the insulating film ER is formed of a multi-layer film including a plurality of photosensitive resin films made of the same material.

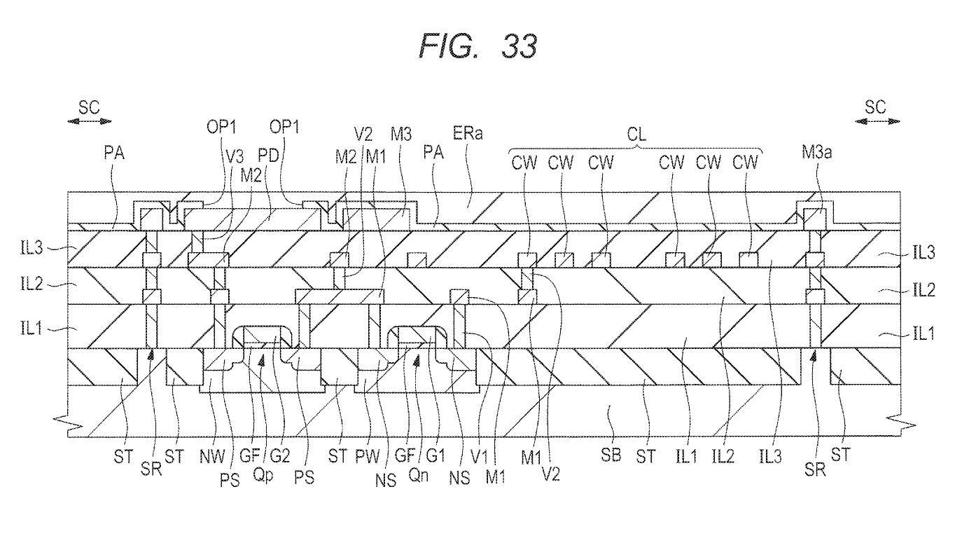

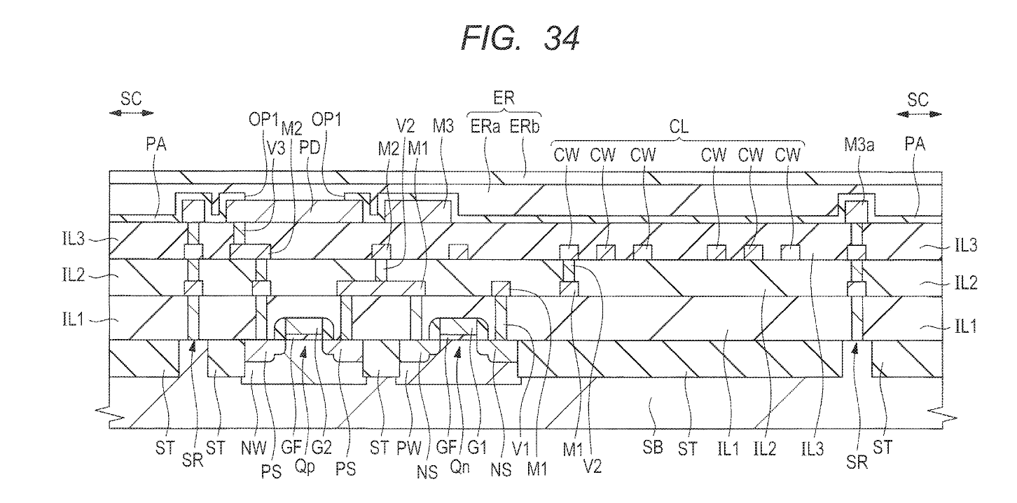

For example, after the structure in FIG. 31 described above is obtained by forming the opening OP1 in the insulating film PA, as shown in FIG. 33, a first-layer photosensitive resin film ERa is formed by the coating method (spin coating method) first and then subjected to the baking treatment (heat treatment). Subsequently, as shown in FIG. 34, over the first-layer photosensitive resin film ERa, a second-layer photosensitive resin film ERb made of the same material as that of the photosensitive resin film ERa is formed by the coating method (spin coating method) and then subjected to the baking treatment (heat treatment). This allows the insulating film ER including the photosensitive resin film ERa and the photosensitive resin film ERb over the photosensitive resin film ERa to be formed. In this case, since the photosensitive resin films ERa and ERb are made of the same material, the entire combination of the photosensitive resin films ERa and ERb can also be regarded as the single-layer insulating film ER.

Since the coating method (spin coating method) allows a planar film to be formed, the coating method (spin coating method) is appropriate as a method for forming the insulating film ER. When the film formation using the coating method (spin coating method) and the baking treatment of the formed film are performed in a plurality of cycles, the film formed later is more likely to have an upper surface with higher planarity. Accordingly, by forming the insulating film ER by performing the film formation using the coating method (spin coating method) and the baking treatment of the formed film in a plurality of cycles, the planarity of the upper surface of the insulating film ER can more reliably be enhanced. In addition, by performing the film formation using the coating method (spin coating method) and the baking treatment of the formed film in a plurality of cycles, the thickness of the insulating film ER can be increased. This can increase the breakdown voltage (dielectric strength voltage) between the coil CL in the semiconductor chip CP1 and the coil CL in the semiconductor chip CP2 in the semiconductor package PKG.

After the structure in FIG. 32 or 34 described above is obtained by forming the insulating film ER, the step of subjecting the insulating film ER to exposure and development treatment to pattern the insulating film ER is performed. The step of subjecting the insulating film ER to exposure and development treatment to pattern the insulating film ER allows the opening OP2 to be formed in the insulating film ER. The following will specifically describe the step of subjecting the insulating film ER to exposure and development treatment to pattern the insulating film ER (the step of forming the opening OP2).

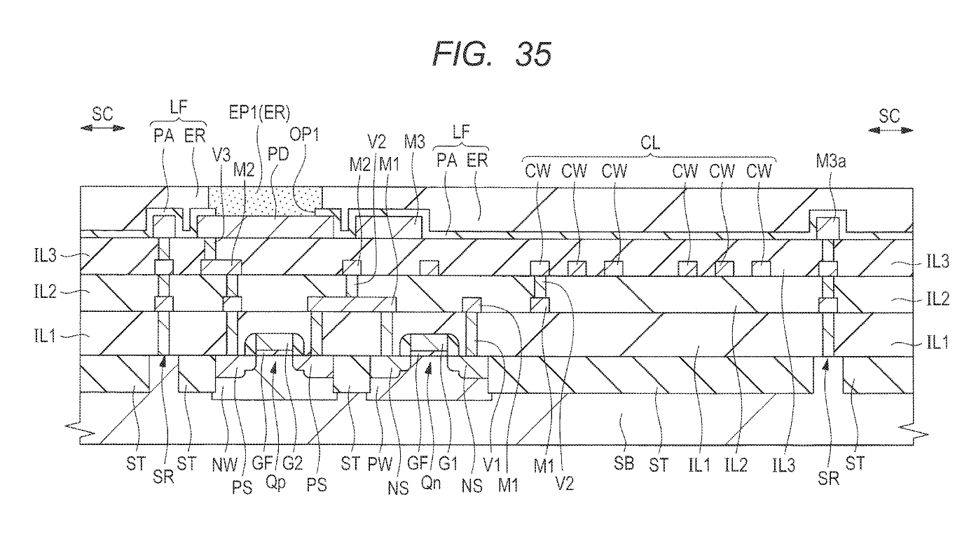

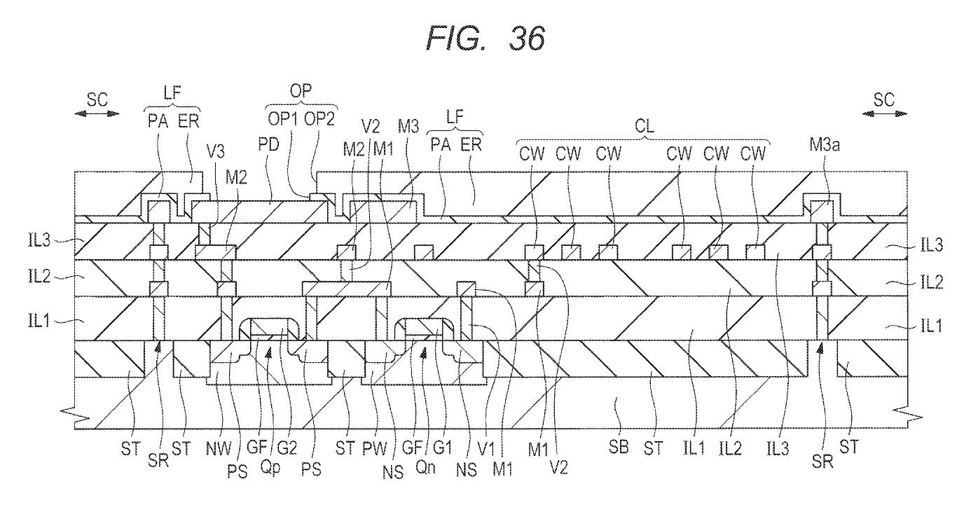

That is, using a photomask for forming the opening OP2, the insulating film ER made of the photosensitive resin is exposed, as shown in FIG. 35. In FIG. 35, an exposed region EP1 (region that has been exposed) of the insulating film ER is hatched with dots. For example, when the insulating film ER is made of a positive photosensitive resin, the region of the insulating film ER where the opening OP2 is to be formed is exposed, as shown in FIG. 35. Then, the insulating film ER made of the photosensitive resin is subjected to development treatment. By the development treatment, the insulating film ER is patterned. Specifically, as shown in FIG. 36, the portion of the insulating film ER which corresponds to the opening OP2 is selectively removed so that the opening OP2 is formed in the insulating film ER.

After the development treatment, the insulating film ER is preferably subjected to baking treatment (heat treatment). By the baking treatment, the insulating film ER is cured to have increased (higher) hardness. By performing the baking treatment after the development treatment, it is easier to perform the subsequent steps. For example, since the insulating film ER is hardened to a degree by the baking treatment, the handling of the semiconductor wafer is improved. The baking treatment of the insulating film ER after the development treatment is performed prior to the step of cutting the semiconductor substrate SB described later.

Thus, as shown in FIG. 36, a state is obtained in which the opening OP is formed in the multi-layer film LF including the insulating film PA and the insulating film ER over the insulating film PA. The opening OP is formed of the opening OP1 of the insulating film PA and the opening OP2 of the insulating film ER. Preferably, the opening OP1 is included in the opening OP2 in plan view. In that case, the inner wall of the opening OP of the multi-layer film LF is formed of the inner wall of the opening OP2 of the insulating film ER, the inner wall of the opening OP1 of the insulating film PA, and the upper surface of the insulating film PA which is located between the respective inner walls of the openings OP1 and OP2 and uncovered with the insulating film ER. From the opening OP of the multi-layer film LF, at least a portion of the pad PD is exposed.

Note that, in the case where the pad PD is formed of the multi-layer film including the barrier conductor film, the aluminum film over the barrier conductive film, and the barrier conductor film over the aluminum film as described above, when the opening OP1 is formed in the insulating film PA, it is also possible to remove the barrier conductor film (upper-layer barrier conductive film) exposed from the opening OP1 by etching and expose the aluminum film forming the pad PD from the opening OP1. After the aluminum film forming the pad PD is exposed from the opening OP1, an underlying metal film (not shown) can also be formed over the aluminum film exposed from the opening OP1. The underlying metal film is made of a multi-layer film including, e.g., a nickel (Ni) film and a gold (Au) film over the nickel (Ni) film or the like. The formation of the underlying metal film leads to the coupling of the foregoing wires BW to the underlying metal film. As a result, the foregoing wires BW can easily be coupled.

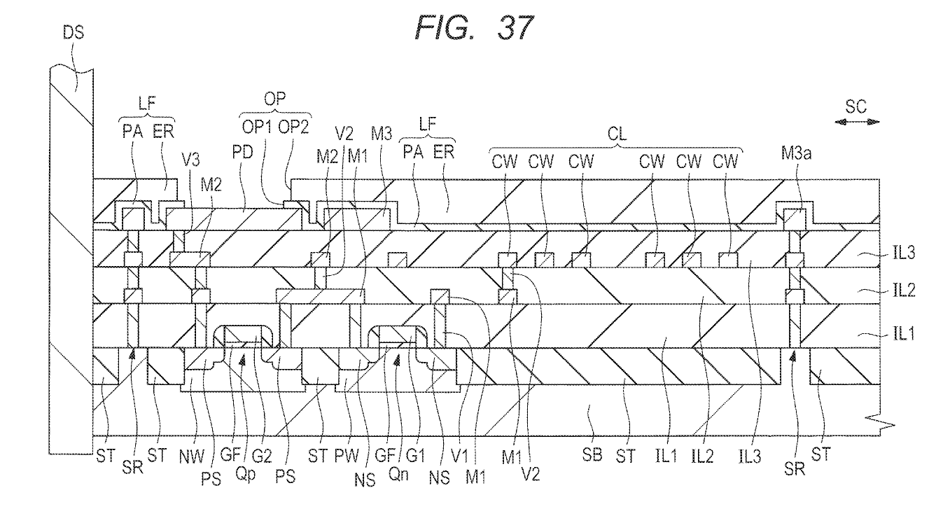

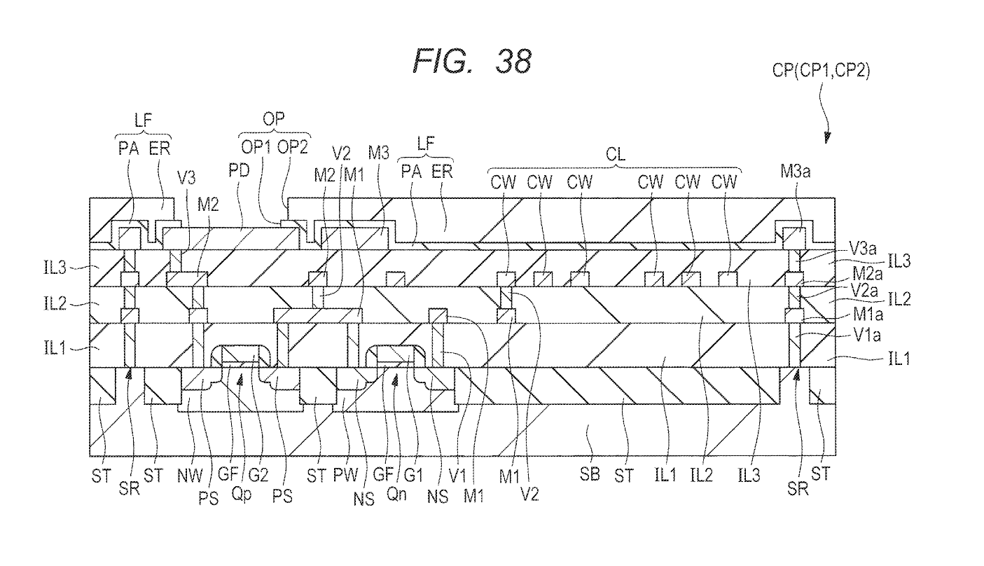

Thereafter, the back surface of the semiconductor substrate SB is ground or polished as necessary to reduce the thickness of the semiconductor substrate SB. Then, the semiconductor substrate SB is subjected to dicing (cutting) together with the multi-layer structure over the semiconductor substrate SB. At this time, as also shown in FIG. 37, the semiconductor substrate SB and the multi-layer structure over the semiconductor substrate SB are cut (diced) along the scribe region SC using a dicing saw (dicing blade or cutting blade) DS. Thus, as shown in FIG. 38, from the individual chip regions of the semiconductor substrate SB (semiconductor wafer), semiconductor chips are acquired.

In this manner, the semiconductor chip (semiconductor device) CP can be manufactured.

<About Stacking of Semiconductor Chips>

In FIG. 10 described above, to the cross-sectional structure of each of the semiconductor chips CP1 and CP2, the cross-sectional structure of the semiconductor chip CP in FIG. 20 described above is applied. That is, in FIG. 10 described above, the cross-sectional structure of each of the semiconductor chips CP1 and CP2 is substantially the same as the cross-sectional structure of the semiconductor chip CP in FIG. 20 described above. Note that, actually, the semiconductor chips CP1 and CP2 have respective semiconductor elements and wires which are different from each other due to the circuit formed in the semiconductor chip CP1 and the circuits formed in the semiconductor chip CP2 which are different from each other. However, the configuration and manufacturing method of the semiconductor chip CP described above with reference to FIGS. 20 to 38 are common to those of each of the semiconductor chips CP1 and CP2.

As shown in FIGS. 10 and 20 described above, the semiconductor chip CP1 has the uppermost-layer insulating film ER (ER1), while the semiconductor chip CP2 has the uppermost-layer insulating film ER (ER2). The semiconductor chips CP1 and CP2 are stacked such that the insulating film ER (ER1) of the semiconductor chip CP1 and the insulating film ER (ER2) of the semiconductor chip CP2 face each other. The upper surface of the insulating film ER (ER1) of the semiconductor chip CP1 is in contact with the upper surface of the insulating film ER (ER2) of the semiconductor chip CP2. The coils CL of the semiconductor chip CP1 and the coils CL of the semiconductor chip CP2 overlap each other in plan view and are not coupled via a conductor, but are magnetically coupled to each other.

<About Study by Present Inventors>

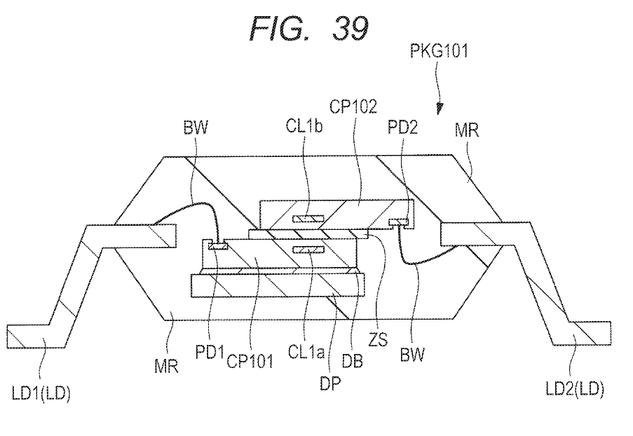

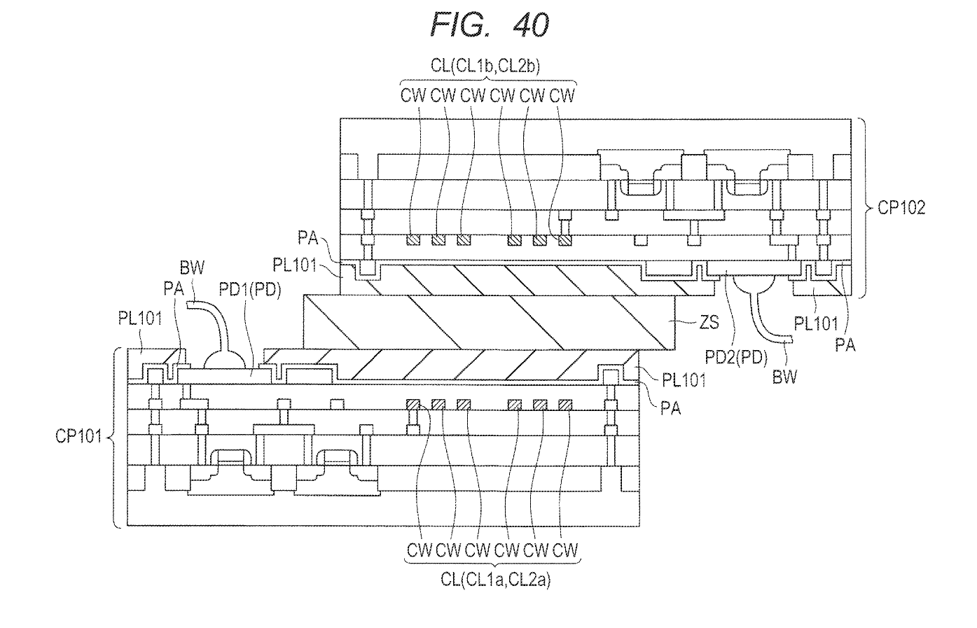

FIG. 39 is a cross-sectional view of a semiconductor package PKG101 in a studied example studied by the present inventors, which corresponds to FIG. 8 described above. FIG. 40 is a partially enlarged cross-sectional view showing a portion of the semiconductor package PKG101 in the studied example in FIG. 39 in enlarged relation, which corresponds to FIG. 10 described above.

In the semiconductor package PKG101 in the studied example in FIGS. 39 and 40, two semiconductor chips CP101 and CP102 are stacked with an insulating sheet ZS being interposed therebetween. The semiconductor chips CP101 and CP102 correspond to the foregoing semiconductor chips CP1 and CP2, but are different from the foregoing semiconductor chips CP1 and CP2 in the following point.

That is, in each of the semiconductor chips CP1 and CP2, the uppermost layer is the insulating film ER while, in each of the semiconductor chips CP101 and CP102, the uppermost layer is an insulating film PL101. That is, in each of the semiconductor chips CP101 and CP102, the insulating film ER is not used. Over the insulating film PA, the insulating film PL101 is formed to serve as the uppermost-layer film of the semiconductor chip. The insulating film PL101 used in each of the semiconductor chips CP101 and CP102 is a typical polyimide film (polyimide resin film) and has no adhesive property.

The manufacturing process of the semiconductor package PKG101 in the studied example is performed as follows. That is, first, a lead frame, the semiconductor chip CP101 having the uppermost layer made of the insulating film PL101, and the semiconductor chip CP102 having the uppermost layer made of the insulating film PL101 are provided. Then, by performing a die bonding step, the semiconductor chip CP101 is mounted over the die pad DP of the lead frame via the die bonding material DB and bonded thereto. Then, the semiconductor chip 102 is mounted over the top surface of the semiconductor chip CP101 via the insulating sheet ZS and fixed thereto such that the top surface of the semiconductor chip CP102 faces the top surface of the semiconductor chip CP101. The insulating sheet ZS has an adhesive property. As the insulating sheet ZS, e.g., a DAF (Die Attach Film) can be used. One surface of the insulating sheet ZS is bonded to the insulating film PL101 of the semiconductor chip CP101, while the other surface of the insulating sheet ZS is bonded to the insulating film PL101 of the semiconductor chip CP102. Thus, the semiconductor chip CP101 and the semiconductor chip CP102 are fixed via the insulating sheet ZS. Then, a wire bonding step is performed to couple the plurality of pads PD1 of the semiconductor chip CP101 and the plurality of pads PD2 of the semiconductor chip CP102 to the plurality of leads LD using the plurality of wires BW. Then, a resin sealing step is performed to form the sealing resin portion MR sealing therein the semiconductor chips CP101 and CP102, the die pad DP, the insulating sheet ZS, the plurality of leads LD, and the plurality of wires BW. Then, by cutting the leads LD and bending the leads LD, the semiconductor package PKG101 in the studied example in FIGS. 39 and 40 is manufactured.

When the semiconductor package PKG101 in the studied example is manufactured, after the semiconductor chips CP101 and CP102 are manufactured, the semiconductor chips CP101 and CP102 need to be stuck to each other via the insulating sheet ZS having the adhesive property. For example, it is appropriate to stick one surface of the insulating sheet ZS to the top surface of the semiconductor chip CP101 and then stick the semiconductor chip CP102 to the other surface of the insulating sheet ZS. Alternatively, it is appropriate to stick one surface of the insulating sheet ZS to the top surface of the semiconductor chip CP102 and then stick the other surface of the insulating sheet ZS to the top surface of the semiconductor chip CP101. That is, when the semiconductor package PKG101 in the studied example is manufactured, it is necessary to stick the semiconductor chip CP101 to the insulating sheet ZS and stick the semiconductor chip CP102 to the insulating sheet ZS.

However, as a result of conducting study, the present inventors have found that, when the semiconductor package PKG101 in the studied example is manufactured, the following problem arises.

That is, when the insulating sheet ZS is stuck to the top surface of the semiconductor chip CP101 or when the insulating sheet ZS is stuck to the top surface of the semiconductor chip CP102, air bubbles or a defect may develop between the top surface of the semiconductor chip CP101 and the insulating sheet ZS or between the top surface of the semiconductor chip CP102 and the insulating sheet ZS. When air bubbles or a defect has developed between the top surface of the semiconductor chip CP101 and the insulating sheet ZS or between the top surface of the semiconductor chip CP102 and the insulating sheet ZS, the reliability of the manufactured semiconductor package PKG101 deteriorates. For example, starting from the air bubbles or defect that has developed between the top surface of the semiconductor chip CP101 (or the semiconductor chip CP102) and the insulating sheet ZS, delamination between the top surface of the semiconductor chip CP101 (or the semiconductor chip CP102) and the insulating sheet ZS may proceed. When delamination has occurred between the top surface of the semiconductor chip CP101 (or the semiconductor chip CP102) and the insulating sheet ZS, the delaminated portion serves as a leakage path or the like to degrade the reliability of the semiconductor package PKG101. In particular, in the semiconductor package PKG101 having a configuration in which the coils in the semiconductor chip CP101 are magnetically coupled to the coils in the semiconductor chip CP102 and a signal is transmitted between the semiconductor chips CP101 and CP102 using these coils, the proceeding of the foregoing delamination may reduce the breakdown voltage (dielectric strength voltage) between the coil in the semiconductor chip CP101 and the coil in the semiconductor chip CP102.

Accordingly, in the semiconductor package in which the two semiconductor chips are stacked also, it is desired to inhibit or prevent the occurrence of delamination at a position between the stacked semiconductor chips and improve the reliability of the semiconductor package.

<About Main Characteristic Features and Effects>

The semiconductor package PKG in the present embodiment is a semiconductor package (semiconductor device) which includes the semiconductor chip CP1 (first semiconductor chip) and the semiconductor chip CP2 (second semiconductor chip) and in which the semiconductor chips CP1 and CP2 are stacked.

One of the main characteristic features of the present embodiment is that, as the insulating film ER1 (first photosensitive resin film) as the uppermost-layer film of the semiconductor chip CP1, a photosensitive resin film having an adhesive property is used and, as the insulating film ER2 (second photosensitive resin film) as the uppermost-layer film of the semiconductor chip CP2, a photosensitive resin film having an adhesive property is used. The semiconductor chips CP1 and CP2 are stacked such that the insulating film ER1 (photosensitive resin film having the adhesive property) of the semiconductor chip CP1 and the insulating film ER2 (photosensitive resin film having the adhesive property) of the semiconductor chip CP2 are in contact with each other.

As in the semiconductor package PKG101 in the foregoing studied example, when the semiconductor chips CP101 and CP102 are stacked with the insulating sheet ZS having the adhesive property being interposed therebetween unlike in the present embodiment, air bubbles or a defect may develop between the top surface of the semiconductor chip CP101 and the insulating sheet ZS or between the top surface of the semiconductor chip CP102 and the insulating sheet ZS. This leads to delamination between the top surface of the semiconductor chip CP101 and the insulating sheet ZS or the delamination between the top surface of the semiconductor chip CP102 and the insulating sheet ZS and consequently degrades the reliability of the semiconductor package PKG101.

By contrast, in the present embodiment, each of the insulating film ER1 as the uppermost-layer film of the semiconductor chip CP1 and the insulating film ER2 as the uppermost-layer film of the semiconductor chip CP2 is the photosensitive resin film having the adhesive property. This allows the semiconductor chips CP1 and CP2 to be brought into direct contact with each other and bonded to each other without using an equivalent to the foregoing insulating sheet ZS. That is, by stacking the semiconductor chips CP1 and CP2 such that the adhesive insulating film ER1 (photosensitive resin film) of the semiconductor chip CP1 and the adhesive insulating film ER2 (photosensitive resin film) of the semiconductor chip CP2 come in contact with each other, the semiconductor chips CP1 and CP2 can be bonded and fixed to each other.

In the present embodiment, the semiconductor chips CP1 and CP2 are stacked such that the adhesive insulating film ER1 of the semiconductor chip CP1 is in direct contact with the adhesive insulating film ER2 of the semiconductor chip CP2 without using an equivalent to the foregoing insulating sheet ZS. As a result, the present embodiment is free from delamination between either of the semiconductor chips and the insulating sheet ZS which may occur in the semiconductor package PKG101 in the foregoing studied example.

The insulating sheet ZS is a member separate from the semiconductor chips CP101 and CP102. As a result, when the semiconductor chips CP101 and CP102 are stacked with the insulating sheet ZS being interposed therebetween, air bubbles or a defect is likely to develop between the top surface of the semiconductor chip CP101 and the insulating sheet ZS or between the top surface of the semiconductor chip CP102 and the insulating sheet ZS and cause delamination therebetween. By contrast, in the present embodiment, each of the insulating film ER1 as a part of the semiconductor chip CP1 and the insulating film ER2 as a part of the semiconductor chip CP2 is imparted with the adhesive property. By bringing the insulating film ER1 as the part of the semiconductor chip CP1 into contact with the insulating film ER2 as the part of the semiconductor chip CP2, the semiconductor chips CP1 and CP2 are bonded together using the adhesive property of each of the insulating films ER1 and ER2. Accordingly, in the present embodiment, it is possible to easily and reliably bond the insulating film ER1 of the semiconductor chip CP1 to the insulating film ER2 of the semiconductor chip CP2 and enhance the adhesion between the semiconductor chips CP1 and CP2, i.e., the adhesion between the insulating film ER1 of the semiconductor chip CP1 and the insulating film ER2 of the semiconductor chip CP2. This can inhibit or prevent the occurrence of delamination at a position between the stacked semiconductor chips CP1 and CP2 and improve the reliability of the semiconductor package PKG.

The semiconductor chip CP1 is formed by forming the insulating film ER1 (ER) and then cutting and singulating the semiconductor substrate SB by dicing. Likewise, the semiconductor chip CP2 is formed by forming the insulating film ER2 (ER) and then cutting and singulating the semiconductor substrate SB by dicing. Accordingly, at the stage where the insulating film ER1 (ER) is formed, the semiconductor substrate SB has not been cut yet and is in a wafer state. Likewise, at the stage where the insulating film ER2 (ER) is formed, the semiconductor substrate SB has not been cut yet and is in a wafer state. Therefore, when the insulating film ER1 (ER) is formed, it is possible to enhance the adhesion between the insulating film ER1 (ER) and the underlying insulating film PA. Likewise, when the insulating film ER2 (ER) is formed, it is possible to enhance the adhesion between the insulating film ER2 (ER) and the underlying insulating film PA.

When the semiconductor package PKG101 in the studied example is manufactured, it is necessary to stick the adhesive insulating sheet ZS to each of the semiconductor chips not in a wafer state, but in the form of a chip. Since it is difficult to stick the adhesive insulating sheet ZS to the semiconductor chip, the adhesion between the semiconductor chip and the insulating sheet ZS is likely to be reduced, and air bubbles or a defect is likely to develop between the semiconductor chip and the insulating sheet ZS. By contrast, in the present embodiment, at the stage where the insulating film ER is formed, the semiconductor substrate SB before being formed into chips is in a wafer state. When a resin sheet (adhesive resin sheet) is to be stuck to a chip or a wafer, the resin sheet is more easily stuck to the wafer than to the chip, and the adhesion between the resin sheet and the underlie is more likely to be improved when the wafer is the underlie than when the chip is the underlie. Accordingly, in the present embodiment, the insulating film ER is formed before the semiconductor substrate SB (semiconductor wafer) is cut. Therefore, even when the insulating film ER is formed by sticking a photosensitive resin sheet onto the entire main surface (i.e., onto the insulating film PA) of the wafer (semiconductor substrate SB), it is possible to improve the adhesion between the photosensitive resin sheet (insulating film ER) and the underlying insulating film PA. Also, in the present embodiment, the insulating film ER is formed before the semiconductor substrate SB (semiconductor wafer) is cut. This allows the insulating film ER to be easily and reliably formed using a coating method (preferably, a spin coating method). By forming the insulating film ER using the coating method (preferably, the spin coating method), the adhesion between the formed insulating film ER and the underlying insulating film PA can further be improved.

Thus, in the present embodiment, the insulating film ER is formed before the semiconductor substrate SB (semiconductor wafer) is cut. This can enhance the adhesion between the insulating film ER and the underlying insulating film PA. In addition, by directly bonding the semiconductor chips CP1 and CP2 together using the adhesive property of the insulating film ER formed before the semiconductor substrate SB (semiconductor wafer) is cut, it is possible to inhibit or prevent the occurrence of a problem (such as delamination) resulting from the bonding together of the semiconductor chips CP1 and CP2. This can improve the reliability of the semiconductor package PKG. Moreover, since the insulating film ER is made of the photosensitive resin film, the opening OP2 for exposing the pad PD can be formed easily and reliably in the insulating film ER.

The insulating film ER can also be formed by sticking a photosensitive resin sheet to the main surface (entire main surface) of the semiconductor substrate SB, i.e., onto the insulating film PA, but the insulating film ER is more preferably formed by a coating method (preferably, a spin coating method). By forming the insulating film ER by the coating method (spin coating method), it is possible to enhance the adhesion between the insulating film ER and the underlying film (which is the insulating film PA herein) and also enhance the planarity of the upper surface of the insulating film ER. Consequently, it is possible to enhance the adhesion between the insulating film ER1 of the semiconductor chip CP1 and the insulating film ER2 of the semiconductor chip CP2. This can more reliably inhibit or prevent the occurrence of delamination at a position between the stacked semiconductor chips CP1 and CP2 and more reliably improve the reliability of the semiconductor package PKG.

The insulating film ER is the photosensitive resin film having the adhesive property. However, as the insulating film ER, a permanent resist (permanent photoresist or photosensitive permanent film) can be used appropriately. Permanent resists are photosensitive resin materials and, among them, there is a permanent resist having an adhesive property. Accordingly, the permanent resist can appropriately be used as the insulating film ER. Examples of a liquid-type permanent resist material (permanent resist material for which a coating method is used) include TMMR-S2000™ available from Tokyo Ohka Kogyo Co., Ltd. and KI-1000-T4™ available from Hitachi Chemical Co., Ltd. Examples of a film-type (sheet-type) permanent resist material include TMMF-S2000™ available from Tokyo Ohka Kogyo Co., Ltd., KI-1000-T4F™ available from Hitachi Chemical Co., Ltd., and SRF-SS-8000™ available from Toagosei Co., Ltd.

Examples of the material of a permanent resist that can be used for the insulating film ER include a photosensitive resin composition containing the following components A, B, C, D, and E.

The component A is a photo-radical-reactive resin having at least one or more ethylenic unsaturated groups and a carboxyl group in a molecule.

The component B is a photopolymeric monomer having at least one or more ethylenic unsaturated groups and a tricyclodecane structure in a molecule.

The component C is a photopolymerization initiator.

The component D is an epoxy resin.

The component E is a silica filler.

Note that the specific examples of the permanent resist usable for the insulating film ER are shown herein, but the permanent resist usable for the insulating film ER is not limited thereto.

### Embodiment 2

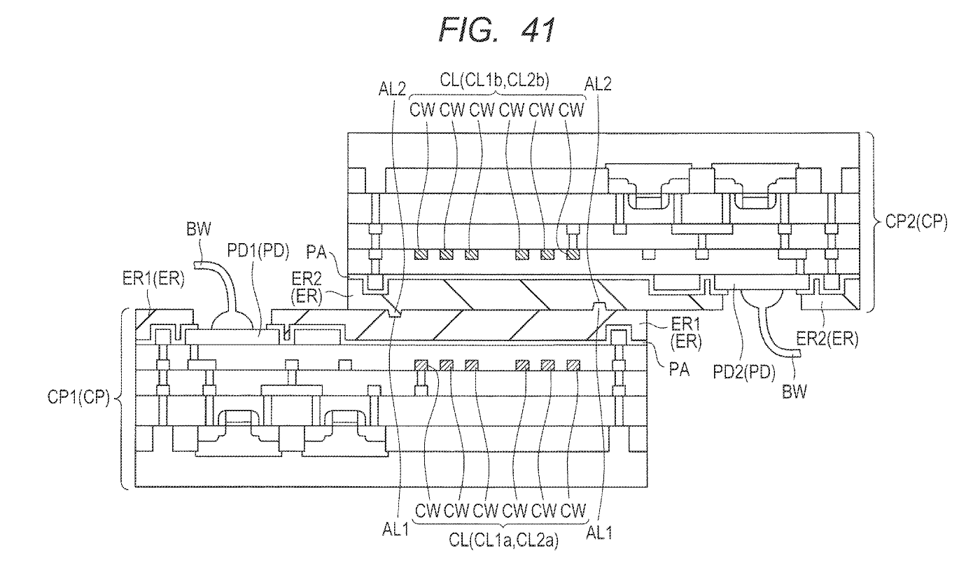

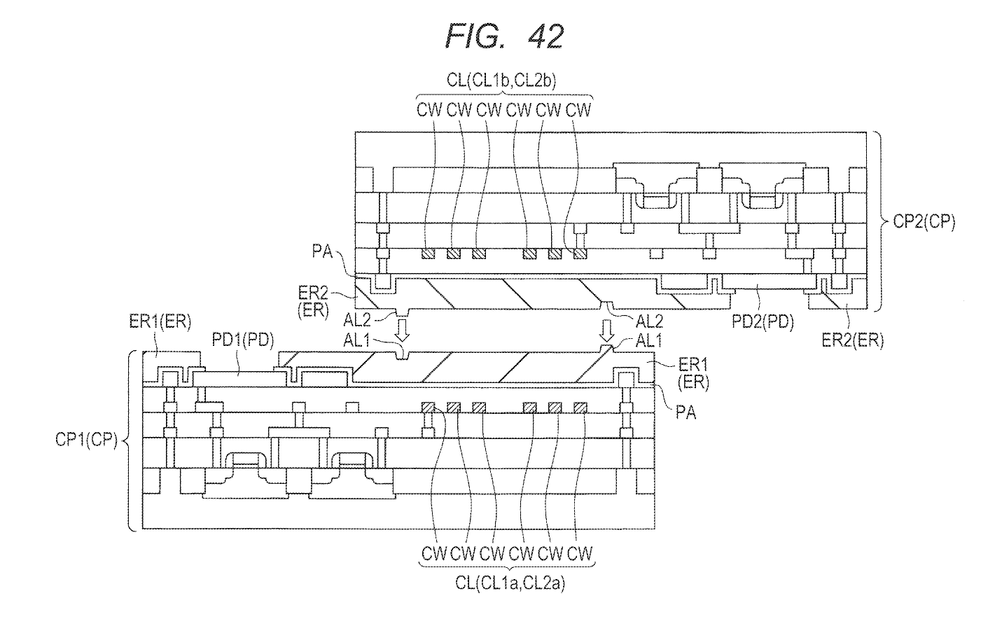

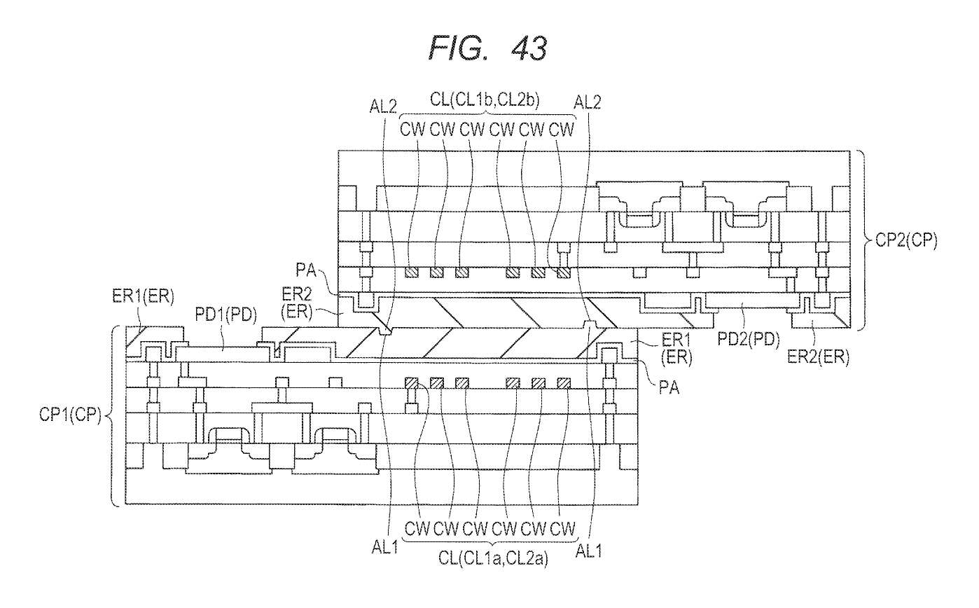

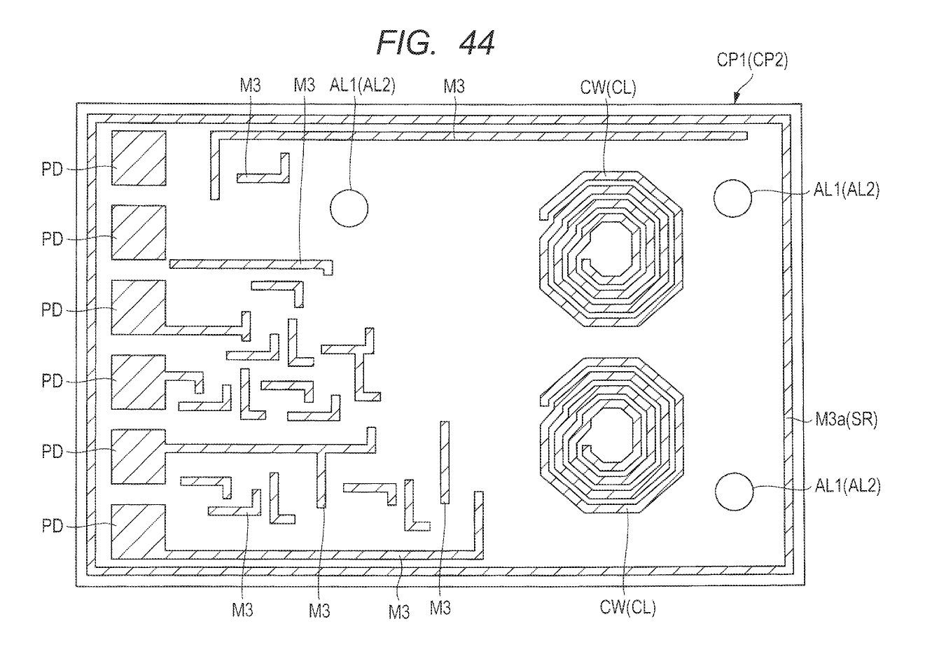

FIG. 41 is a partially enlarged cross-sectional view showing a portion of the semiconductor package PKG in Embodiment 2 in enlarged relation, which corresponds to FIG. 10 described above. FIGS. 42 and 43 are cross-sectional views illustrating the manufacturing process of the semiconductor package PKG in Embodiment 2, which are equivalent to FIGS. 14 and 15 described above. FIG. 44 is a plan view showing the semiconductor chip CP1 used in the semiconductor package PKG in Embodiment 2 of FIG. 41. In FIG. 44, the pattern of the uppermost-layer wiring layer (including the pad PD, the wires M3, and the seal-ring wire M3a herein) and the coil wires CW are shown with hatching. In FIG. 44, the positions of alignment portions AL1 are also shown. A plan view of the semiconductor chip CP2 is basically the same as FIG. 44. Specifically, when the semiconductor chips CP2 and CP1 are stacked, at positions overlapping the coil wires CW (coils CL) of the semiconductor chip CP1 in plan view, the coil wires CW (coils CL) of the semiconductor chips CP2 are present. Also, at positions overlapping the alignment portions AL1 of the semiconductor chip CP1 in plan view, alignment portions AL2 of the semiconductor chip CP2 are present. Note that, by way of example, FIG. 44 shows the case where the number of the alignment portions AL1 provided in the semiconductor chip CP1 (CP2) is 3.

A semiconductor package PKG2 in Embodiment 2 is different from the semiconductor package PKG in Embodiment 1 described above in the following point.

That is, the semiconductor chip CP1 used in the semiconductor package PKG2 in Embodiment 2 has the alignment portions AL1 (first alignment portions) each made of a projecting or depressed portion of the insulating film ER1. The semiconductor chip CP2 used in the semiconductor package PKG2 in Embodiment 2 has the alignment portions AL2 (second alignment portions) each made of a projecting or depressed portion of the insulating film ER2. The semiconductor chips CP1 and CP2 are stacked such that the alignment portions AL1 of the semiconductor chip CP1 and the alignment portions AL2 of the semiconductor chip CP2 fit together.

That is, in the step in FIG. 13 described above, as shown in FIGS. 42 and 43, the semiconductor chips CP1 and CP2 are stacked such that the insulating film ER1 (the upper surface thereof) of the semiconductor chip CP1 and the insulating film ER2 (the upper surface thereof) of the semiconductor chip CP2 come in contact with each other and the alignment portions AL1 of the semiconductor chip CP1 and the alignment portions AL2 of the semiconductor chip CP2 fit together. As a result of the fitting together of the alignment portions AL1 of the semiconductor chip CP1 and the alignment portions AL2 of the semiconductor chip CP2, the relative positions of the semiconductor chips CP1 and CP2 are defined to predetermined positions. In addition, since each of the insulating films ER1 and ER2 has the adhesive property as described above, the insulating film ER2 of the semiconductor chip CP2 is bonded and fixed to the insulating film ER1 of the semiconductor chip CP1. Thus, it is possible to bond and fix the semiconductor chip CP2 to the semiconductor chip CP1, while reliably defining the relative positions of the semiconductor chips CP1 and CP2 to the predetermined positions.

One of each of the fitting pairs of alignment portions AL1 and AL2 is a projecting portion, while the other thereof is a depressed portion. That is, when the alignment portion AL1 of the semiconductor chip CP1 is the projecting portion of the insulating film ER1, the alignment portion AL2 of the semiconductor chip CP2 which fits together with the alignment portion AL1 is the depressed portion of the insulating film ER2. When the alignment portion AL1 of the semiconductor chip CP1 is the depressed portion of the insulating film ER1, the alignment portion AL2 of the semiconductor chip CP2 which fits together with the alignment portion AL1 is the projecting portion of the insulating film ER2.

Thus, the fitting pair of alignment portions AL1 and AL2 is formed of the projecting portion of the insulating film ER1 and the depressed portion of the insulating film ER2 or formed of the depressed portion of the insulating film ER1 and the projecting portion of the insulating film ER2. This allows the alignment portions AL1 and AL2 to easily and reliably fit together. When the projecting portion of the fitting pair of alignment portions AL1 and AL2 is formed in a tapered shape (shape which tapers toward the tip of the projecting portion) and the depressed portion of the fitting pair of alignment portions AL1 and AL2 is also formed in a tapered shape (shape having an area which gradually decreases toward the bottom of the depressed portion), the projecting portion is more easily fit into the depressed portion.

As also shown in FIG. 44, in the semiconductor chip CP1, the alignment portions AL1 are preferably formed at positions which do not overlap the coils CL (coil wires CW) in the semiconductor chip CP1 in plan view. Likewise, in the semiconductor chip CP2, the alignment portions AL2 are preferably formed at positions which do not overlap the coils CL (coil wires CW) in the semiconductor chip CP2 in plan view. This can prevent the alignment portions AL1 and AL2 from affecting the magnetic coupling between the coils CL in the semiconductor chip CP1 and the coils CL in the semiconductor chip CP2.

In Embodiment 2, in the semiconductor chip CP1, at least one alignment portion AL1 is provided and, in the semiconductor chip CP2, at least one alignment portion AL2 is provided. However, each of the number of the alignment portions AL1 provided in the semiconductor chip CP1 and the number of the alignment portions AL2 provided in the semiconductor chip CP2 may be a plural number (two or more). When the plurality of alignment portions AL1 are provided in the semiconductor chip CP1, the plurality of alignment portions AL1 are spaced apart from each other in plan view. Likewise, when the plurality of alignment portions AL2 are provided in the semiconductor chip CP2, the plurality of alignment portions AL2 are spaced apart from each other in plan view.

When the plurality of alignment portions AL1 are provided in the semiconductor chip CP1, the plurality of alignment portions AL1 may also include the projecting portion and the depressed portion in mixed relation. Likewise, when the plurality of alignment portions AL2 are provided in the semiconductor chip CP2, the plurality of alignment portions AL2 may also include the projecting portion and the depressed portion in mixed relation. In such a case also, a relationship between the fitting pair of alignment portions AL1 and AL2 such that one of the alignment portions AL1 and AL2 is the projecting portion and the other thereof is the depressed portion is maintained.

Preferably, the number of the alignment portions AL1 provided in the semiconductor chip CP1 is the same as the number of the alignment portions AL2 provided in the semiconductor chip CP2. For example, when the number of the alignment portions AL1 provided in the semiconductor chip CP1 is 3, it is preferable that the number of the alignment portions AL2 provided in the semiconductor chip CP2 is also 3. This can prevent a projecting portion not used for alignment from being formed in either of the insulating films ER1 and ER2 of the semiconductor chips CP1 and CP2 and thus reliably improve the adhesion between the insulating film ER1 of the semiconductor chip CP1 and the insulating film ER2 of the semiconductor chip CP2.

Each of the number of the alignment portions AL1 provided in the semiconductor chip CP1 and the number of the alignment portions AL2 provided in the semiconductor chip CP2 is preferably 3 or more. That is, it is more preferable that, in the insulating film ER1 of the semiconductor chip CP1, the alignment portions AL1 each made of the depressed portion or the projecting portion are formed at three or more locations and, in the insulating film ER2 of the semiconductor chip CP2, the alignment portions AL2 each made of the depressed portion or the projecting portion are formed at three or more locations. In this case, the semiconductor chips CP1 and CP2 are stacked such that the alignment portions AL1 of the semiconductor chip CP1 and the alignment portions AL2 of the semiconductor chip CP2 fit together. As a result, the total of three or more fitting pairs of the alignment portions AL1 and AL2 are provided. This allows the semiconductor chips CP1 and CP2 to be reliably aligned and stacked and allows an improvement in alignment accuracy when the semiconductor chips CP1 and CP2 are stacked. Consequently, the relative positional relationship between the coils CL in the semiconductor chip CP1 and the coils CL in the semiconductor chip CP can accurately be defined as designed. Therefore, it is possible to improve the coupling coefficient of the magnetic coupling between the coils CL in the semiconductor chip CP1 and the coils CL in the semiconductor chip CP2.

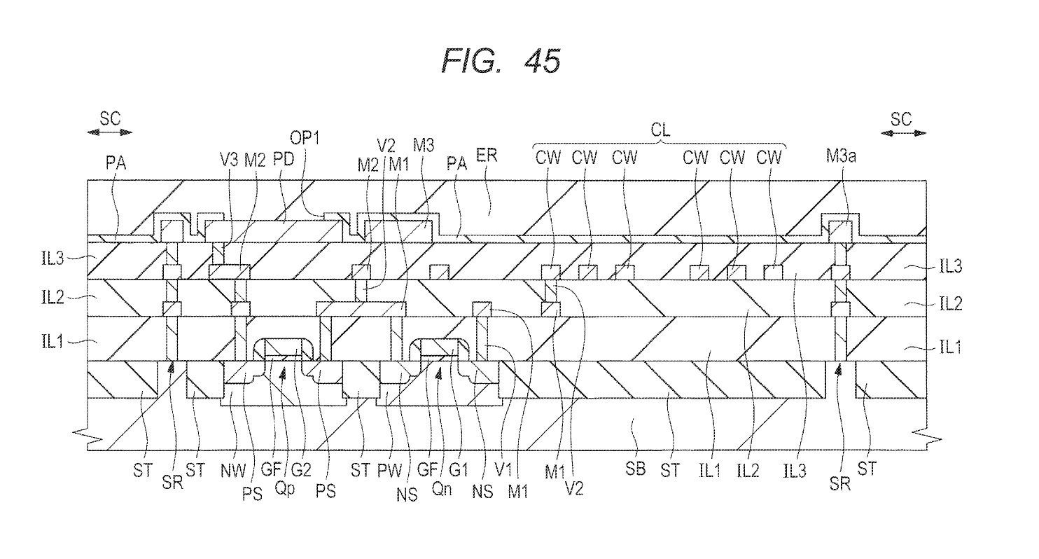

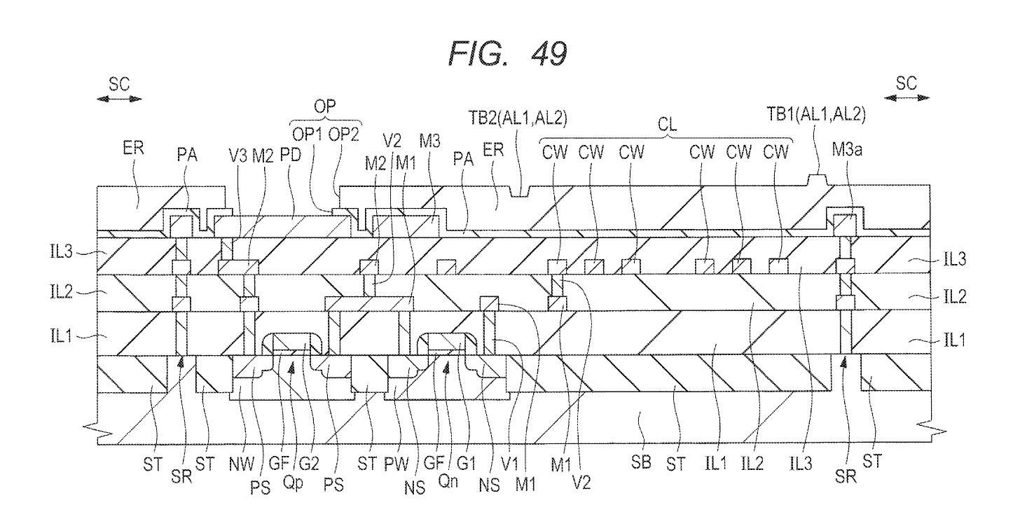

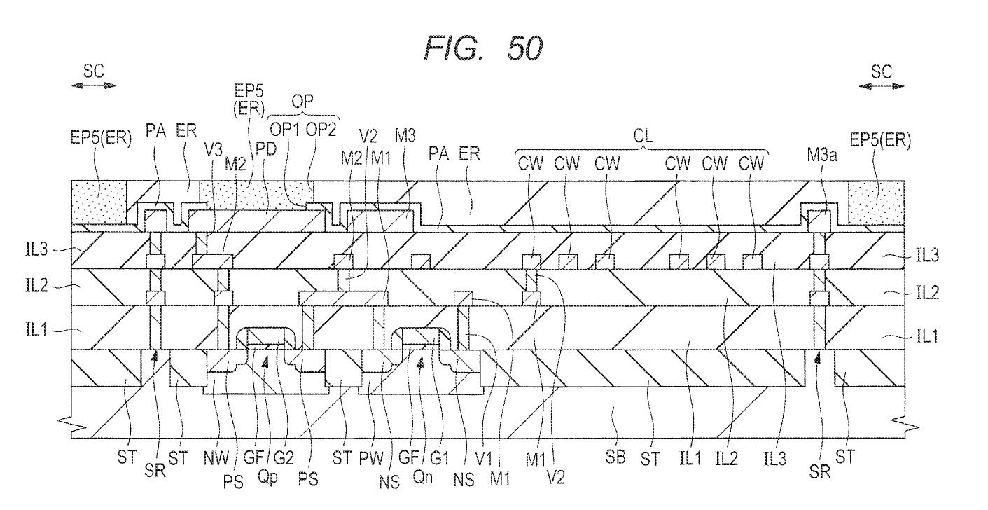

Next, an example of a method of forming the alignment portions AL1 will be described with reference to FIGS. 45 and 49. FIGS. 45 to 49 are main-portion cross-sectional views of the semiconductor chip CP1 in Embodiment 2 during the manufacturing process thereof. Note that the alignment portions AL2 can also be formed using the same method as the method of forming the alignment portions AL1.

First, in the same manner as in Embodiment 1 described above, the insulating film ER is formed to provide the structure in FIG. 45 corresponding to FIG. 32 or 34 described above.

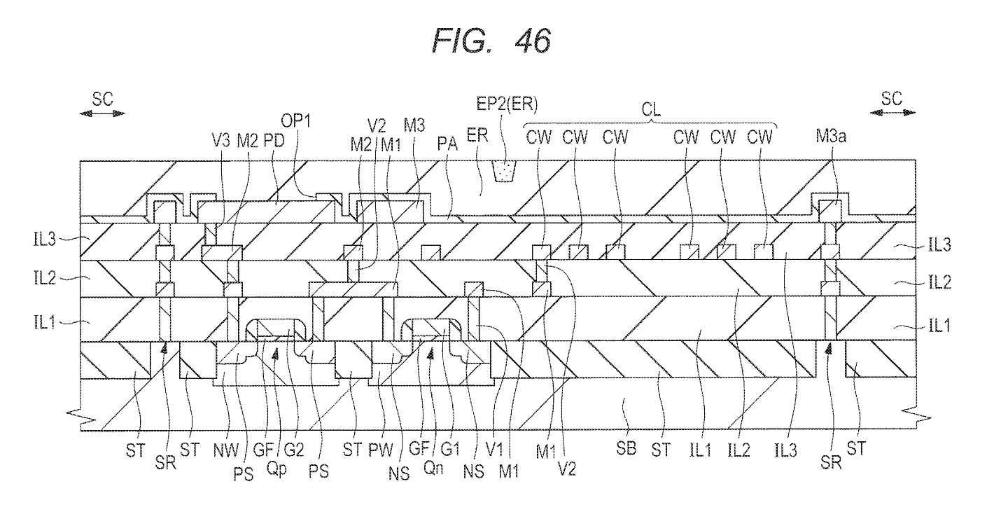

Then, in Embodiment 2, using a first photomask, the insulating film ER is exposed. The first photomask has an opening through which the region of the insulating film ER where a depressed portion is to be formed is exposed. Accordingly, when the insulating film ER is exposed using the first photomask, the region of the insulating film ER where the depressed portion is to be formed is selectively exposed, as shown in FIG. 46. Note that, in FIG. 46, an exposed region (region that has been exposed) EP2 of the insulating film ER is hatched with dots.

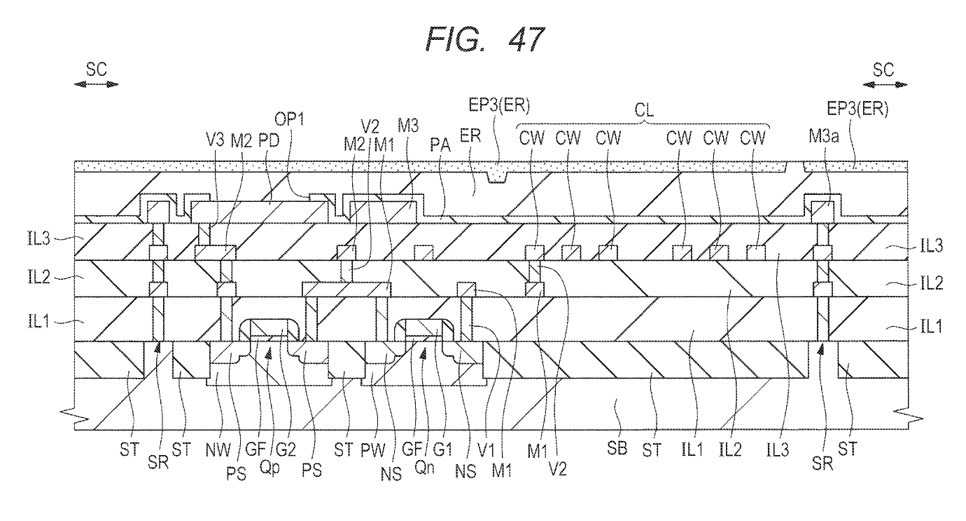

Then, using a second photomask, the insulating film ER is exposed. The second photomask covers the region of the insulating film ER where a projecting portion is to be formed and has an opening which exposes the surface layer portion (upper layer portion) of the insulating film ER except for the region thereof where the projecting portion is to be formed. Consequently, when the insulating film ER is exposed using the second photomask, as shown in FIG. 47, the surface layer portion of the insulating film ER except for the region thereof where the projecting portion is to be formed is exposed. Note that, in FIG. 47, an exposed region EP3 of the insulating film ER is hatched with dots. The exposed region EP3 is a combination of the region exposed in the exposure step using the first photomask and the region exposed in the exposure step using the second photomask. The depth of the region of the insulating film ER which is exposed in the exposure step using the second photomask is smaller than the depth of the region of the insulating film ER which is exposed in the exposure step using the first photomask.

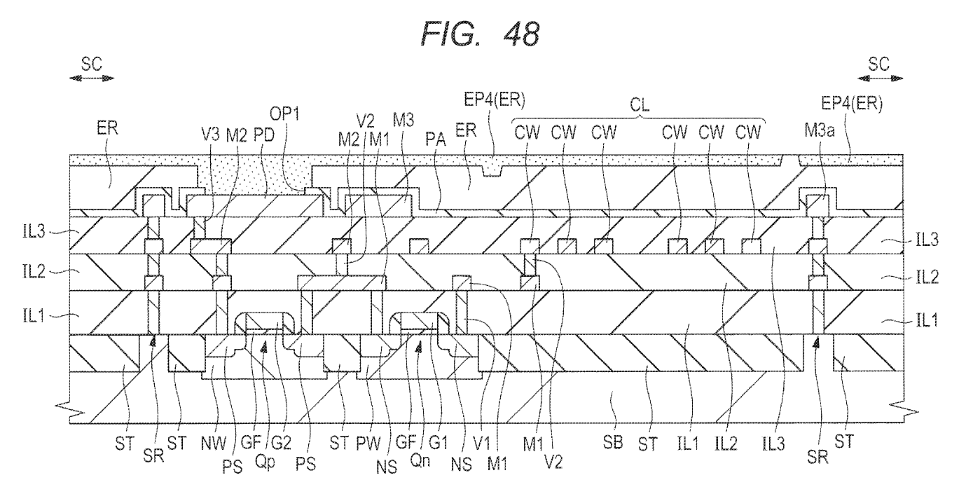

Then, using a third photomask, the insulating film ER is exposed. The third photomask has an opening which exposes the region of the insulating film ER where the opening OP2 is to be formed. Accordingly, when the insulating film ER is exposed using the third photomask, the region of the insulating film ER where the opening OP2 is to be formed is selectively exposed, as shown in FIG. 48. Note that, in FIG. 48, an exposed region EP4 of the insulating film ER is hatched with dots. The exposed region EP4 is a combination of the region exposed in the exposure step using the first photomask, the region exposed in the exposure step using the second photomask, and the region exposed in the exposure step using the third photomask. Note that the order in which the exposure step using the first photomask, the exposure step using the second photomask, and the exposure step using the third photomask are performed is changeable.

Then, development treatment is performed to remove the exposed regions of the insulating film ER. Thus, from the insulating film ER, the region exposed in the exposure step using the first photomask, the region exposed in the exposure step using the second photomask, and the region exposed in the exposure step using the third photomask are removed. In short, the exposed region EP4 shown in FIG. 48 is removed. As a result, as shown in FIG. 49, in the insulating film ER, the opening OP2, a projecting portion TB1, and a depressed portion TB2 are formed. Then, the insulating film ER is subjected to baking treatment (heat treatment). The projecting portion TB1 and the depressed portion TB2 of the insulating film ER serve as the alignment portions AL1. The opening OP2 is the same in Embodiment 2 as in Embodiment 1 described above. In the case of FIGS. 33 and 34, the projecting portion TB1 and the depressed portion TB2 may be formed in the foregoing photosensitive resin film ERb.

The subsequent steps are the same in Embodiment 2 as in Embodiment 1 described above. After the back surface of the semiconductor substrate SB is ground or polished as necessary to reduce the thickness of the semiconductor substrate SB, the semiconductor substrate SB is diced (cut) together with the multi-layer structure over the semiconductor substrate SB. Thus, from the individual chip regions of the semiconductor substrate SB (semiconductor wafer), semiconductor chips are acquired.

### Embodiment 3

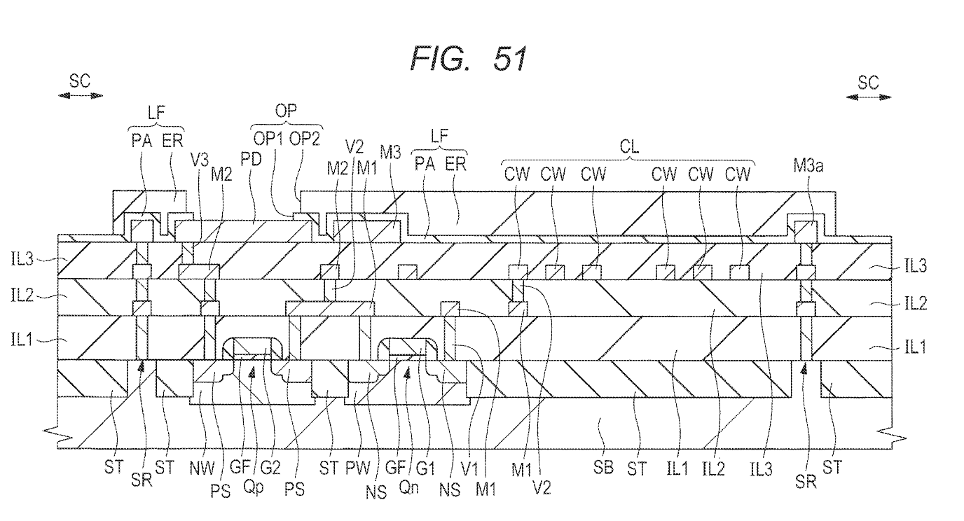

In Embodiment 3, referring to FIGS. 50 to 53, a description will be given of the case where, before a dicing step (step of cutting the semiconductor substrate SB) is performed, the insulating film ER located over the scribe region SC of the semiconductor substrate SB is removed therefrom. FIGS. 50 to 53 are main-portion cross-sectional views of the semiconductor chip CP in Embodiment 3 during the manufacturing process thereof.

First, in the same manner as in Embodiment 1 described above, the insulating film ER is formed to provide the structure in FIG. 32 or 34 described above. Then, over the insulating film ER made of a photosensitive resin, a photomask is placed. After the insulating film ER made of the photosensitive resin is exposed via the photomask, the insulating film ER is subjected to development treatment. At this time, the portion of the insulating film ER which corresponds to the opening OP2 is selectively removed so that the opening OP2 is formed in the insulating film ER, while the insulating film ER over the scribe region SC of the semiconductor substrate SB is also removed therefrom. That is, when the opening OP2 is formed in the insulating film ER by the exposure and the development treatment, the insulating film ER over the scribe region SC is also removed therefrom.

For example, when the insulating film ER is made of a positive photosensitive resin, as shown in FIG. 50, the region of the insulating film ER where the opening OP2 is to be formed and the region of the insulating film ER which is located over the scribe region SC are exposed. FIG. 50 shows the stage where the exposure step is performed. In FIG. 50, an exposed region (region that has been exposed) EP5 of the insulating film ER is hatched with dots. Then, when development treatment is performed, the exposed region EP5 of the insulating film ER is removed so that the opening OP2 is formed in the insulating film ER as shown in FIG. 51, while the insulating film ER over the scribe region SC of the semiconductor substrate SB is also removed therefrom. After the development treatment, the insulating film ER is subjected to baking treatment (heat treatment). The baking treatment cures the insulating film ER and increases the hardness of the insulating film ER.

Thus, as also shown in FIG. 51, a state is obtained in which the opening OP is formed in the multi-layer film LF including the insulating film PA and the insulating film ER over the insulating film PA. In this state, the insulating film ER has been removed from over the scribe region SC of the semiconductor substrate SB. The opening OP is the same in Embodiment 3 as in Embodiment 1 described above. Embodiment 3 is different from Embodiment 1 described above in that the insulating film ER has been removed from over the scribe region SC of the semiconductor substrate SB. Note that it is also possible to combine Embodiment 3 with Embodiment 2 described above.

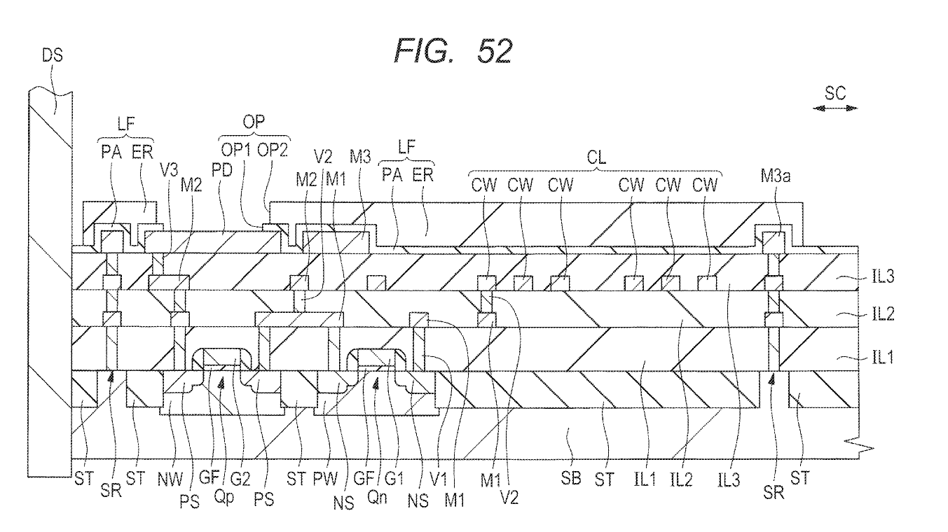

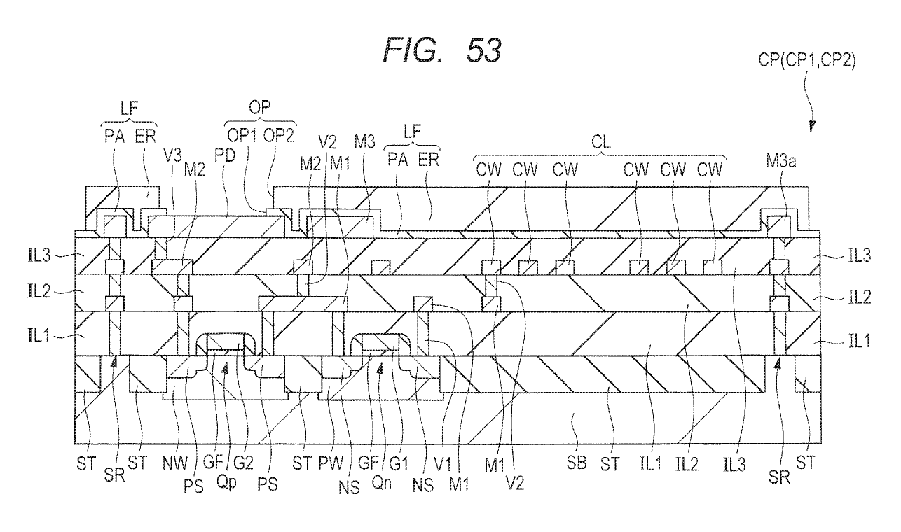

Then, in the same manner as in Embodiment 1 described above, in Embodiment 3 also, the back surface of the semiconductor substrate SB is ground or polished as necessary to reduce the thickness of the semiconductor substrate SB. Then, the semiconductor substrate SB is diced (cut) together with the multi-layer structure over the semiconductor substrate SB. At this time, as also shown in FIG. 52, the semiconductor substrate SB and the multi-layer structure over the semiconductor substrate SB are cut (diced) along the scribe region SC. As a result, as shown in FIG. 53, semiconductor chips are acquired from the individual chip regions of the semiconductor substrate SB (semiconductor wafer). In this manner, the semiconductor chip CP can be manufactured.

In Embodiment 3, before the dicing step is performed, the insulating film ER over the scribe region SC of the semiconductor substrate SB is removed therefrom. Accordingly, in the dicing step, the insulating film ER need not be cut. Since the insulating film ER has an adhesive property, when the insulating film ER also needs to be cut in the dicing step, the adhesive insulating film ER undesirably adheres to the dicing saw DS. As a result, the dicing step is hard to perform and, e.g., the number of times the dicing saw DS needs to be cleaned or replaced may be increased.

However, in Embodiment 3, before the dicing step is performed, the insulating film ER over the scribe region SC of the semiconductor substrate SB is removed therefrom. Consequently, in the dicing step, the insulating film ER need not be cut, and therefore it is possible to prevent the adhesive insulating film ER from adhering to the dicing saw DS. This allows the dicing step to be easily performed and can reduce, e.g., the number of times the dicing saw needs to be cleaned or replaced.

FIGS. 50 to 53 show the case where, at the stage where the dicing step is performed, the insulating film ER has been removed from over the scribe region SC of the semiconductor substrate SB, but the interlayer insulating films IL1, IL2, and IL3 and the insulating film PA have not been removed. In another form, there may also be a case in which the insulating film ER and the insulating film PA have been removed from over the scribe region SC of the semiconductor substrate SB, but the interlayer insulating films IL1, IL2, and IL3 have not been removed. In this case, when the opening OP1 is formed in the insulating film PA, the insulating film PA over the scribe region SC of the semiconductor substrate SB may be removed appropriately therefrom and, when the opening OP2 is formed in the insulating film ER, the insulating film ER over the scribe region SC of the semiconductor substrate SB may also be removed appropriately therefrom. In still another form, there may also be a case in which, at the stage where the dicing step is performed, the insulating film ER, the insulating film PA, and the interlayer insulating films IL1, IL2, and IL3 have been removed from over the scribe region SC of the semiconductor substrate SB.

### Embodiment 4

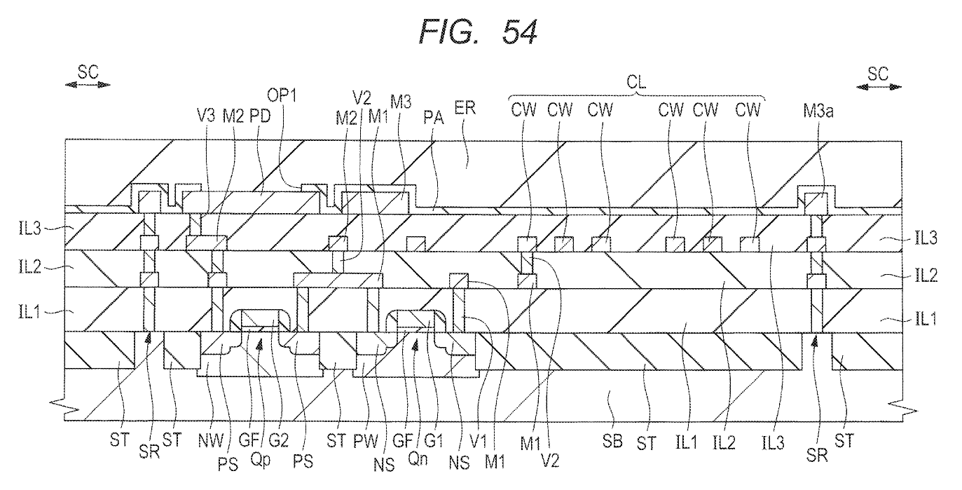

Next, a description will be given of planarization treatment for the insulating film ER with reference to FIGS. 54 to 56. FIGS. 54 to 56 are main-portion cross-sectional views of the semiconductor chip CP in Embodiment 4 during the manufacturing process thereof.

In the semiconductor package PKG, the semiconductor chip CP1 and CP2 are stacked such that the insulating film ER1 of the semiconductor chip CP1 and the insulating film ER2 of the semiconductor chip CP2 are in contact with each other. To enhance the adhesion between the insulating film ER1 of the semiconductor chip CP1 and the insulating film ER2 of the semiconductor chip CP2, it is preferable to enhance the planarity of the upper surface of each of the insulating films ER1 and ER2 of the semiconductor chips CP1 and CP2 when the semiconductor chips CP1 and CP2 are manufactured. In Embodiment 4, when the semiconductor chip CP (CP1 or CP2) is manufactured, the planarization treatment for the insulating film ER is performed as follows to enhance the planarity of the upper surface of the insulating film ER (ER1 or ER2) of the semiconductor chip CP (CP1 or CP2). The following is a specific description thereof.

In Embodiment 4 also, the insulating film ER is formed in the same manner as in Embodiment 1 described above to provide the structure in FIG. 54 corresponding to FIG. 32 or 34 described above. Note that, since the planarization treatment for the insulating film ER is performed in Embodiment 4, the formed film thickness of the insulating film ER can also be set larger than in Embodiment 1 described above.

Then, as shown in FIG. 55, the insulating film ER formed over the semiconductor substrate SB (i.e., over the insulating film PA) is irradiated with laser light (LZ) from a lateral direction (horizontal direction) to expose the surface layer portion (upper layer portion) of the insulating film ER. Note that, in FIG. 55, the direction of travel of the laser light is schematically shown by the arrow designated by LZ. At this time, the laser light for exposure travels in a direction generally parallel with the main surface of the semiconductor substrate SB such that the surface layer portion of the insulating film ER is irradiated with the laser light, but the lower layer portion of the insulating film ER is prevented from being irradiated with the laser light. The laser light incident on the upper portion of the side surface of the insulating film ER travels in a horizontal direction (direction generally parallel with the main surface of the semiconductor substrate SB) in the insulating film ER. The laser light is scanned in the direction of travel, while being kept traveling in the direction generally parallel with the main surface of the semiconductor substrate SB, to irradiate the surface layer portion of the insulating film ER over the entire main surface of the semiconductor wafer. This achieves a state in which only the surface layer portion of the entire insulating film ER is exposed to the laser light. In FIG. 55, an exposed region (region exposed to the laser light) EP6 of the insulating film ER is hatched with dots.

Then, by subjecting the insulating film ER to development treatment, the exposed region EP6 of the insulating film ER is removed. As a result, a structure in which the upper surface of the insulating film ER is planarized as shown in FIG. 56 is obtained. Even when the upper surface of the insulating film ER has any level difference before exposure, in the exposure step, the laser light for exposure travels in a direction generally parallel with the main surface of the semiconductor substrate SB. Accordingly, when the exposure treatment using the laser light and the subsequent development treatment are performed, the upper surface of the insulating film ER no longer has such a level difference and becomes planar. Thus, the upper surface of the insulating film ER can be planarized.

In the case of FIGS. 33 and 34 described above, after the structure in FIG. 34 described above is obtained, the insulating film ER can be subjected to the planarization treatment using the laser light described herein. In a modification, it is also possible to form the foregoing photosensitive resin film ERa by a coating method as shown in FIG. 33 described above, subsequently subject the photosensitive resin film ERa to the planarizing treatment using the laser light described herein, and form the foregoing photosensitive resin film ERb over the photosensitive resin film ERa by a coating method, as shown in FIG. 34 described above. In the case of this modification also, by planarizing the upper surface of the photosensitive resin film ERa, the upper surface of the insulating film ER made of a multi-layer film including the photosensitive resin films ERa and ERb is also planarized. Accordingly, the planarization in this modification is included in the planarization treatment for the insulating film ER in Embodiment 4.

The subsequent steps are the same in Embodiment 4 as in Embodiment 1 described above. The foregoing opening OP2 is formed in the insulating film ER, and the back surface of the semiconductor substrate SB is ground or polished as necessary to reduce the thickness of the semiconductor substrate SB. Then, the semiconductor substrate SB is diced (cut) together with the multi-layer structure over the semiconductor substrate SB, but the illustration thereof is omitted herein.

Embodiment 4 can also be combined with one or both of

Embodiments 2 and 3 described above. In the case of combining Embodiment 4 and Embodiment 2 described above, after the planarization for the insulating film ER is performed, the alignment portions (AL1 and AL2) and the opening OP2 may be formed appropriately in the insulating film ER, as in Embodiment 2 described above.

### Embodiment 5

FIGS. 57 to 61 are main-portion cross-sectional views of the semiconductor chip CP in Embodiment 5 during the manufacturing process thereof.

In Embodiment 5 also, the insulating film PA is formed in the same manner as in Embodiment 1 described above to provide the structure in FIG. 30 described above.

Then, as shown in FIG. 57, over the insulating film PA, a polyimide film (polyimide resin film) PL is formed. A polyimide film is a type of an organic insulating film made of a polymer containing an imide bond in a repeating unit. The polyimide film PL does not have an adhesive property such as that of the foregoing insulating film ER.

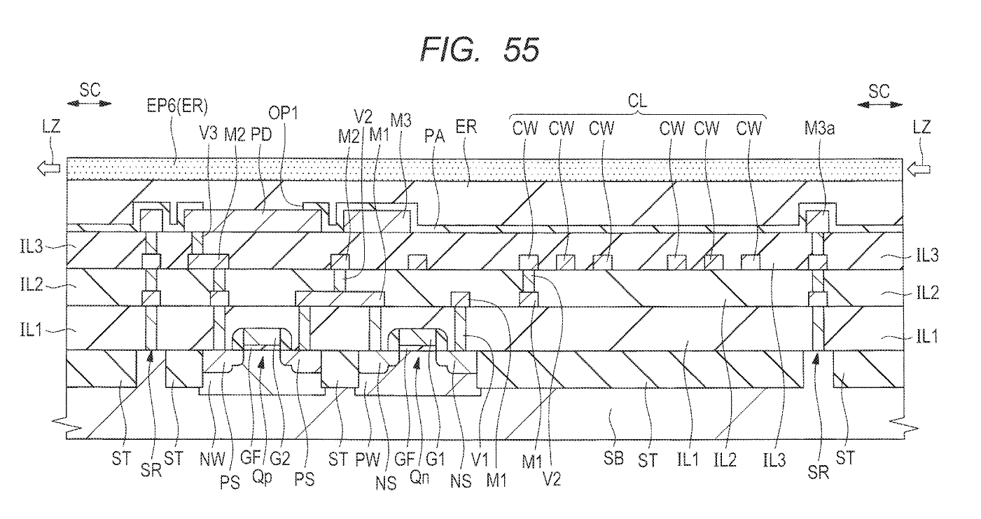

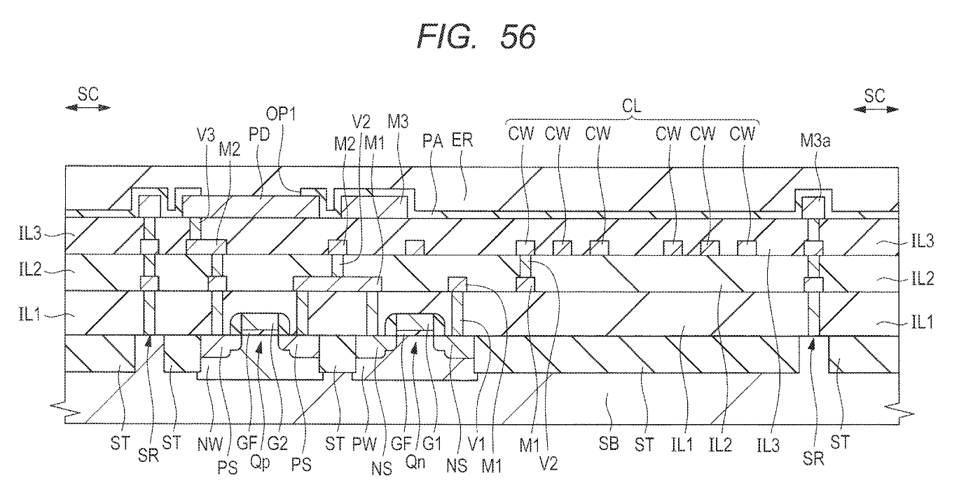

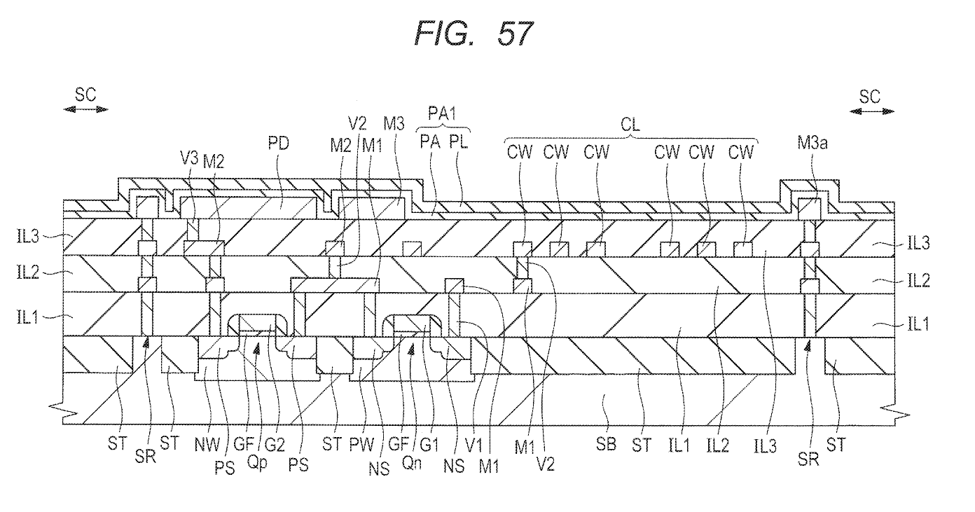

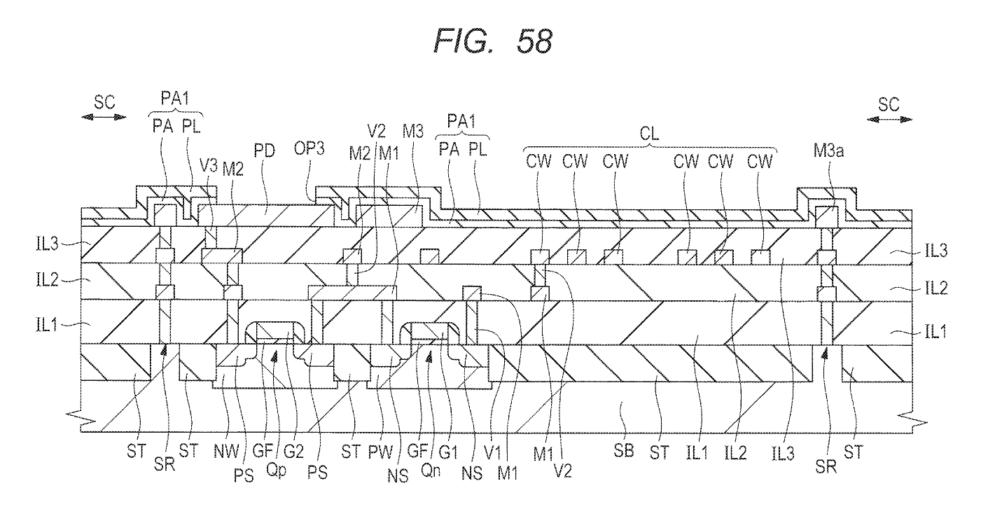

Next, as shown in FIG. 58, in the multi-layer film PA1 including the insulating film PA and the polyimide film PL over the insulating film PA, an opening OP3 is formed. The opening OP3 can be formed using, e.g., a photolithographic technique and an etching technique. The opening OP3 is formed at the same two-dimensional position as that of the foregoing opening OP1 and included in the pad PD in plan view. Accordingly, when the opening OP3 is formed in the multi-layer film PA1, a portion of the pad PD is exposed from the opening OP3 of the multi-layer film PAL It is also possible to form the opening OP3 extending through the multi-layer film PA1 by individually performing the step of forming an opening in the polyimide film PL and the step of forming an opening in the insulating film PA. When the polyimide film PL is a photosensitive polyimide film, it is also possible to form the opening in the polyimide film PL by subjecting the photosensitive polyimide film to exposure and development.

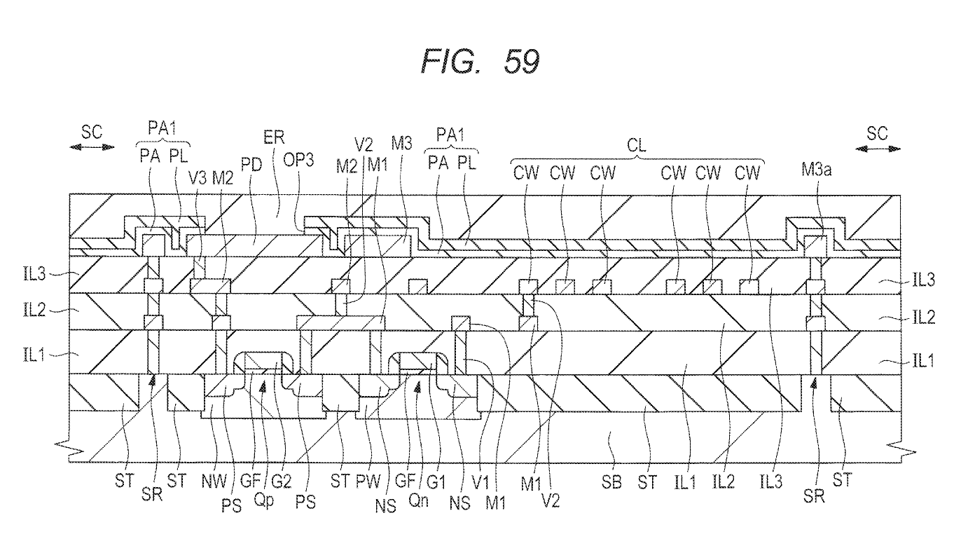

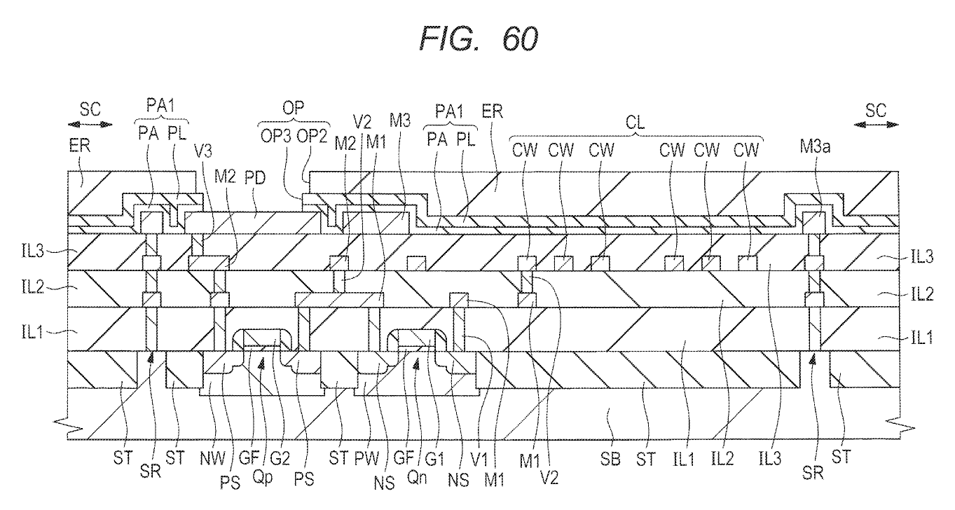

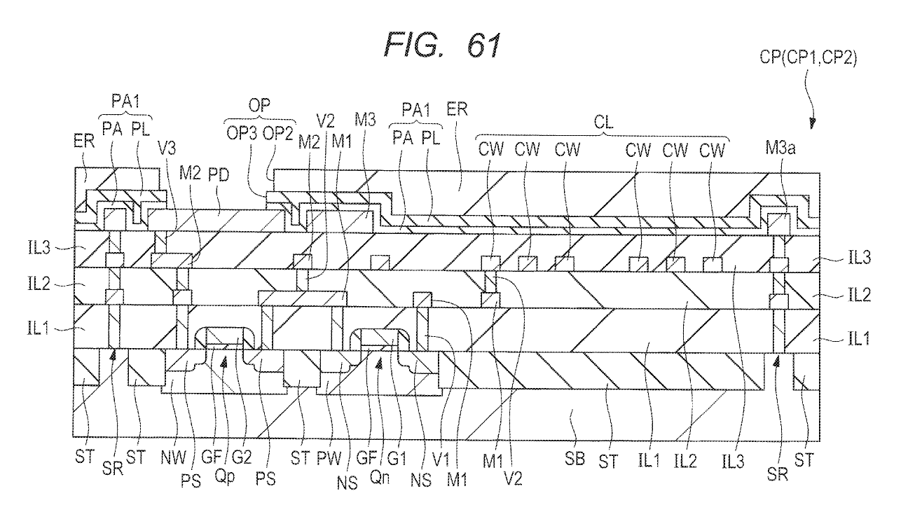

The subsequent steps are the same in Embodiment 5 as in Embodiment 1 described above. As shown in FIG. 59, over the main surface (entire main surface) of the semiconductor substrate SB, i.e., over the multi-layer film PA1, the insulating film ER is formed. A method of forming the insulating film ER is the same as in Embodiment 1 described above. Then, in the same manner as in Embodiment 1 described above, the insulating film ER is subjected to exposure and development to be formed with the opening OP2. As a result, as shown in FIG. 60, a state is obtained in which the opening OP is formed in a multi-layer film including the insulating film PA, the polyimide film PL over the insulating film PA, and the insulating film ER over the polyimide film PL. From the opening OP, at least one portion of the pad PD is exposed. The opening OP in Embodiment 5 is formed of the openings OP3 and OP2, and the opening OP3 is preferably included in the opening OP2 in plan view. Subsequently, in the same manner as in Embodiment 1 described above, the back surface of the semiconductor substrate SB is ground or polished as necessary to reduce the thickness of the semiconductor substrate SB. Then, the semiconductor substrate SB is diced (cut) together with the multi-layer structure over the semiconductor substrate SB. As a result, as shown in FIG. 61, the semiconductor chips CP are acquired from the individual chip regions of the semiconductor substrate SB (semiconductor wafer).

In the case of Embodiment 5, the insulating film under the insulating film ER (ER1 or ER2) as the photosensitive resin film having the adhesive property is made of the multi-layer film including the insulating film PA and the polyimide film PL over the insulating film PA. Since the insulating film ER needs to have an adhesive property, the range of choices for the material thereof is limited so that the insulating film ER is likely to have a certain degree of hardness. On the other hand, the polyimide film PL need not have an adhesive property such as that of the insulating film ER, and is therefore a soft film.

In Embodiment 5, under the insulating film ER, the polyimide film PL which is softer than the insulating film ER is formed and, over the soft polyimide film PL, the insulating film ER harder than the polyimide film PL is formed. This allows the stress applied to the insulating film ER (ER1 or ER2) to be reduced using the polyimide film PL under the insulating film ER (ER1 or ER2). That is, it is possible to allow the polyimide film PL to function as a stress relief layer (buffer layer). Thus, in the semiconductor package PKG in which the semiconductor chips CP1 and CP2 are stacked such that the insulating film ER1 of the semiconductor chip CP1 and the insulating film ER2 of the semiconductor chip CP2 are in contact with each other, it is possible to inhibit or prevent a crack or the like from being formed in the insulating film ER1 or ER2 of the semiconductor chip CP1 or CP2.

Embodiment 5 can also be combined with one or more of Embodiments 2, 3, and 4 described above.

While the invention achieved by the present inventors has been specifically described heretofore on the basis of the embodiments thereof, the present invention is not limited to the foregoing embodiments. It will be appreciated that various changes and modifications can be made in the invention within the scope not departing from the gist thereof.

What is claimed is:

1. A semiconductor device, comprising:
a first semiconductor chip including a first semiconductor substrate, a first wiring structure formed over the first semiconductor substrate and including one or more wiring layers, a first insulating film formed over the first wiring structure, and a first photosensitive resin film formed over the first insulating film and having an adhesive property; and
a second semiconductor chip including a second semiconductor substrate, a second wiring structure formed over the second semiconductor substrate and including one or more wiring layers, a second insulating film formed over the second wiring structure, and a second photosensitive resin film formed over the second insulating film and having an adhesive property,
wherein the first photosensitive resin film forms an uppermost layer of the first semiconductor chip,
wherein the second photosensitive resin film forms an uppermost layer of the second semiconductor chip, and
wherein the first semiconductor chip and the second semiconductor chip are stacked such that the first photosensitive resin film of the first semiconductor chip and the second photosensitive resin film of the second semiconductor chip are in contact with each other.

2. The semiconductor device according to claim 1,
wherein the first semiconductor chip includes a first coil formed in the first wiring structure,
wherein the second semiconductor chip has a second coil formed in the second wiring structure, and
wherein the first coil and the second coil are magnetically coupled to each other.

3. The semiconductor device according to claim 2,
wherein a signal is transmitted between the first semiconductor chip and the second semiconductor chip via the first and second coils magnetically coupled to each other.

4. The semiconductor device according to claim 1,
wherein each of the first insulating film and the second insulating film is made of silicon nitride or silicon oxynitride.

5. The semiconductor device according to claim 1,
wherein the first semiconductor chip has a plurality of first pads, and
wherein the second semiconductor chip has a plurality of second pads,
the semiconductor device further comprising:
a chip mounting portion over which the first semiconductor chip is mounted;
a plurality of first external terminals and a plurality of second external terminals;
a plurality of first conductive coupling members electrically coupling the first external terminals to the first pads of the first semiconductor chip;
a plurality of second conductive coupling members electrically coupling the second external terminals to the second pads of the second semiconductor chip; and
a sealing portion sealing therein the first semiconductor chip, the second semiconductor chip, the chip mounting portion, the first conductive coupling members, the second conductive coupling members, the first external terminals, and the second external terminals.

6. The semiconductor device according to claim 1,
wherein the first semiconductor chip includes a first alignment portion made of a projecting portion or a depressed portion of the first photosensitive resin film,
wherein the second semiconductor chip includes a second alignment portion made of a projecting portion or a depressed portion of the second photosensitive resin film, and
wherein the first semiconductor chip and the second semiconductor chip are stacked such that the first alignment portion and the second alignment portion fit together.

7. The semiconductor device according to claim 6,
wherein the first photosensitive resin film has the first alignment portions formed at three or more locations thereon,
wherein the second photosensitive resin film has the second alignment portions formed at three or more locations thereon, and
wherein the first semiconductor chip and the second semiconductor chip are stacked such that the first alignment portions and the second alignment portions fit together.

8. The semiconductor device according to claim 1,
wherein the first insulating film is made of a multi-layer film including a first film made of silicon nitride or silicon oxynitride and a first polyimide film over the first film,
wherein the first photosensitive resin film is formed over the first polyimide film,
wherein the second insulating film is made of a multi-layer film including a second film made of silicon nitride or silicon oxynitride and a second polyimide film over the second film, and
wherein the second photosensitive resin film is formed over the second polyimide film.

9. A method of manufacturing a semiconductor device including a first semiconductor chip and a second semiconductor which are stacked one over the other, the method of manufacturing the semiconductor device comprising the steps of:
(a) providing the first semiconductor chip;
(b) providing the second semiconductor chip; and
(c) after the steps (a) and (b), stacking the first semiconductor chip and the second semiconductor chip,
wherein the step (a) includes the steps of:
(a1) forming a first wiring structure including one or more wiring layers over a first semiconductor substrate;
(a2) after the step (a1), forming a first insulating film over the first wiring structure;
(a3) after the step (a2), forming a first photosensitive resin film over the first insulating film;
(a4) after the step (a3), subjecting the first photosensitive resin film to exposure and development treatment to pattern the first photosensitive resin film; and
(a5) after the step (a4), cutting the first semiconductor substrate,
wherein the step (b) includes the steps of:
(b1) forming a second wiring structure including one or more wiring layers over a second semiconductor substrate;
(b2) after the step (b1), forming a second insulating film over the second wiring structure;
(b3) after the step (b2), forming a second photosensitive resin film over the second insulating film;
(b4) after the step (b3), subjecting the second photosensitive resin film to exposure and development treatment to pattern the second photosensitive resin film; and
(b5) after the step (b4), cutting the second semiconductor substrate,
wherein each of the first photosensitive resin film and the second photosensitive resin film has an adhesive property, and
wherein, in the step (c), the first semiconductor chip and the second semiconductor chip are stacked such that the first photosensitive resin film of the first semiconductor chip having the adhesive property and the second photosensitive resin film of the second semiconductor chip having the adhesive property come in contact with each other.

10. The method of manufacturing the semiconductor device according to claim 9,
wherein the first semiconductor chip includes a first coil formed in the first wiring structure,
wherein the second semiconductor chip includes a second coil formed in the second wiring structure, and
wherein, in the step (c), the first semiconductor chip and the second semiconductor chips are stacked such that the first coil of the first semiconductor chip and the second coil of the second semiconductor chip are magnetically coupled to each other.

11. The method of manufacturing the semiconductor device according to claim 9,
wherein, in the step (a3), over the first insulating film, the first photosensitive resin film is formed using a coating method, and
wherein, in the step (b3), over the second insulating film, the second photosensitive resin film is formed using a coating method.

12. The method of manufacturing the semiconductor device according to claim 9,
wherein, in the step (a4), the first photosensitive resin film over a first scribe region of the first semiconductor substrate is removed therefrom,
wherein, in the step (a5), the first semiconductor substrate is cut along the first scribe region of the first semiconductor substrate,
wherein, in the step (b4), the second photosensitive resin film over a second scribe region of the second semiconductor substrate is removed therefrom, and
wherein, in the step (b5), the second semiconductor substrate is cut along the second scribe region of the second semiconductor substrate.

13. The method of manufacturing the semiconductor device according to claim 9, further comprising, after the step (a4) and before the step (a5), the step of:
(a6) subjecting the first photosensitive resin film to heat treatment,
the method of manufacturing the semiconductor device further comprising, after the step (b4) and before the step (b5), the step of:
(b6) subjecting the second photosensitive resin film to heat treatment.

14. The method of manufacturing the semiconductor device according to claim 9,
wherein the step (c) includes the steps of:
(c1) mounting the first semiconductor chip over a chip mounting portion; and
(c2) mounting and stacking the second semiconductor chip over the first semiconductor chip such that the first photosensitive resin film of the first semiconductor chip and the second photosensitive resin film of the second semiconductor chip come in contact with each other,
wherein the first semiconductor chip has a plurality of first pads,
wherein the second semiconductor chip has a plurality of second pads,
the method manufacturing the semiconductor device further comprising, after the step (c), the steps of:
(d) electrically coupling a plurality of first external terminals to the first pads of the first semiconductor chip via a plurality of first conductive coupling members and electrically coupling a plurality of second external terminals to the second pads of the second semiconductor chip via a plurality of second conductive coupling members; and
(e) after the step (d), forming a sealing portion sealing therein the first semiconductor chip, the second semiconductor chip, the chip mounting portion, the first conductive coupling members, the second conductive coupling members, the first external terminals, and the second external terminals.

15. The method of manufacturing the semiconductor device according to claim 9,
wherein each of the first insulating film and the second insulating film is made of silicon nitride or silicon oxynitride.

16. The method of manufacturing the semiconductor device according to claim 9,
wherein the first semiconductor chip includes a first alignment portion made of a projecting portion or a depressed portion of the first photosensitive resin film,
wherein the second semiconductor chip includes a second alignment portion made of a projecting portion or a depressed portion of the second photosensitive resin film, and
wherein, in the step (c), the first semiconductor chip and the second semiconductor chip are stacked such that the first photosensitive resin film of the first semiconductor chip and the second photosensitive resin film of the second semiconductor chip come in contact with each other and the first alignment portion and the second alignment portion fit together.

17. The method of manufacturing the semiconductor device according to claim 16,
wherein the first photosensitive resin film of the first semiconductor chip has the first alignment portions formed at three or more locations thereon,
wherein the second photosensitive resin film of the second semiconductor chip has the second alignment portions formed at three or more locations thereon, and
wherein, in the step (c), the first semiconductor chip and the second semiconductor chip are stacked such that the first alignment portions and the second alignment portions fit together.

18. The method of manufacturing the semiconductor device according to claim 9,
wherein the first insulating film is made of a multi-layer film including a first film made of silicon nitride or silicon oxynitride and a first polyimide film over the first film,
wherein, in the step (a3), the first photosensitive resin film is formed over the first polyimide film,
wherein the second insulating film is made of a multi-layer film including a second film made of silicon nitride or silicon oxynitride and a second polyimide film over the second film, and
wherein, in the step (b3), the second photosensitive resin film is formed over the second polyimide film.

19. The method of manufacturing the semiconductor device according to claim 9,
wherein, in the step (a3), the first photosensitive resin film is formed by repeating, in a plurality of cycles, the steps of:
(a7) forming a third film for forming the first photosensitive resin film by a coating method; and
(a8) after the step (a7), subjecting the third film formed in the step (a7) to heat treatment, and
wherein, in the step (b3), the second photosensitive resin film is formed by repeating, in a plurality of cycles, the steps of:
(b7) forming a fourth film for forming the second photosensitive resin film by a coating method; and
(b8) after the step (b7), subjecting the fourth film formed in the step (b7) to heat treatment.

20. The method of manufacturing the semiconductor device according to claim 9,
wherein the step (a) further includes, after the step (a3) and before the step (a4), the steps of:
(a9) exposing a surface layer portion of the first photosensitive resin film using laser light traveling in a direction parallel with a main surface of the first semiconductor substrate; and
(a10) after the step (a9), removing a region of the first photosensitive resin film which is exposed in the step (a9) by development treatment, and
wherein the step (b) further includes, after the step (b3) and before the step (b4), the steps of:
(b9) exposing a surface layer portion of the second photosensitive resin film using laser light traveling in a direction parallel with a main surface of the second semiconductor substrate; and
(b10) after the step (b9), removing a region of the second photosensitive resin film which is exposed in the step (b9) by development treatment.
